(19) United States
(12) Patent Application Publication
(10) Pub. No.: US 2013/0200357 A1
(43) Pub. Date: Aug. 8, 2013

(54) FORMULATIONS FOR ORGANIC ELECTROLUMINESCENT DEVICES

(71) Applicants: Aurélie Ludemann, Frankfurt am Main (DE); Rémi Manouk Anémian, Seoul (KR); Susanne Heun, Bad Soden (DE); Holger Heil, Frankfurt am Main (DE); Thomas Eberle, Landau (DE)

(72) Inventors: Aurélie Ludemann, Frankfurt am Main (DE); Rémi Manouk Anémian, Seoul (KR); Susanne Heun, Bad Soden (DE); Holger Heil, Frankfurt am Main (DE); Thomas Eberle, Landau (DE)

(73) Assignee: Merck Patent GmbH, Darmstadt (DE)

(21) Appl. No.: 13/879,155

(22) PCT Filed: Sep. 15, 2011
(86) PCT No.: PCT/EP2011/004645

§ 371 Date: Apr. 12, 2013

(30) Foreign Application Priority Data
Oct. 14, 2010 (DE) 10 2010 048 497.0

(51) Int. Cl. C09K 11/06; H01L 51/00

(52) U.S. Cl. CPC C09K 11/06; H01L 51/0072
USPC 257/40; 252/301.16

(57) ABSTRACT

The present invention relates to a formulation, in particular for use in organic electroluminescent devices, comprising a carbazole compound, an electron-transport compound, a triplet emitter compound and at least one solvent, where the electron-transport compound encompasses a ketone compound or a triazine compound and where the carbazole compound contains at least two carbazole groups whose N atoms are connected to one another via an aromatic or heteroaromatic ring system. The invention is furthermore directed to organic electro-luminescent devices which comprise the mixtures according to the invention.

The present invention relates to formulations, in particular for use in organic electroluminescent devices, comprising a carbazole compound, an electron-transport compound, a triplet emitter compound and at least one solvent, where the electron-transport compound encompasses a ketone compound or a triazine compound and where the carbazole compound contains at least two carbazole groups which are connected to one another via their N atoms. The invention is furthermore directed to organic electro-luminescent devices which comprise the mixtures according to the invention.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. A development in the area of organic electroluminescent devices are phosphorescent OLEDs. These have significant advantages owing to the higher achievable efficiency compared with fluorescent OLEDs.

However, there is still a need for improvement in the case of phosphorescent OLEDs. This applies, in particular, to the efficiency and lifetime of the devices.

In accordance with the prior art, electron-conducting materials, inter alia ketones (for example in accordance with WO 04/093207) or triazine derivatives (for example in accordance with DE 102008036982), are used as matrix materials for phosphorescent emitters. Low operating voltages and long lifetimes are achieved, in particular, with ketones, which makes this class of compounds a very interesting matrix material. However, there is still a need for improvement on use of these matrix materials, like in the case of other matrix materials, in particular with respect to the efficiency and lifetime of the devices.

The prior art furthermore discloses organic electroluminescent devices which comprise a phosphorescent emitter doped in a mixture of two matrix materials.

US 2007/0252516 discloses phosphorescent organic electroluminescent devices which comprise a mixture of a hole-conducting matrix material and an electron-conducting matrix material. Improved efficiency is disclosed for these OLEDs. An influence on the lifetime is not evident.

US 2007/0099026 discloses white-emitting organic electroluminescent devices in which the green- or red-emitting layer comprises a phosphorescent emitter and a mixture of a hole-conducting matrix material and an electron-conducting matrix material. Hole-conducting materials disclosed are, inter alia, triarylamine and carbazole derivatives. Electron-conducting materials disclosed are, inter alia, aluminium and zinc compounds, oxadiazole compounds and triazine or triazole compounds. Further improvements are also still desirable for these OLEDs.

WO 2008/127063 A2 discloses an electroluminescent device which has a cathode, an anode and in between a light-emitting layer which comprises a triplet emitter compound in a host. The host here is a mixture of an electron-transporting co-host unit and a hole-transporting co-host unit. However, this device urgently requires an electron-injection layer.

These mixtures are usually applied by vapour deposition in a high vacuum, which is on the one hand very complex and on the other hand results in the decomposition of a large number of compounds at the high temperatures necessary for the vapour-deposition process. This has an adverse effect on an electroluminescent device produced in this way.

The technical object on which the invention is based was therefore the provision of a formulation which can be processed in a simple manner and results in a very long lifetime and good efficiency in an organic electroluminescent device.

This object is achieved in accordance with the invention by a formulation comprising a carbazole compound, an electron-transport compound, a triplet emitter compound and at least one solvent, where the electron-transport compound encompasses a ketone compound or a triazine compound and where the carbazole compound contains at least two carbazole groups which are connected to one another via their N atoms.

Besides the at least one solvent, the formulation according to the invention comprises:
at least one carbazole compound,
at least one electron-transport compound and
at least one triplet emitter compound.

The proportion of the carbazole compound in the formulation according to the invention is preferably in the range from 10 to 70% by weight, particularly preferably in the range from 20 to 60% by weight and very particularly preferably in the range from 30 to 50% by weight, based on the mixture of carbazole compound, electron-transport compound and triplet emitter compound.

The proportion of the electron-transport compound, and thus the proportion of ketone and/or triazine compound, in the formulation according to the invention is preferably in the range from 10 to 70% by weight, particularly preferably in the range from 20 to 60% by weight and very particularly preferably in the range from 30 to 50% by weight, based on the mixture of carbazole compound, electron-transport compound and triplet emitter compound.

The weight ratio between the carbazole compound and the electron-transport compound is preferably between 10:1 and 1:10, particularly preferably between 7:1 and 1:7 and very particularly preferably between 4:1 and 1:4.

The proportion of the triplet emitter compound in the formulation according to the invention is preferably in the range from 0.01 to 50% by weight, particularly preferably in the range from 0.1 to 40% by weight and very particularly preferably in the range from 1 to 30% by weight, based on the mixture of carbazole compound, electron-transport compound and triplet emitter compound.

The concentration of the mixture of carbazole compound, electron-transport compound and triplet emitter compound in the formulation according to the invention is preferably in the range from 1 to 100 g/l, particularly preferably in the range from 5 to 50 g/l and very particularly preferably in the range from 10 to 30 g/l.

The N atoms of the carbazole groups are preferably connected to one another via an aromatic or heteroaromatic ring system.

In an embodiment of the present invention, the carbazole compound is preferably a compound of the formula (1)

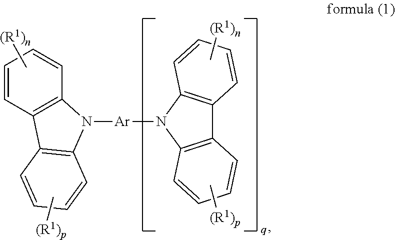

where the following applies to the symbols and indices used:
Ar is on each occurrence an aromatic or heteroaromatic ring system having 5 to 60 aromatic ring atoms, which may be substituted by one or more radicals R;
R, R¹ is on each occurrence, identically or differently, H, D, F, Cl, Br, I, N(Ar¹)₂, CN, NO₂, Si(R²)₃, B(OR²)₂, C(═O)Ar¹, P(═O)(Ar¹)₂, S(═O)Ar¹, S(═O)₂Ar¹, —CR²═CR²(Ar¹), OSO₂R², a straight-chain alkyl, alkoxy or thioalkoxy group having 1 to 40 C atoms or a branched or cyclic alkyl, alkoxy or thioalkoxy group having 3 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C=Se, C═NR², P(═O)(R²), SO, SO₂, NR², O, S or CONR² and where one or more H atoms may be replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or a combination of these systems; two or more substituents R, R¹ or R and R¹ here may also form a mono- or polycyclic, aliphatic, aromatic or heteroaromatic ring system with one another;

Ar¹ is on each occurrence, identically or differently, an aromatic or hetero-aromatic ring system having 5 to 60 aromatic ring atoms, which may be substituted by one or more radicals R²;
R² is on each occurrence, identically or differently, H or an aliphatic, aromatic and/or heteroaromatic hydrocarbon radical having 1 to 20 C atoms; or an aromatic or heteroaromatic ring system having 5 to 60 aromatic ring atoms, which may be substituted by one or more radicals R; two or more substituents R² here may also form a mono or polycyclic, aliphatic, aromatic or heteroaromatic ring system with one another;
n is on each occurrence, identically or differently, 0, 1, 2, 3 or 4;
p is on each occurrence, identically or differently, 0, 1, 2, 3 or 4;
q is 1, 2, 3, 4 or 5.

If the index q is equal to 1, this means that Ar represents a divalent group. If the index q is greater than 1, this means that a total of three or more carbazole groups are bonded to the aromatic ring system Ar. Ar is a trivalent group for q=2 and a correspondingly polyvalent group for q>2. The index q is preferably =1 or 2, particularly preferably q=1.

The carbazole compounds employed in accordance with the invention preferably have a glass-transition temperature T_{g} of greater than 120° C., particularly preferably greater than 140° C.

The carbazole group in the present invention serves principally as matrix material and/or as hole-transport material. A hole-transporting material is characterised in the present application by an HOMO of preferably greater than −5.4 eV. An electron-transporting material is characterised in the present application by an LUMO of preferably less than −2.4 eV. The HOMO and LUMO positions and the energy gap are determined as described in detail in the example part.

An aryl group in accordance with the present invention contains 6 to 60 C atoms; a heteroaryl group in accordance with the present invention contains 2 to 60 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, phenanthrene, quinoline, isoquinoline, etc.

An aromatic ring system in accordance with the present invention contains 6 to 40 C atoms in the ring system. A heteroaromatic ring system in accordance with the present invention contains 2 to 40 C atoms and at least one heteroatom in the ring system, with the proviso that the sum of C atoms and heteroatoms is at least 5. The heteroatoms are preferably selected from N, O and/or S. An aromatic or heteroaromatic ring system in accordance with the present invention is intended to be taken to mean a system which does not necessarily contain only aryl or heteroaryl groups, but instead in which, in addition, a plurality of aryl or heteroaryl groups may be interrupted by a non-aromatic unit (preferably less than 10% of the atoms other than H), such as, for example, an sp³-hybridised C, N or O atom. Thus, for example, systems such as 9,9′-spirobifluorene, 9,9-diarylfluorene, triarylamine, diaryl ethers, stilbene, etc. are also intended to be taken to be aromatic ring systems in accordance with the present invention, as are systems in which two or more aryl groups are interrupted, for example, by a linear or cyclic alkyl group or by a silyl group. The aromatic ring system preferably contains no metal atoms.

For the purposes of the present invention, a C₁- to C₄₀-alkyl group, in which, in addition, individual H atoms or CH₂ groups may be substituted by the above-mentioned groups, is preferably taken to mean the radicals methyl, ethyl, n-propyl, i-propyl, n-butyl, i-butyl, s-butyl, t-butyl, 2-methyl-butyl, n-pentyl, s-pentyl, cyclopentyl, n-hexyl, cyclohexyl, n-heptyl, cyclo-heptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl and octynyl.

A C₁- to C₄₀-alkoxy group is preferably taken to mean methoxy, trifluoro-methoxy, ethoxy, n-propoxy, i-propoxy, n-butoxy, i-butoxy, s-butoxy, t-butoxy or 2-methylbutoxy.

An aromatic or heteroaromatic ring system having 5 to 60 aromatic ring atoms, which may also in each case be substituted by the above-mentioned radicals R and which may be linked to the aromatic or heteroaromatic system via any desired positions, is taken to mean, in particular, groups derived from benzene, naphthalene, anthracene, phenanthrene, pyrene, chrysene, perylene, fluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

In a preferred embodiment of the invention, the indices n in the compound of the formula (1) are on each occurrence, identically or differently, 0 or 1. The indices n are particularly preferably =0.

In an embodiment, the index p in the compound of the formula (1) is, identically or differently on each occurrence, 0, 1 or 2, particularly preferably 0 or 1. If the index p is equal to 1, the substituent R¹ is preferably bonded in the 6-, 7- or 8-position of the carbazole and particularly preferably in the 6- or 7-position.

For clarity, the numbering of the positions of carbazole is depicted in the following formula:

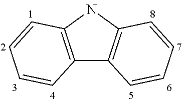 [SMILES: c1ccc2c(c1)[nH]c1ccccc12]

Preferred groups Ar and R¹ in formula (1) contain only phenyl and/or naphthyl groups or heteroaromatic groups having not more than two condensed aromatic or heteroaromatic rings, but no larger condensed aromatic systems. Preferred groups Ar and R¹ are therefore aromatic ring systems which are built up from phenyl and/or naphthyl groups or linked systems of this type, such as, for example, biphenyl, fluorene, spirobifluorene, etc.

Particularly preferred groups Ar are selected from the group consisting of 1,2-phenylene, 1,3-phenylene, 1,4-phenylene, 1,3,5-benzene, 3,3′-biphenyl, 4,4′-biphenyl, 1,3,5-triphenylbenzene, triphenylamine, 2,7-fluorenylene, which may be substituted by one or more radicals R¹, 2,7-spirobifluorenylene, which may be substituted by one or more radicals R¹, indenofluorenylene, which may be substituted by one or more radicals R¹, 4,4′″-(1,1′:2′,″,2″,1′″-quaterphenyl), 4,4′-(2,2′-dimethylbiphenyl), 4,4′-(1,1′-binaphthyl), 4,4′-stilbenzyl and dihydrophenanthrenyl, which may be substituted by one or more radicals R¹.

Particularly preferred groups R¹ of the carbazole compound are selected, identically or differently, from the group consisting of phenyl, 1-naphthyl, 2-naphthyl, 2-carbazolyl, 3-carbazolyl, 9-carbazolyl, triphenylamine, naphthyldiphenylamine and dinaphthylphenylamine, each of which may be substituted by one or more radicals R. The two last-mentioned groups here may be bonded via the naphthalene in the 1- or 2-position or via the phenyl group. A 2- or 3-carbazolyl group here is preferably substituted on the nitrogen by an aromatic radical R.

Preference is furthermore given to compounds of the formula (1) in which the symbol R stands, identically or differently on each occurrence, for H, N(Ar²)₂, a straight-chain alkyl group having 1 to 5 C atoms or a branched alkyl group having 3 to 5 C atoms, where in each case one or more non-adjacent CH₂ groups may be replaced by —R²C═CR²— or —O— and where one or more H atoms may be replaced by F, or an aryl group having 6 to 16 C atoms or a heteroaryl group having 2 to 16 C atoms or a spirobifluorene group, each of which may be substituted by one or more radicals R², or a combination of two of these systems. Particularly preferred radicals R are, identically or differently on each occurrence, H, methyl, ethyl, isopropyl, tert-butyl, where in each case one or more H atoms may be replaced by F, or a phenyl, naphthyl or spirobifluorenyl group, each of which may be substituted by one or more radicals R, or a combination of two of these systems. In the case of compounds which are processed from solution, linear or branched alkyl chains having up to 10 C atoms are also preferred. Bromine, boronic acid or boronic acid derivatives as substituents are preferred, in particular, for use of these compounds as intermediate compounds for the preparation of further compounds according to the invention, for example polymers, oligomers or dendrimers.

Preference is furthermore given to compounds of the formula (1) in which the symbol R¹ is, identically or differently on each occurrence, defined as for the preferred substituent R or stands for Ar or F.

Examples of particularly preferred compounds of the formula (1) are compounds (1-1) to (1-91) depicted below.

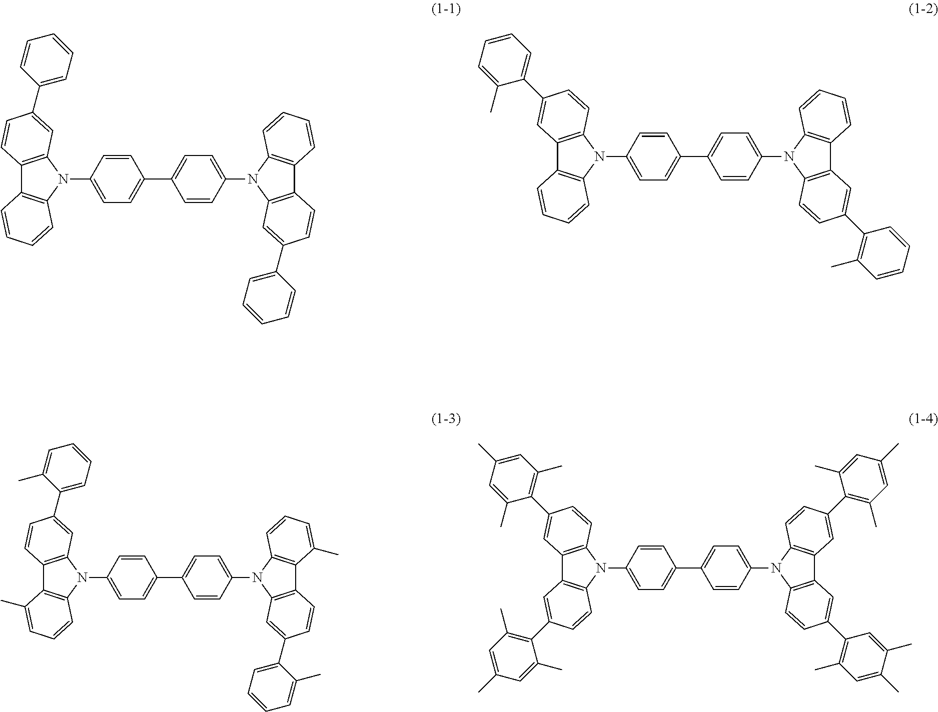

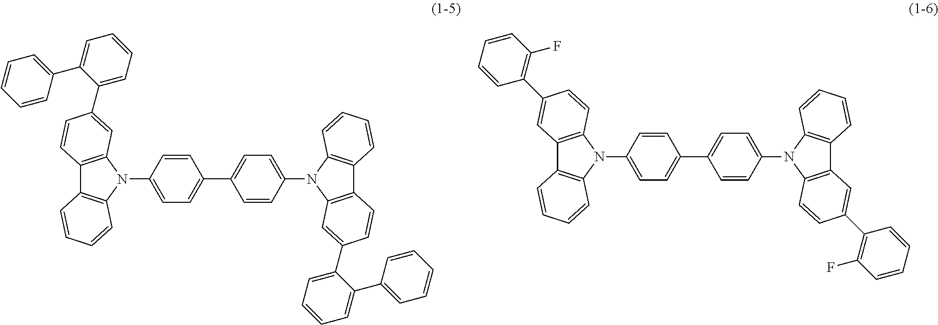 [SMILES: c1ccc(-c2ccccc2-c2ccc3c4ccccc4n(-c4ccc(-c5ccc(-n6c7ccccc7c7ccc(-c8ccccc8-c8ccccc8)cc76)cc5)cc4)c3c2)cc1 ; Fc1ccccc1-c1ccc2c(c1)c1ccccc1n2-c1ccc(-c2ccc(-n3c4ccccc4c4cc(-c5ccccc5F)ccc43)cc2)cc1]

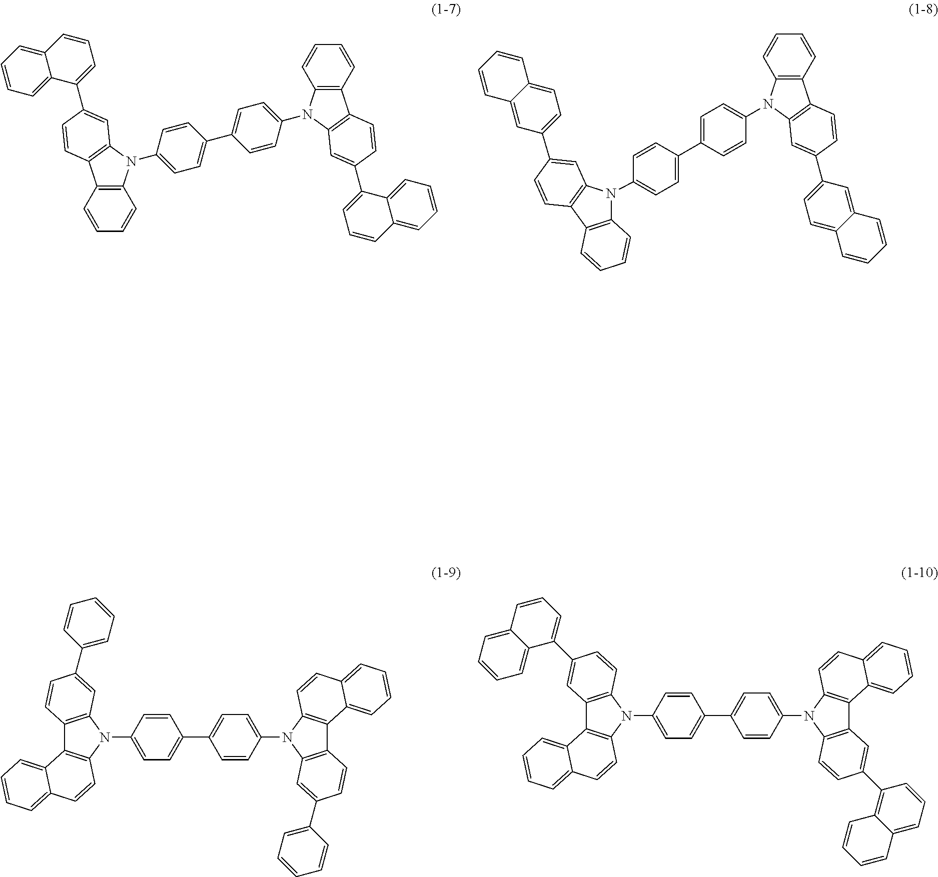 [SMILES: c1ccc2c(-c3ccc4c5ccccc5n(-c5ccc(-c6ccc(-n7c8ccccc8c8ccc(-c9cccc%10ccccc9%10)cc87)cc6)cc5)c4c3)cccc2c1 ; c1ccc2cc(-c3ccc4c5ccccc5n(-c5ccc(-c6ccc(-n7c8ccccc8c8ccc(-c9ccc%10ccccc%10c9)cc87)cc6)cc5)c4c3)ccc2c1 ; c1ccc(-c2ccc3c4c5ccccc5ccc4n(-c4ccc(-c5ccc(-n6c7cc(-c8ccccc8)ccc7c7c8ccccc8ccc76)cc5)cc4)c3c2)cc1 ; c1ccc2c(-c3ccc4c(c3)c3c5ccccc5ccc3n4-c3ccc(-c4ccc(-n5c6ccc(-c7cccc8ccccc78)cc6c6c7ccccc7ccc65)cc4)cc3)cccc2c1]

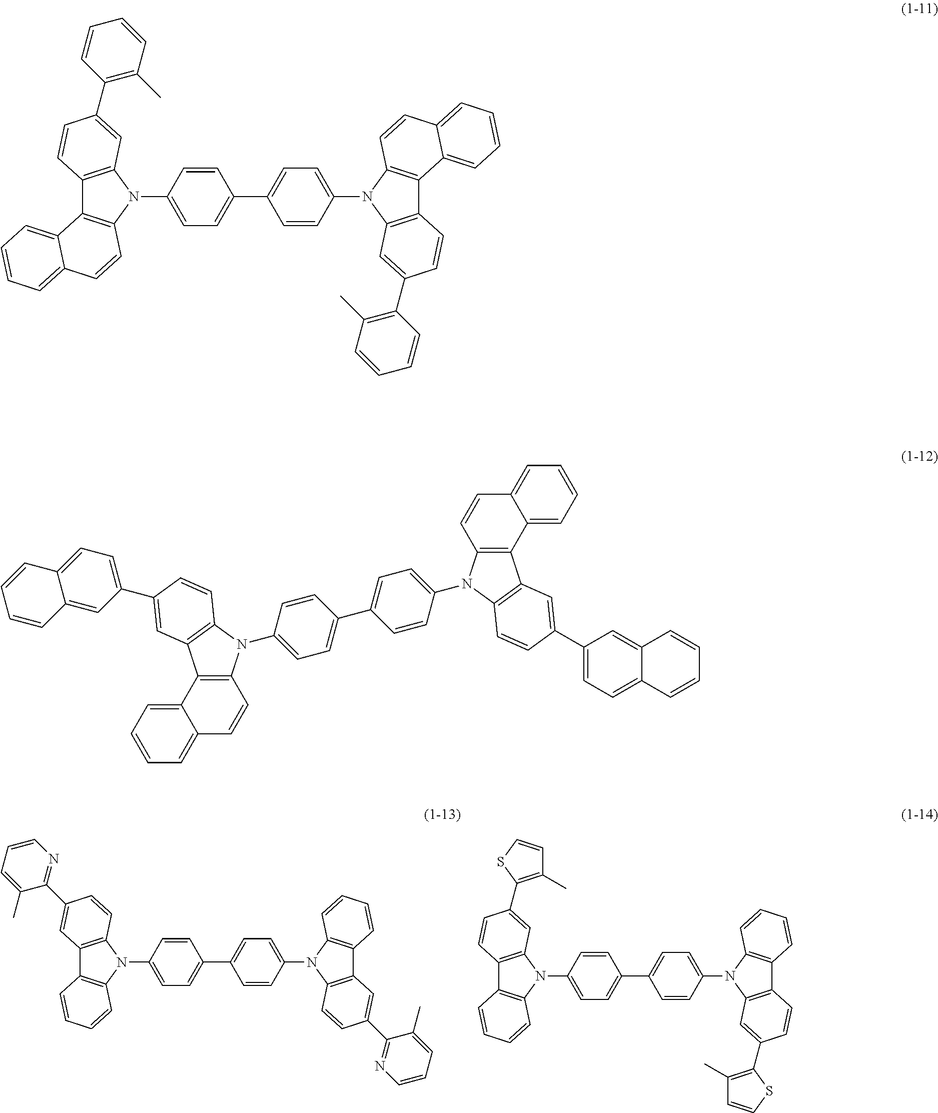 [SMILES: Cc1ccccc1-c1ccc2c3c4ccccc4ccc3n(-c3ccc(-c4ccc(-n5c6cc(-c7ccccc7C)ccc6c6c7ccccc7ccc65)cc4)cc3)c2c1 ; c1ccc2cc(-c3ccc4c(c3)c3c5ccccc5ccc3n4-c3ccc(-c4ccc(-n5c6ccc(-c7ccc8ccccc8c7)cc6c6c7ccccc7ccc65)cc4)cc3)ccc2c1 ; Cc1cccnc1-c1ccc2c(c1)c1ccccc1n2-c1ccc(-c2ccc(-n3c4ccccc4c4cc(-c5ncccc5C)ccc43)cc2)cc1 ; Cc1ccsc1-c1ccc2c3ccccc3n(-c3ccc(-c4ccc(-n5c6ccccc6c6ccc(-c7sccc7C)cc65)cc4)cc3)c2c1]

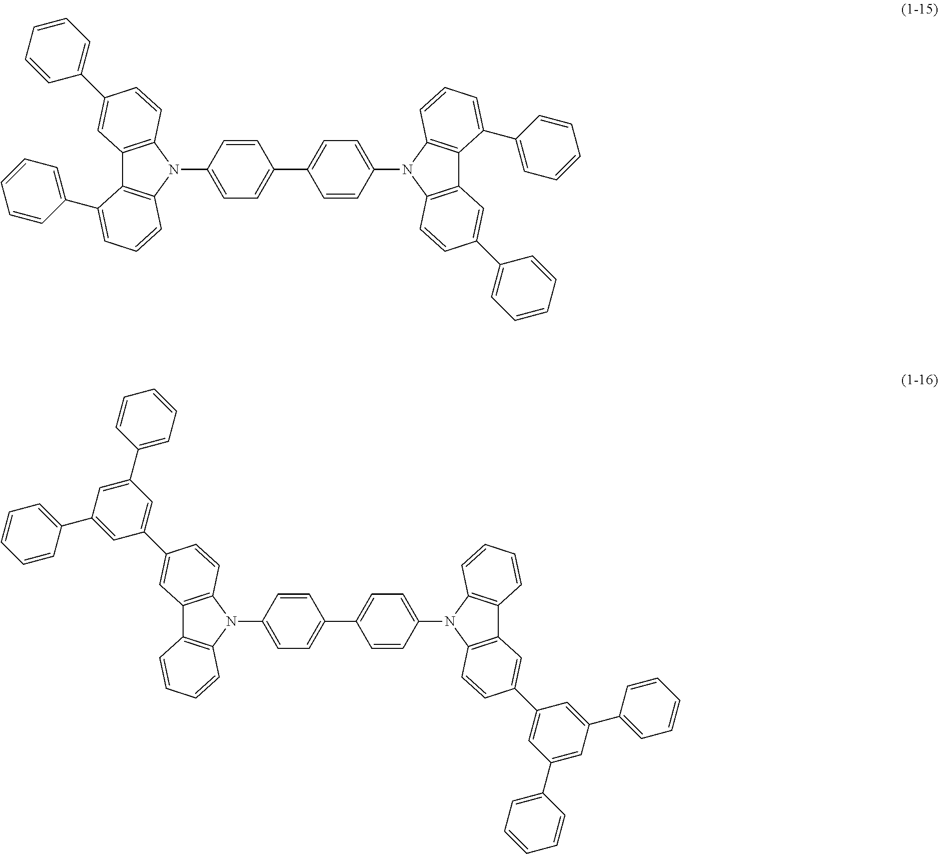 [SMILES: c1ccc(-c2ccc3c(c2)c2c(-c4ccccc4)cccc2n3-c2ccc(-c3ccc(-n4c5ccc(-c6ccccc6)cc5c5c(-c6ccccc6)cccc54)cc3)cc2)cc1 ; c1ccc(-c2cc(-c3ccccc3)cc(-c3ccc4c(c3)c3ccccc3n4-c3ccc(-c4ccc(-n5c6ccccc6c6cc(-c7cc(-c8ccccc8)cc(-c8ccccc8)c7)ccc65)cc4)cc3)c2)cc1]

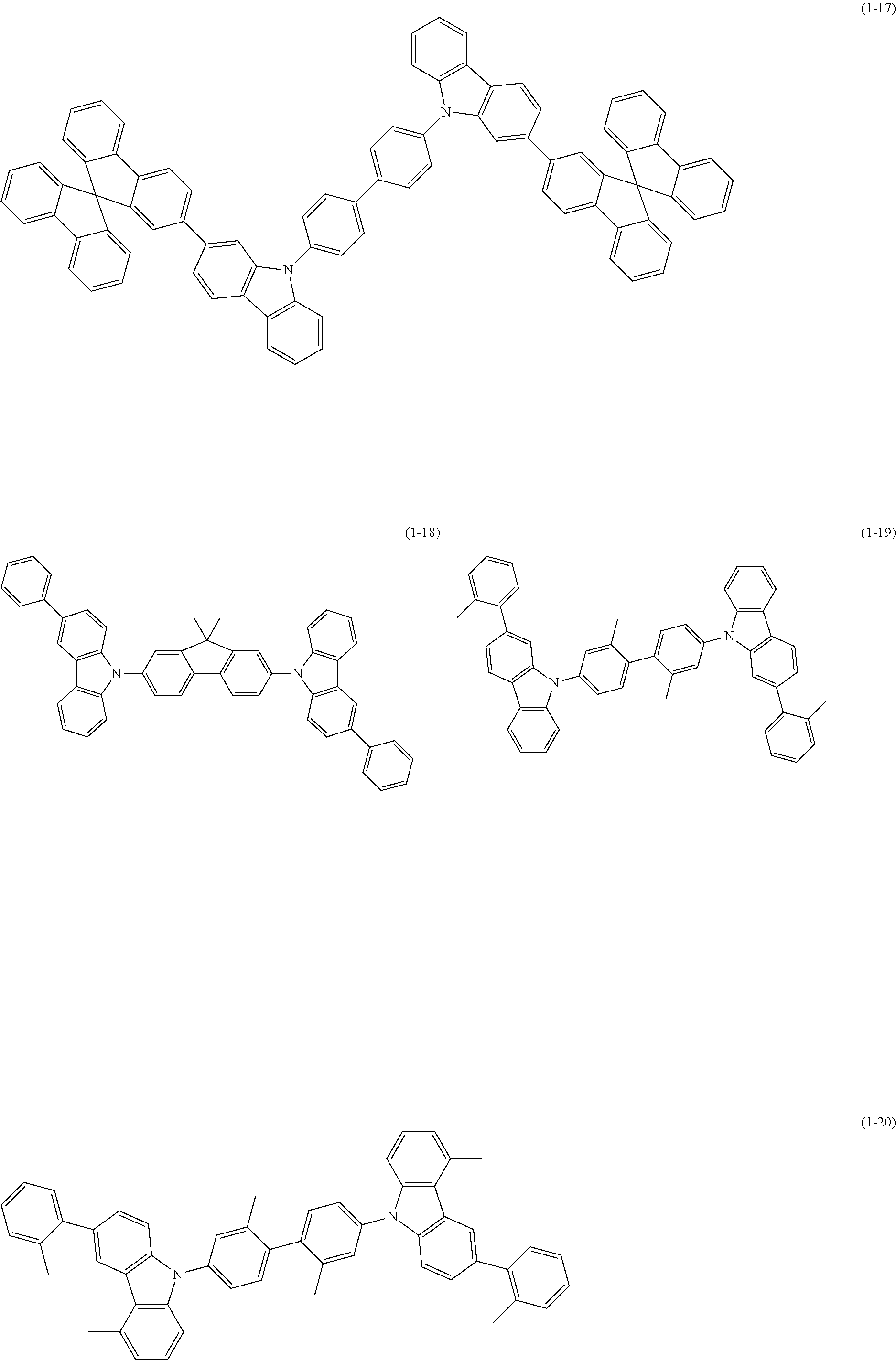

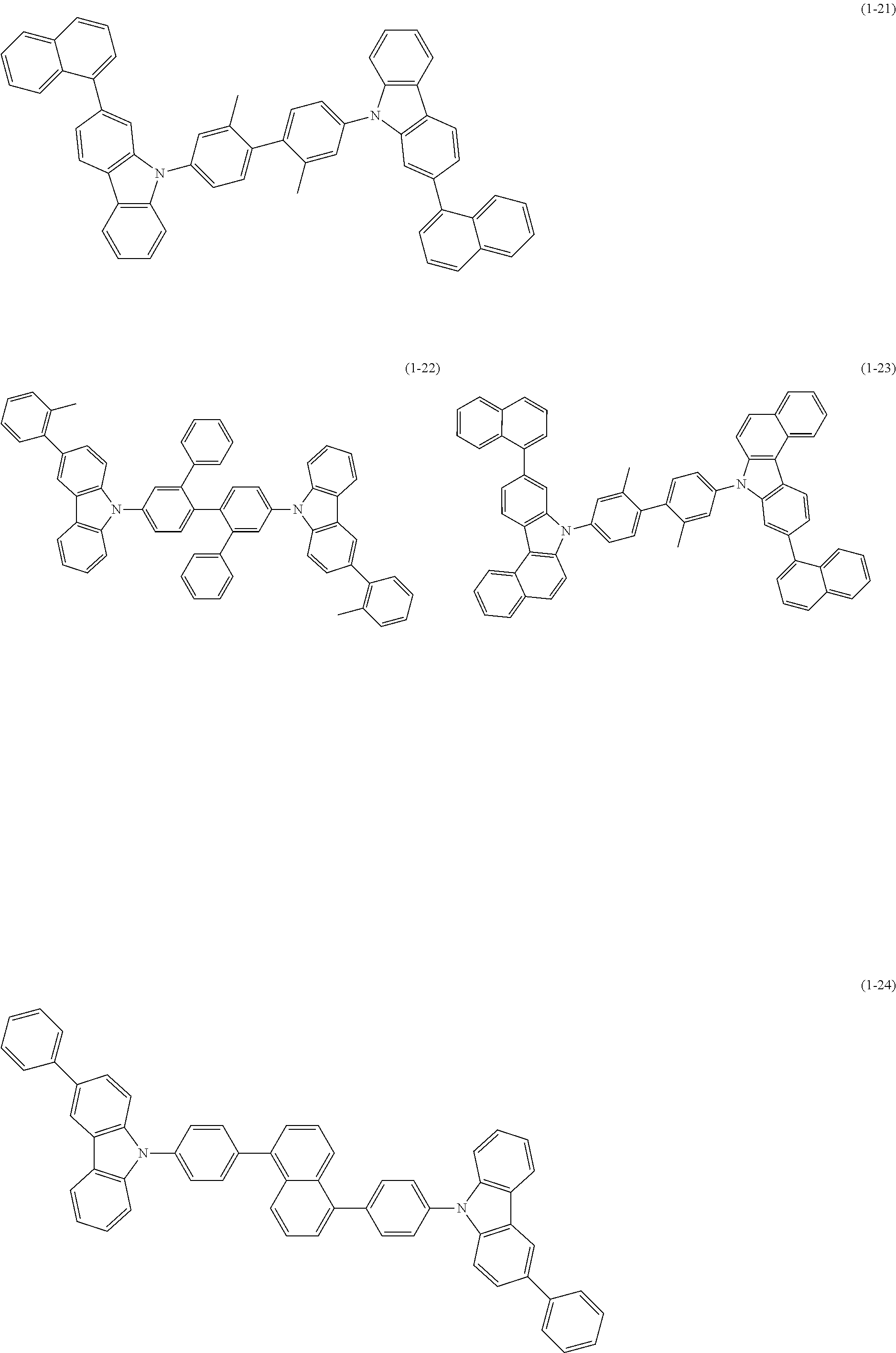 [SMILES: Cc1cc(-n2c3ccccc3c3ccc(-c4cccc5ccccc45)cc32)ccc1-c1ccc(-n2c3ccccc3c3ccc(-c4cccc5ccccc45)cc32)cc1C ; Cc1ccccc1-c1ccc2c(c1)c1ccccc1n2-c1ccc(-c2ccc(-n3c4ccccc4c4cc(-c5ccccc5C)ccc43)cc2-c2ccccc2)c(-c2ccccc2)c1 ; Cc1cc(-n2c3cc(-c4cccc5ccccc45)ccc3c3c4ccccc4ccc32)ccc1-c1ccc(-n2c3cc(-c4cccc5ccccc45)ccc3c3c4ccccc4ccc32)cc1C ; c1ccc(-c2ccc3c(c2)c2ccccc2n3-c2ccc(-c3cccc4c(-c5ccc(-n6c7ccccc7c7cc(-c8ccccc8)ccc76)cc5)cccc34)cc2)cc1]

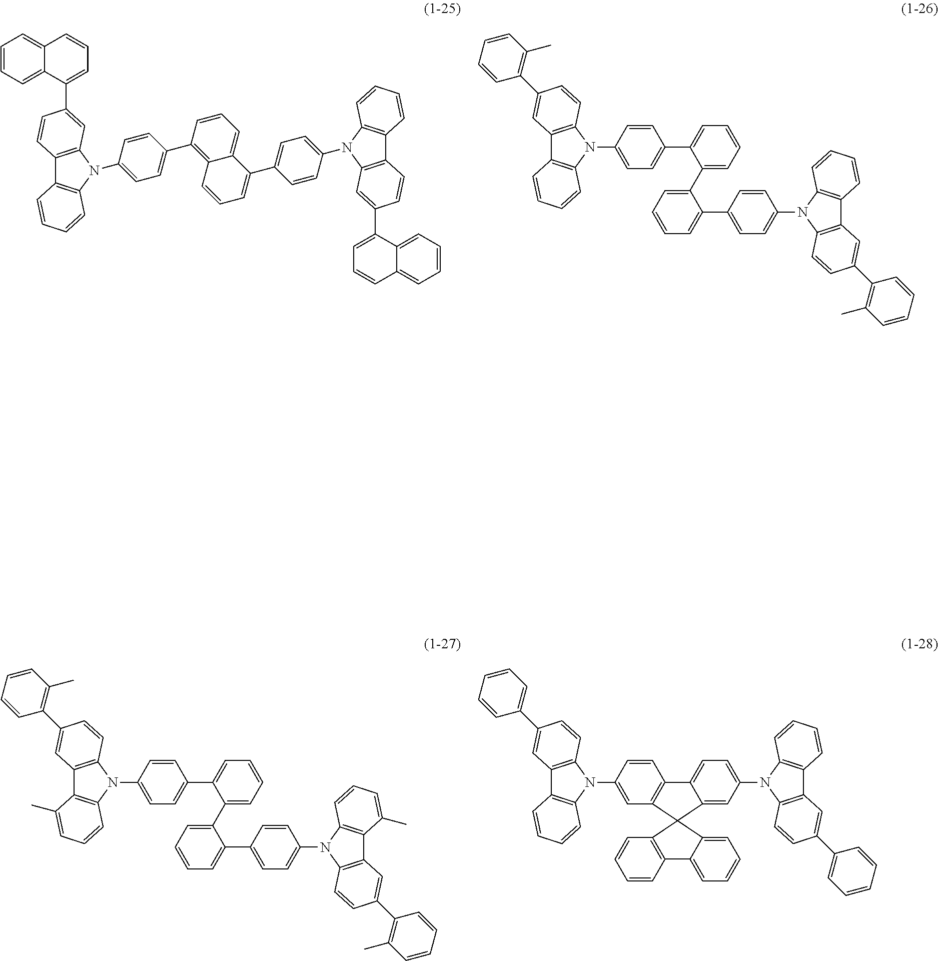 [SMILES: c1ccc2c(-c3ccc4c5ccccc5n(-c5ccc(-c6cccc7c(-c8ccc(-n9c%10ccccc%10c%10ccc(-c%11cccc%12ccccc%11%12)cc%109)cc8)cccc67)cc5)c4c3)cccc2c1 ; Cc1ccccc1-c1ccc2c(c1)c1ccccc1n2-c1ccc(-c2ccccc2-c2ccccc2-c2ccc(-n3c4ccccc4c4cc(-c5ccccc5C)ccc43)cc2)cc1 ; Cc1ccccc1-c1ccc2c(c1)c1c(C)cccc1n2-c1ccc(-c2ccccc2-c2ccccc2-c2ccc(-n3c4ccc(-c5ccccc5C)cc4c4c(C)cccc43)cc2)cc1 ; c1ccc(-c2ccc3c(c2)c2ccccc2n3-c2ccc3c(c2)C2(c4ccccc4-c4ccccc42)c2cc(-n4c5ccccc5c5cc(-c6ccccc6)ccc54)ccc2-3)cc1]

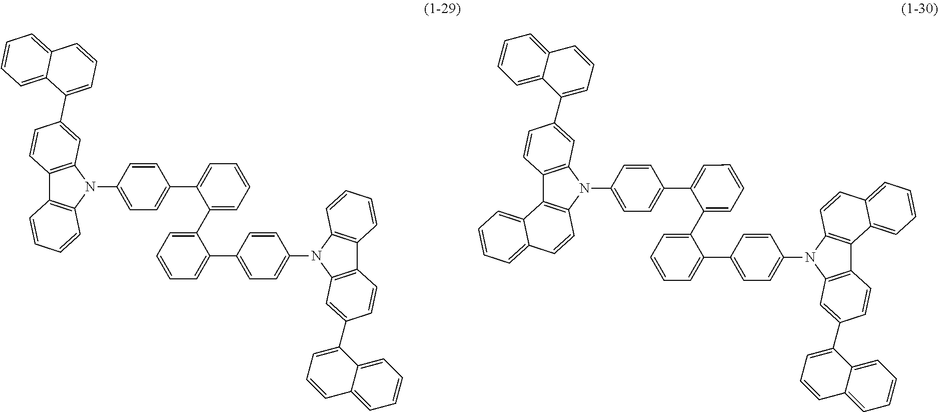 [SMILES: c1ccc(-c2ccccc2-c2ccc(-n3c4ccccc4c4ccc(-c5cccc6ccccc56)cc43)cc2)c(-c2ccc(-n3c4ccccc4c4ccc(-c5cccc6ccccc56)cc43)cc2)c1 ; c1ccc(-c2ccccc2-c2ccc(-n3c4cc(-c5cccc6ccccc56)ccc4c4c5ccccc5ccc43)cc2)c(-c2ccc(-n3c4cc(-c5cccc6ccccc56)ccc4c4c5ccccc5ccc43)cc2)c1]

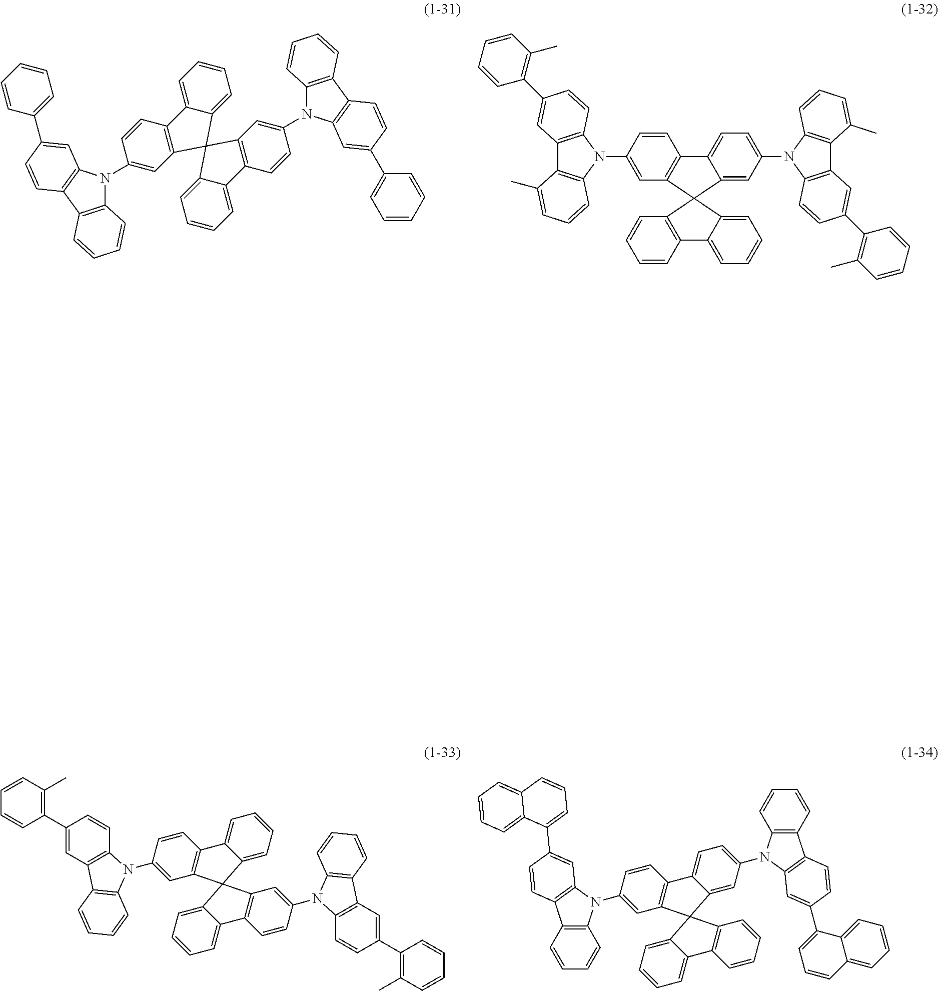 [SMILES: c1ccc(-c2ccc3c4ccccc4n(-c4ccc5c(c4)C4(c6ccccc6-5)c5ccccc5-c5ccc(-n6c7ccccc7c7ccc(-c8ccccc8)cc76)cc54)c3c2)cc1 ; Cc1ccccc1-c1ccc2c(c1)c1c(C)cccc1n2-c1ccc2c(c1)C1(c3ccccc3-c3ccccc31)c1cc(-n3c4ccc(-c5ccccc5C)cc4c4c(C)cccc43)ccc1-2 ; Cc1ccccc1-c1ccc2c(c1)c1ccccc1n2-c1ccc2c(c1)C1(c3ccccc3-2)c2ccccc2-c2ccc(-n3c4ccccc4c4cc(-c5ccccc5C)ccc43)cc21 ; c1ccc2c(c1)-c1ccccc1C21c2cc(-n3c4ccccc4c4ccc(-c5cccc6ccccc56)cc43)ccc2-c2ccc(-n3c4ccccc4c4ccc(-c5cccc6ccccc56)cc43)cc21]

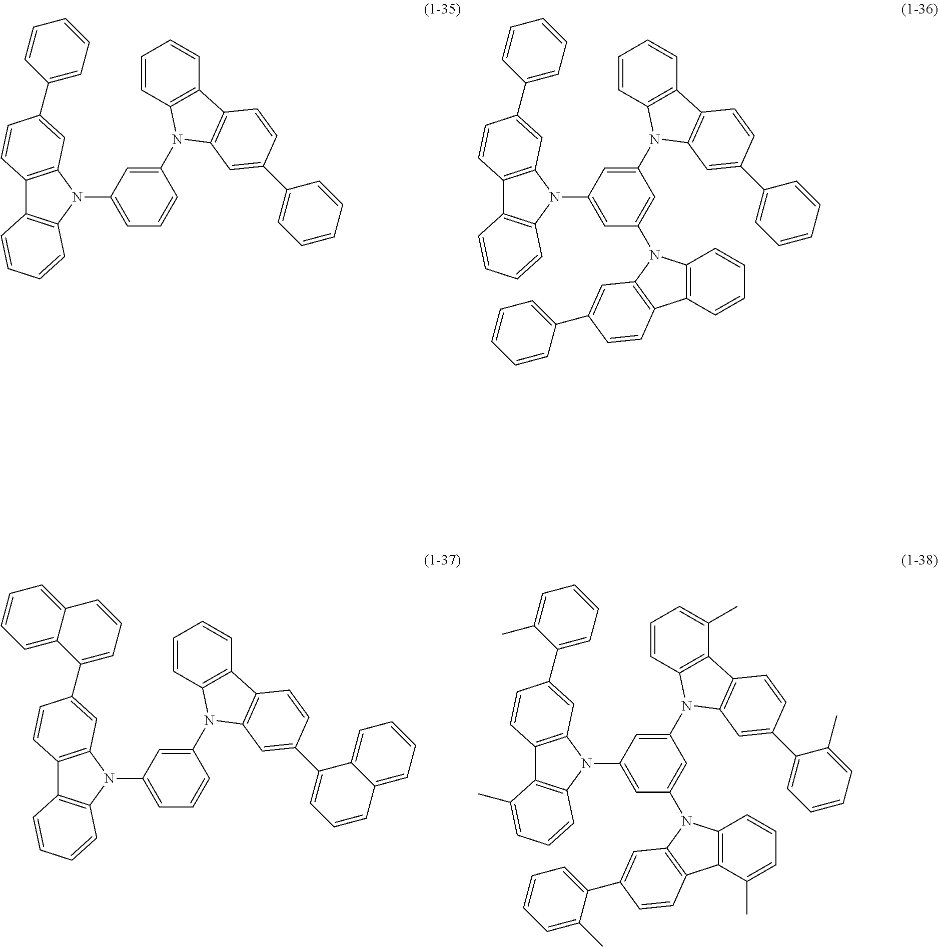 [SMILES: c1ccc(-c2ccc3c4ccccc4n(-c4cccc(-n5c6ccccc6c6ccc(-c7ccccc7)cc65)c4)c3c2)cc1 ; c1ccc(-c2ccc3c4ccccc4n(-c4cc(-n5c6ccccc6c6ccc(-c7ccccc7)cc65)cc(-n5c6ccccc6c6ccc(-c7ccccc7)cc65)c4)c3c2)cc1 ; c1cc(-n2c3ccccc3c3ccc(-c4cccc5ccccc45)cc32)cc(-n2c3ccccc3c3ccc(-c4cccc5ccccc45)cc32)c1 ; Cc1ccccc1-c1ccc2c3c(C)cccc3n(-c3cc(-n4c5cc(-c6ccccc6C)ccc5c5c(C)cccc54)cc(-n4c5cc(-c6ccccc6C)ccc5c5c(C)cccc54)c3)c2c1]

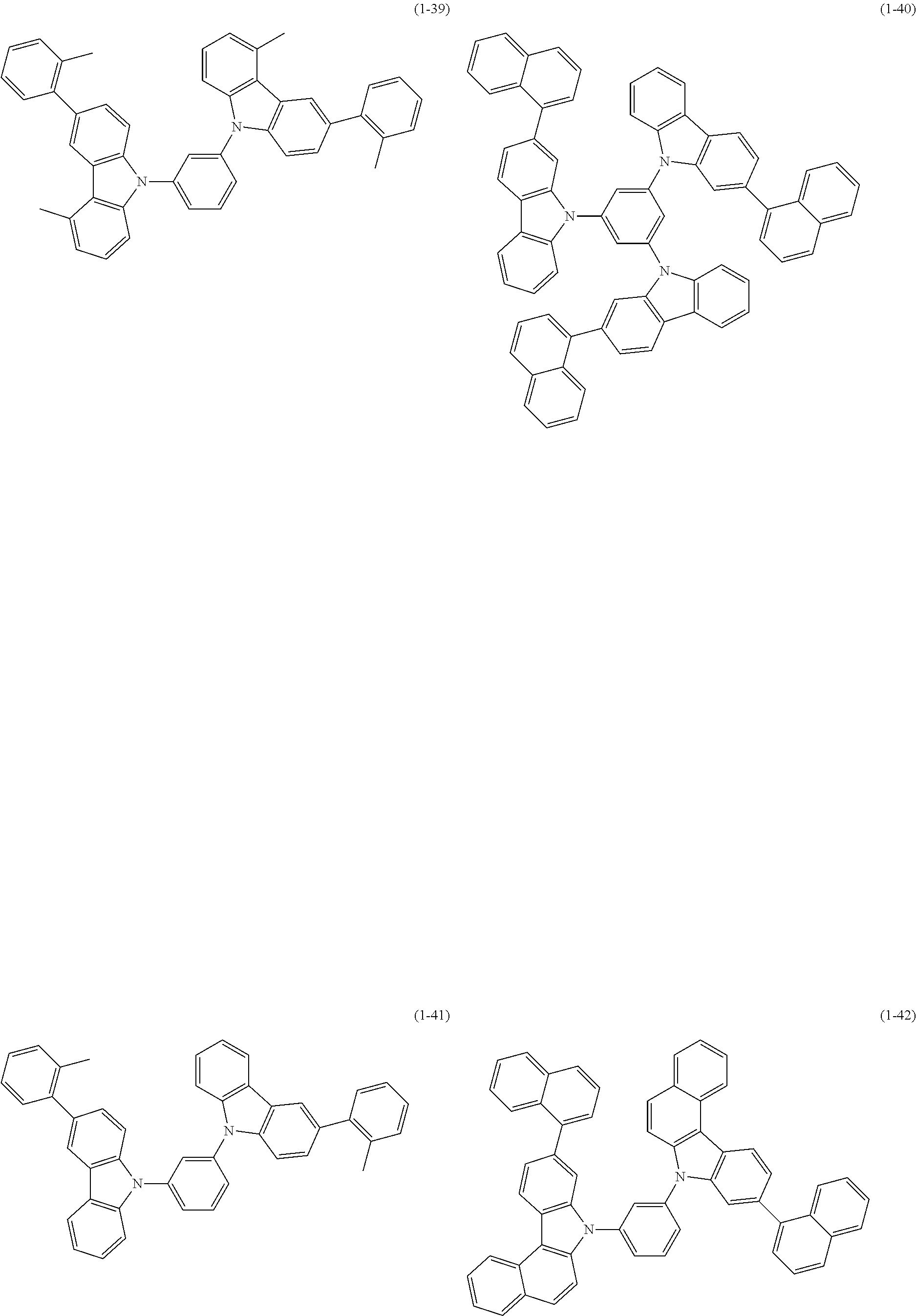 [SMILES: Cc1ccccc1-c1ccc2c(c1)c1c(C)cccc1n2-c1cccc(-n2c3ccc(-c4ccccc4C)cc3c3c(C)cccc32)c1 ; c1ccc2c(-c3ccc4c5ccccc5n(-c5cc(-n6c7ccccc7c7ccc(-c8cccc9ccccc89)cc76)cc(-n6c7ccccc7c7ccc(-c8cccc9ccccc89)cc76)c5)c4c3)cccc2c1 ; Cc1ccccc1-c1ccc2c(c1)c1ccccc1n2-c1cccc(-n2c3ccccc3c3cc(-c4ccccc4C)ccc32)c1 ; c1cc(-n2c3cc(-c4cccc5ccccc45)ccc3c3c4ccccc4ccc32)cc(-n2c3cc(-c4cccc5ccccc45)ccc3c3c4ccccc4ccc32)c1]

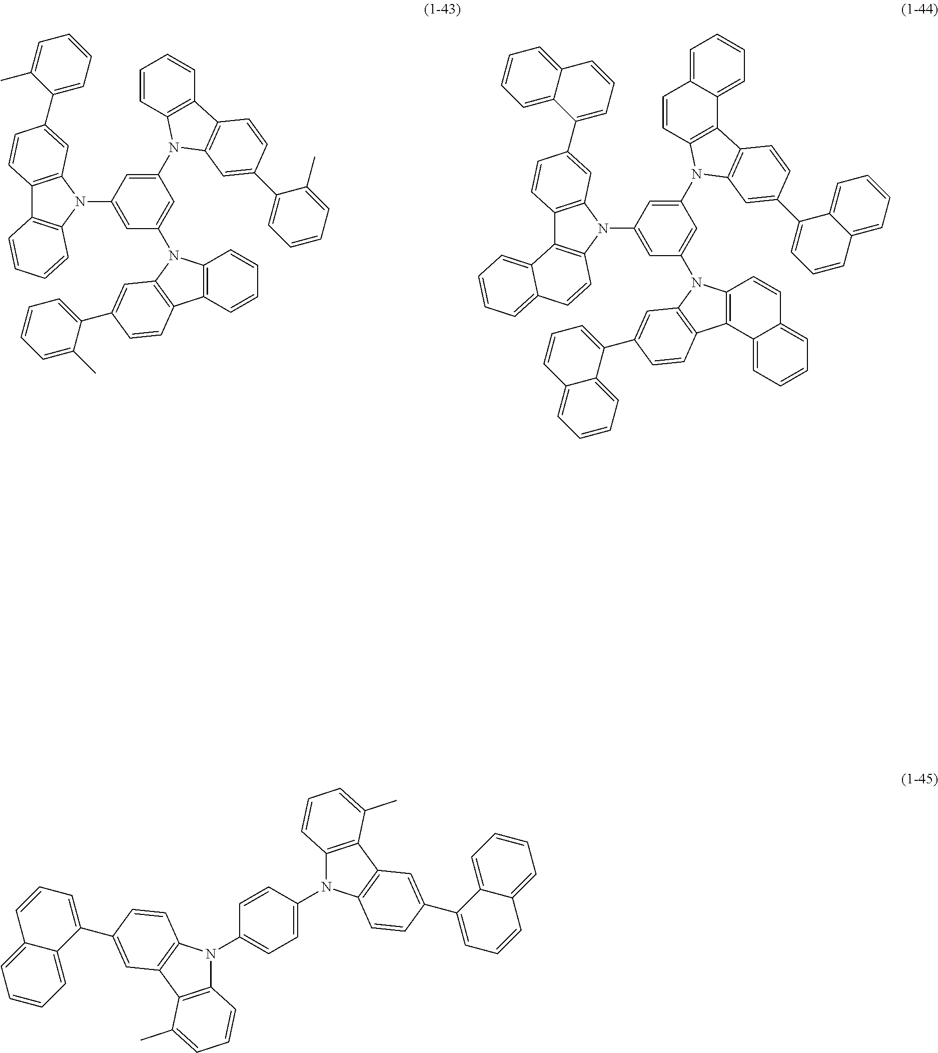 [SMILES: Cc1ccccc1-c1ccc2c3ccccc3n(-c3cc(-n4c5ccccc5c5ccc(-c6ccccc6C)cc54)cc(-n4c5ccccc5c5ccc(-c6ccccc6C)cc54)c3)c2c1 ; c1ccc2c(-c3ccc4c5c6ccccc6ccc5n(-c5cc(-n6c7cc(-c8cccc9ccccc89)ccc7c7c8ccccc8ccc76)cc(-n6c7cc(-c8cccc9ccccc89)ccc7c7c8ccccc8ccc76)c5)c4c3)cccc2c1 ; Cc1cccc2c1c1cc(-c3cccc4ccccc34)ccc1n2-c1ccc(-n2c3ccc(-c4cccc5ccccc45)cc3c3c(C)cccc32)cc1]

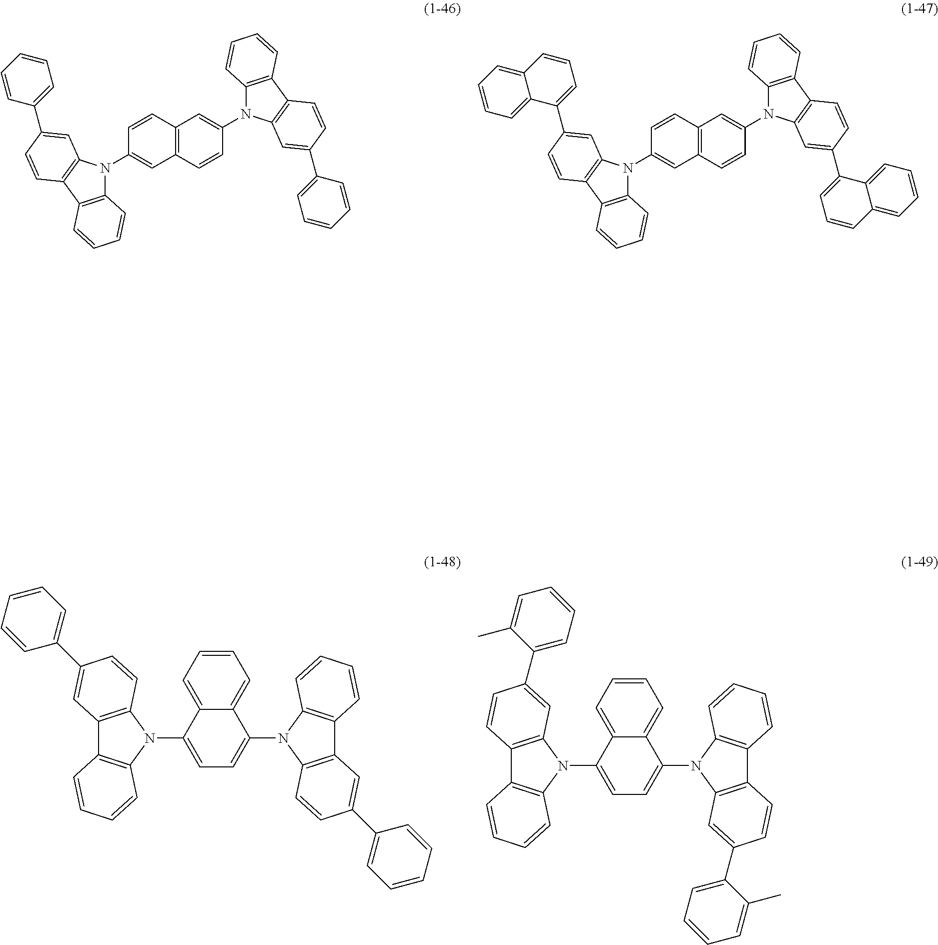

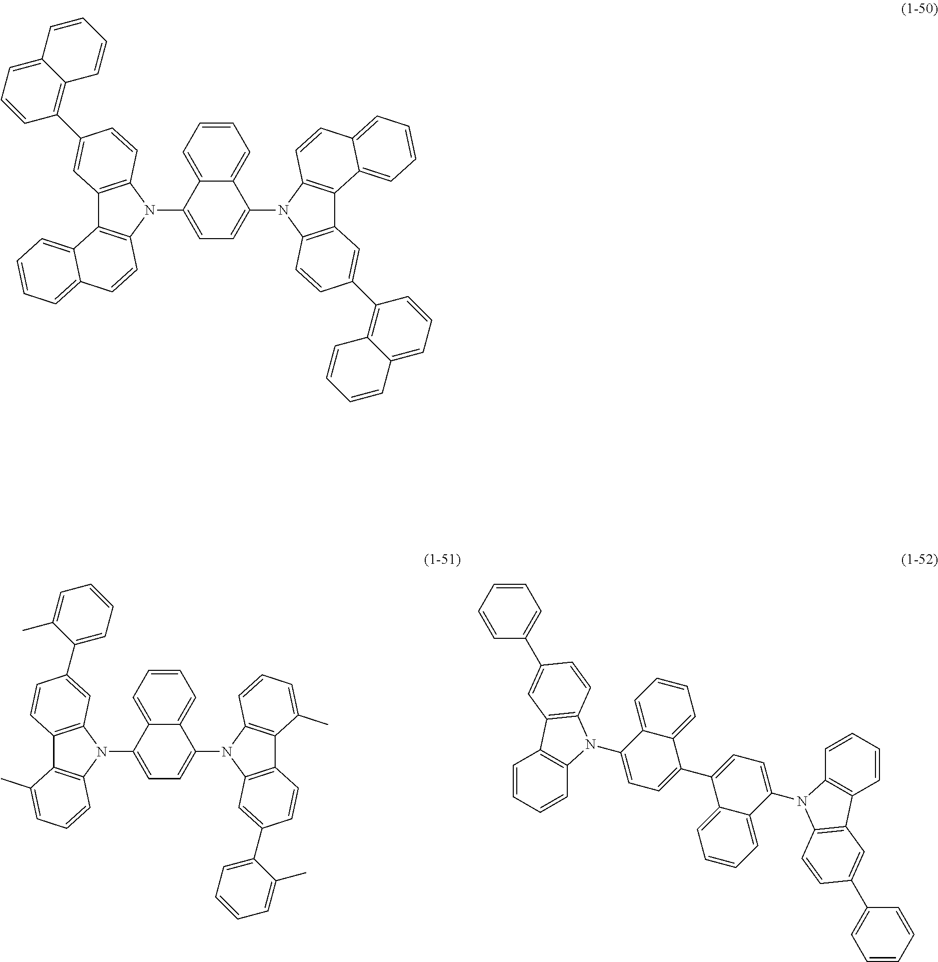

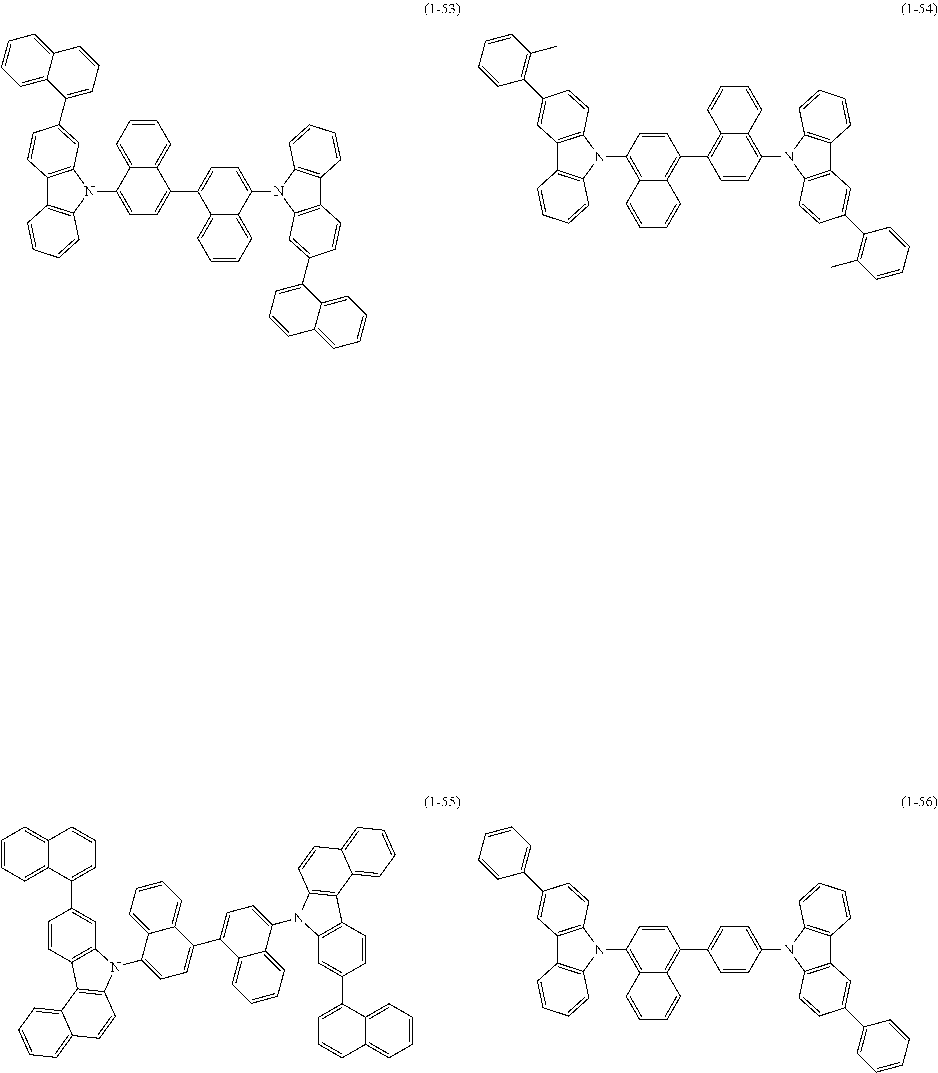 [SMILES: c1ccc2c(-c3ccc4c5ccccc5n(-c5ccc(-c6ccc(-n7c8ccccc8c8ccc(-c9cccc%10ccccc9%10)cc87)c7ccccc67)c6ccccc56)c4c3)cccc2c1 ; Cc1ccccc1-c1ccc2c(c1)c1ccccc1n2-c1ccc(-c2ccc(-n3c4ccccc4c4cc(-c5ccccc5C)ccc43)c3ccccc23)c2ccccc12 ; c1ccc2c(-c3ccc4c5c6ccccc6ccc5n(-c5ccc(-c6ccc(-n7c8cc(-c9cccc%10ccccc9%10)ccc8c8c9ccccc9ccc87)c7ccccc67)c6ccccc56)c4c3)cccc2c1 ; c1ccc(-c2ccc3c(c2)c2ccccc2n3-c2ccc(-c3ccc(-n4c5ccccc5c5cc(-c6ccccc6)ccc54)c4ccccc34)cc2)cc1]

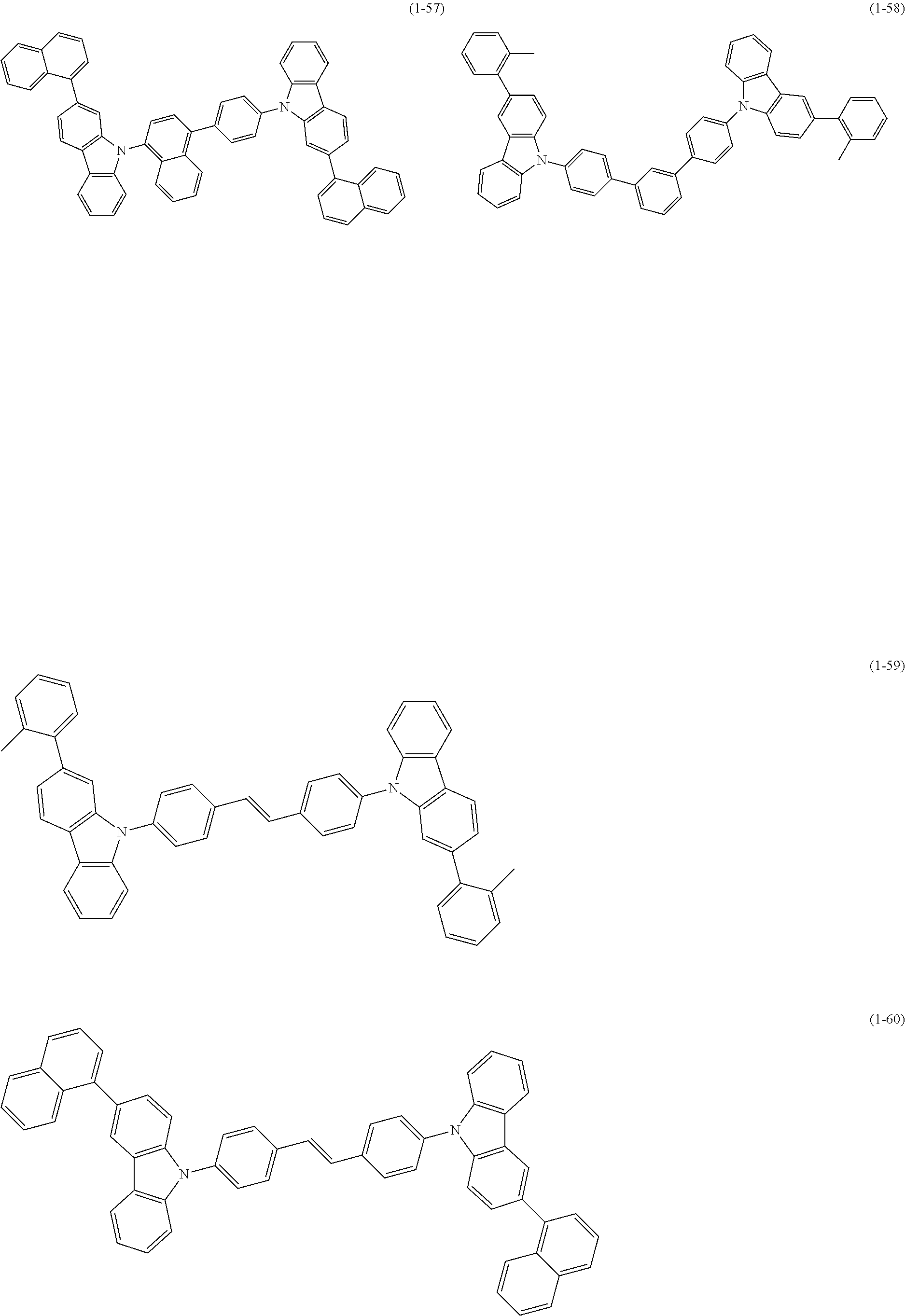

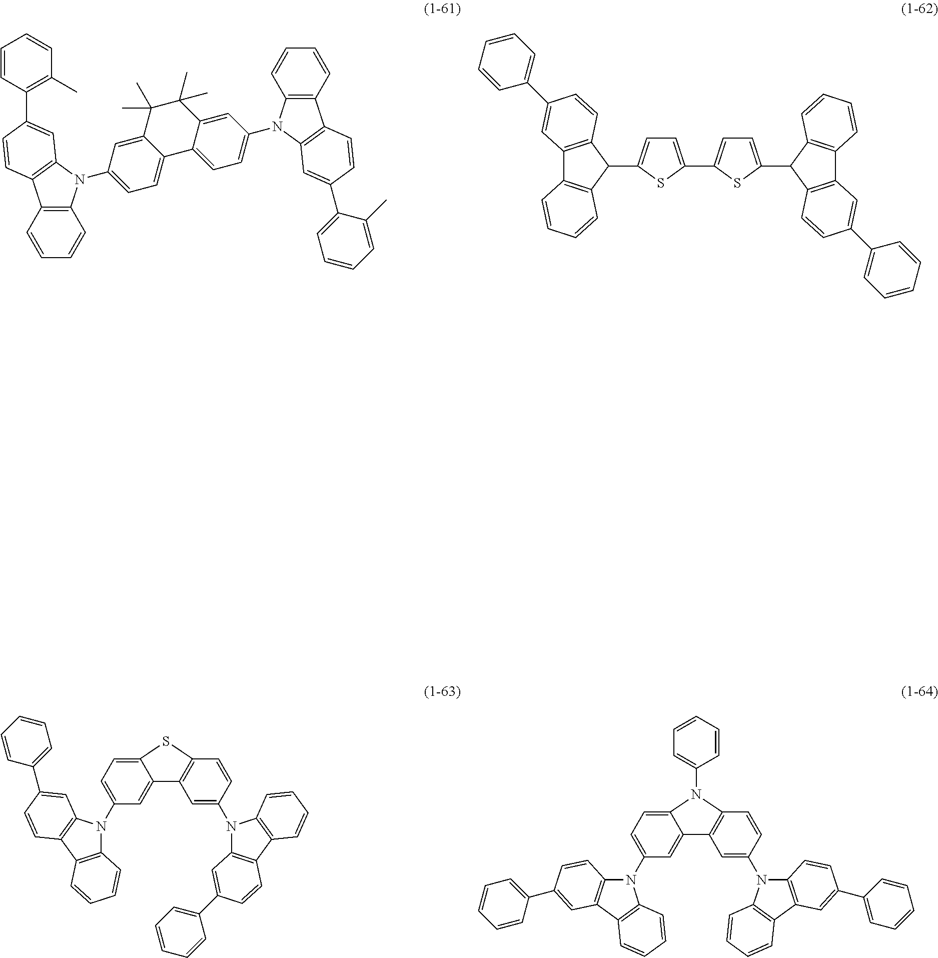 [SMILES: Cc1ccccc1-c1ccc2c3ccccc3n(-c3ccc4c(c3)C(C)(C)C(C)(C)c3cc(-n5c6ccccc6c6ccc(-c7ccccc7C)cc65)ccc3-4)c2c1 ; c1ccc(-c2ccc3c(c2)-c2ccccc2C3c2ccc(-c3ccc(C4c5ccccc5-c5cc(-c6ccccc6)ccc54)s3)s2)cc1 ; c1ccc(-c2ccc3c4ccccc4n(-c4ccc5sc6ccc(-n7c8ccccc8c8ccc(-c9ccccc9)cc87)cc6c5c4)c3c2)cc1 ; c1ccc(-c2ccc3c(c2)c2ccccc2n3-c2ccc3c(c2)c2cc(-n4c5ccccc5c5cc(-c6ccccc6)ccc54)ccc2n3-c2ccccc2)cc1]

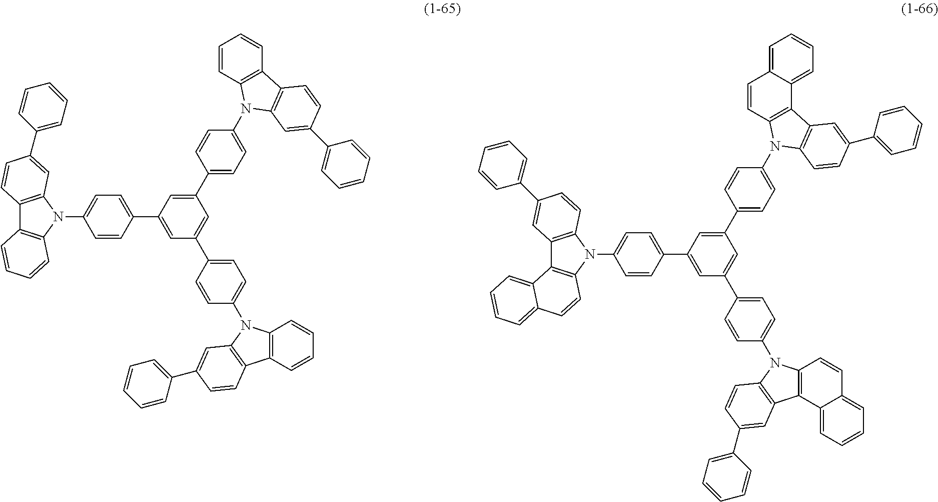 [SMILES: c1ccc(-c2ccc3c4ccccc4n(-c4ccc(-c5cc(-c6ccc(-n7c8ccccc8c8ccc(-c9ccccc9)cc87)cc6)cc(-c6ccc(-n7c8ccccc8c8ccc(-c9ccccc9)cc87)cc6)c5)cc4)c3c2)cc1 ; c1ccc(-c2ccc3c(c2)c2c4ccccc4ccc2n3-c2ccc(-c3cc(-c4ccc(-n5c6ccc(-c7ccccc7)cc6c6c7ccccc7ccc65)cc4)cc(-c4ccc(-n5c6ccc(-c7ccccc7)cc6c6c7ccccc7ccc65)cc4)c3)cc2)cc1]

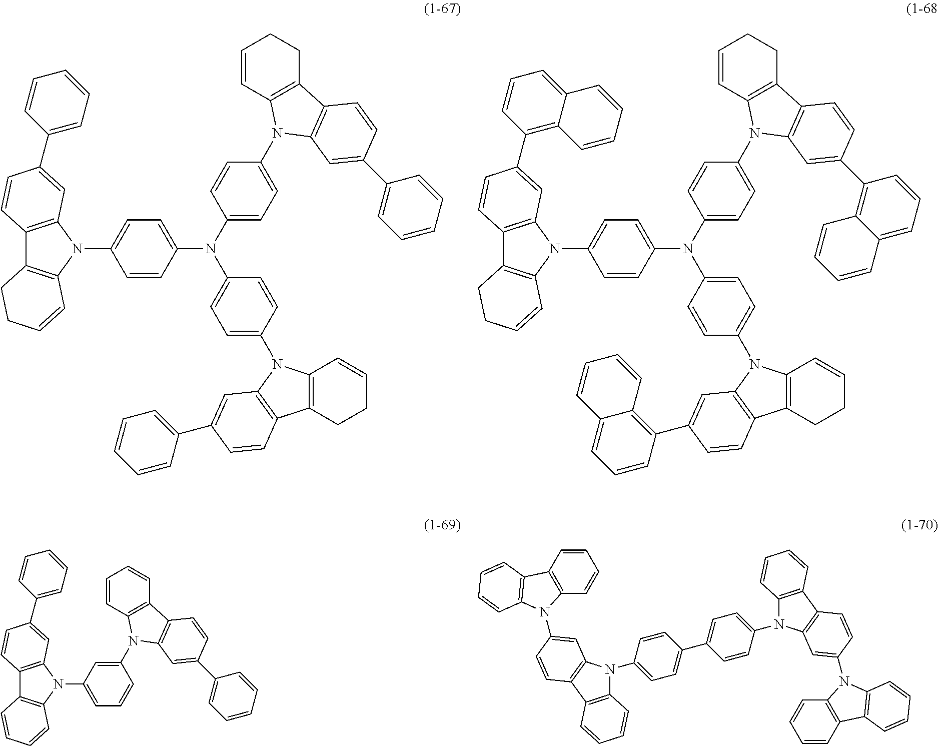

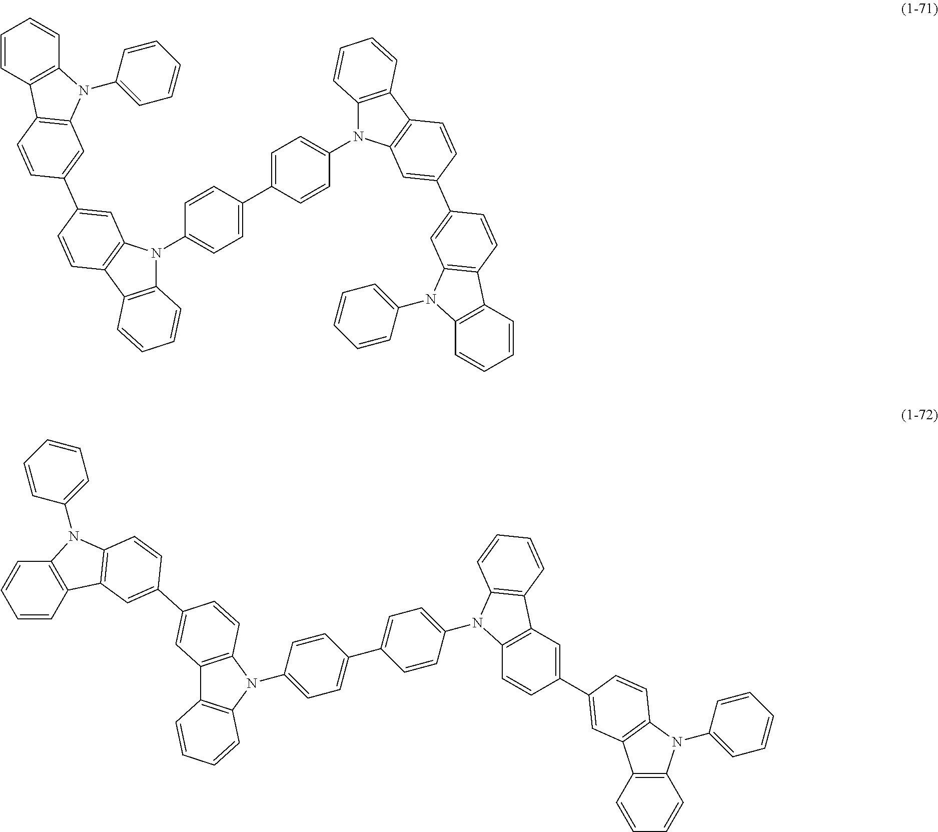 [SMILES: c1ccc(-n2c3ccccc3c3ccc(-c4ccc5c6ccccc6n(-c6ccc(-c7ccc(-n8c9ccccc9c9ccc(-c%10ccc%11c%12ccccc%12n(-c%12ccccc%12)c%11c%10)cc98)cc7)cc6)c5c4)cc32)cc1 ; c1ccc(-n2c3ccccc3c3cc(-c4ccc5c(c4)c4ccccc4n5-c4ccc(-c5ccc(-n6c7ccccc7c7cc(-c8ccc9c(c8)c8ccccc8n9-c8ccccc8)ccc76)cc5)cc4)ccc32)cc1]

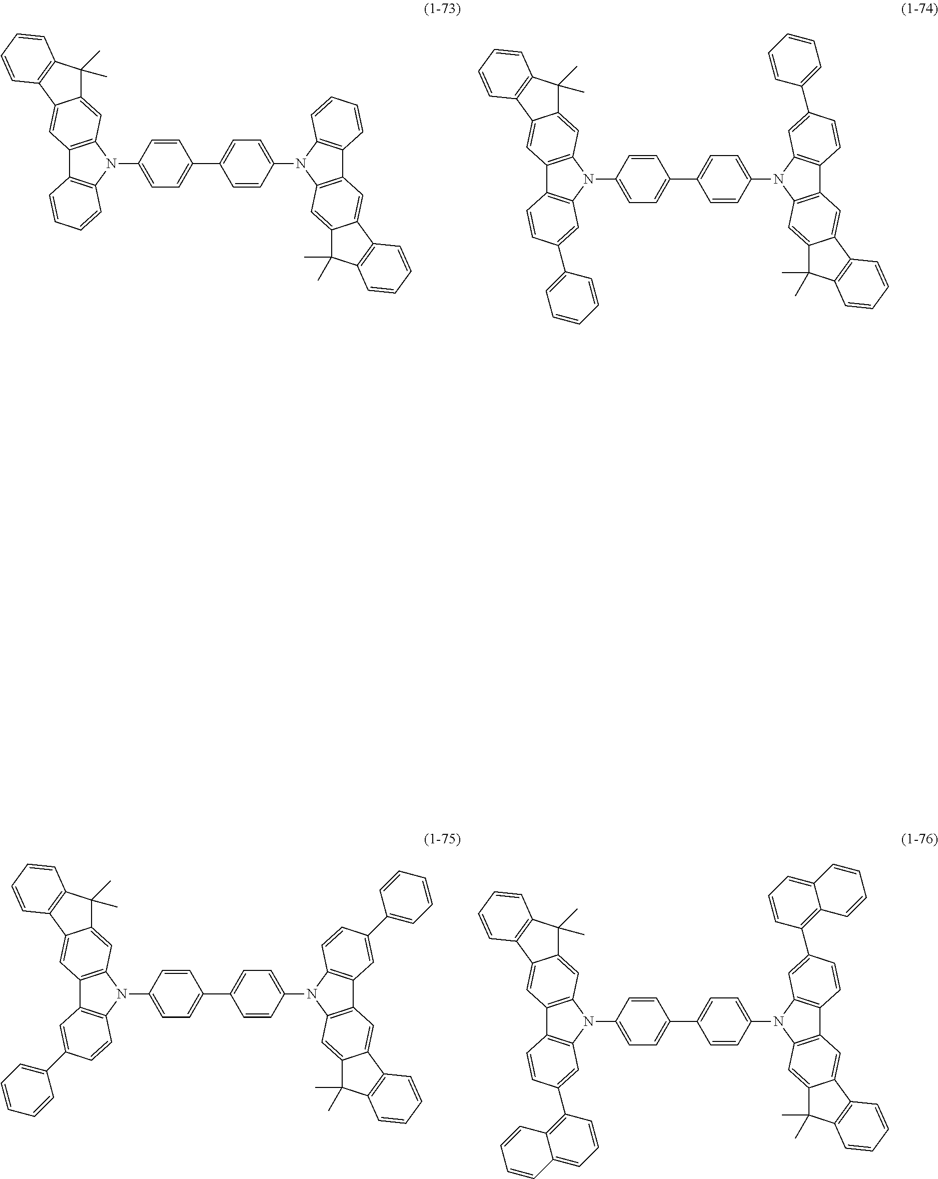 [SMILES: CC1(C)c2ccccc2-c2cc3c4ccccc4n(-c4ccc(-c5ccc(-n6c7ccccc7c7cc8c(cc76)C(C)(C)c6ccccc6-8)cc5)cc4)c3cc21 ; CC1(C)c2ccccc2-c2cc3c4ccc(-c5ccccc5)cc4n(-c4ccc(-c5ccc(-n6c7cc(-c8ccccc8)ccc7c7cc8c(cc76)C(C)(C)c6ccccc6-8)cc5)cc4)c3cc21 ; CC1(C)c2ccccc2-c2cc3c4cc(-c5ccccc5)ccc4n(-c4ccc(-c5ccc(-n6c7ccc(-c8ccccc8)cc7c7cc8c(cc76)C(C)(C)c6ccccc6-8)cc5)cc4)c3cc21 ; CC1(C)c2ccccc2-c2cc3c4ccc(-c5cccc6ccccc56)cc4n(-c4ccc(-c5ccc(-n6c7cc(-c8cccc9ccccc89)ccc7c7cc8c(cc76)C(C)(C)c6ccccc6-8)cc5)cc4)c3cc21]

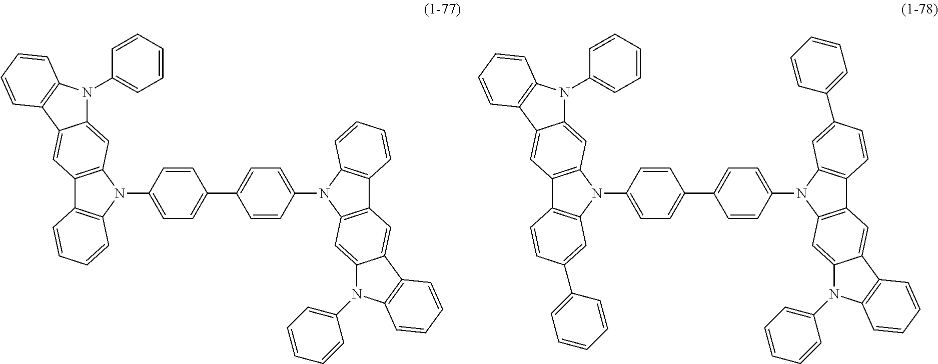 [SMILES: c1ccc(-n2c3ccccc3c3cc4c5ccccc5n(-c5ccc(-c6ccc(-n7c8ccccc8c8cc9c%10ccccc%10n(-c%10ccccc%10)c9cc87)cc6)cc5)c4cc32)cc1 ; c1ccc(-c2ccc3c4cc5c6ccccc6n(-c6ccccc6)c5cc4n(-c4ccc(-c5ccc(-n6c7cc(-c8ccccc8)ccc7c7cc8c9ccccc9n(-c9ccccc9)c8cc76)cc5)cc4)c3c2)cc1]

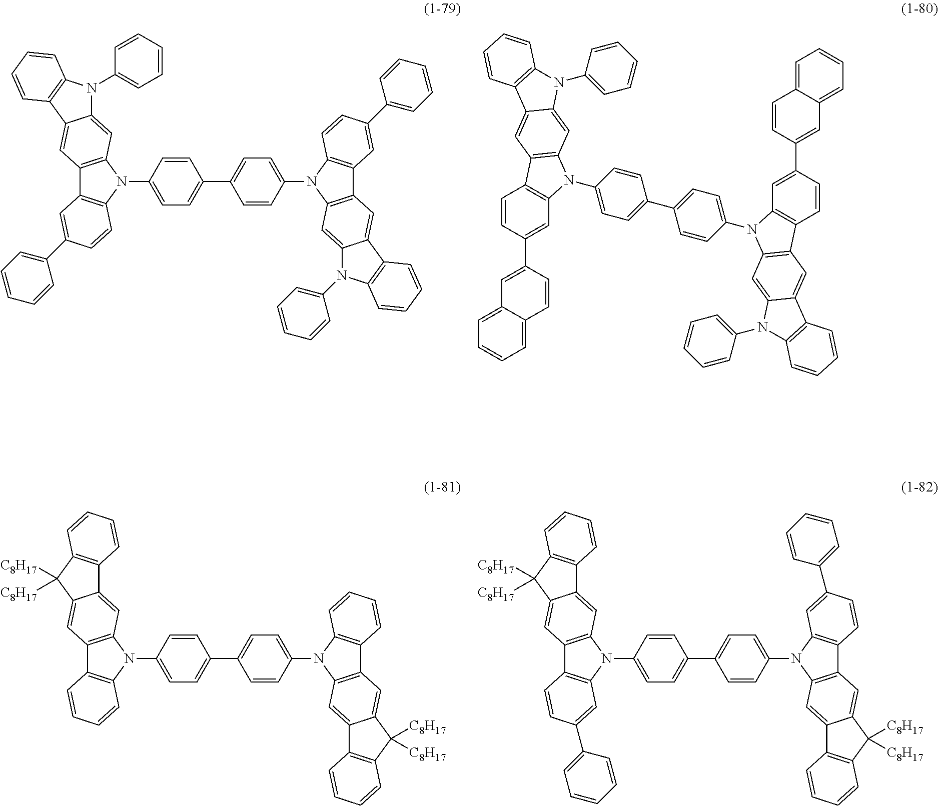

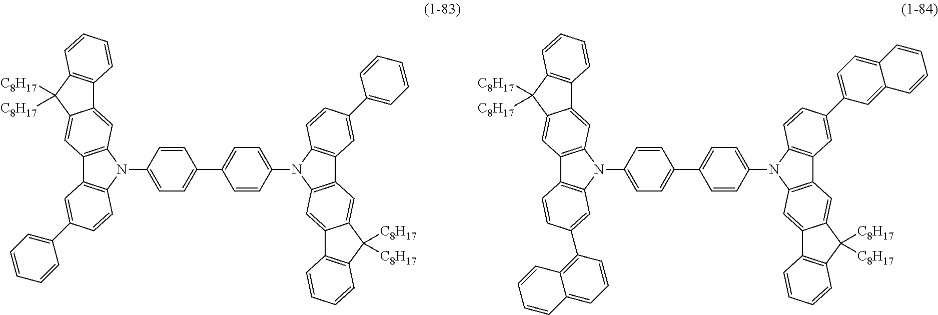

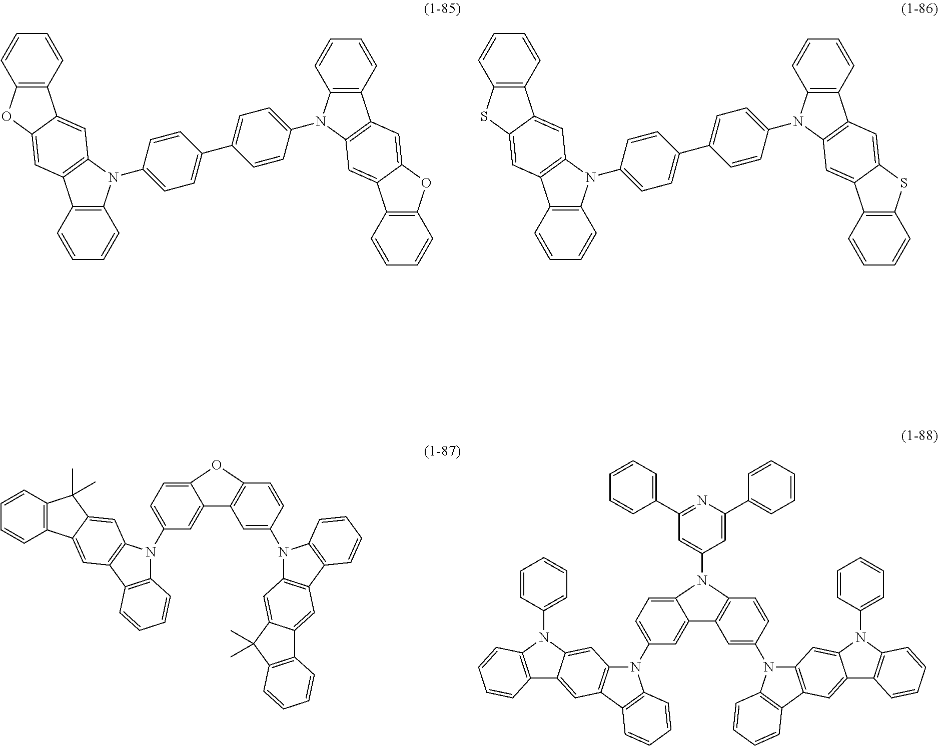 [SMILES: c1ccc2c(c1)oc1cc3c4ccccc4n(-c4ccc(-c5ccc(-n6c7ccccc7c7cc8oc9ccccc9c8cc76)cc5)cc4)c3cc12 ; c1ccc2c(c1)sc1cc3c4ccccc4n(-c4ccc(-c5ccc(-n6c7ccccc7c7cc8sc9ccccc9c8cc76)cc5)cc4)c3cc12 ; CC1(C)c2ccccc2-c2cc3c4ccccc4n(-c4ccc5oc6ccc(-n7c8ccccc8c8cc9c(cc87)C(C)(C)c7ccccc7-9)cc6c5c4)c3cc21 ; c1ccc(-c2cc(-n3c4ccc(-n5c6ccccc6c6cc7c8ccccc8n(-c8ccccc8)c7cc65)cc4c4cc(-n5c6ccccc6c6cc7c8ccccc8n(-c8ccccc8)c7cc65)ccc43)cc(-c3ccccc3)n2)cc1]

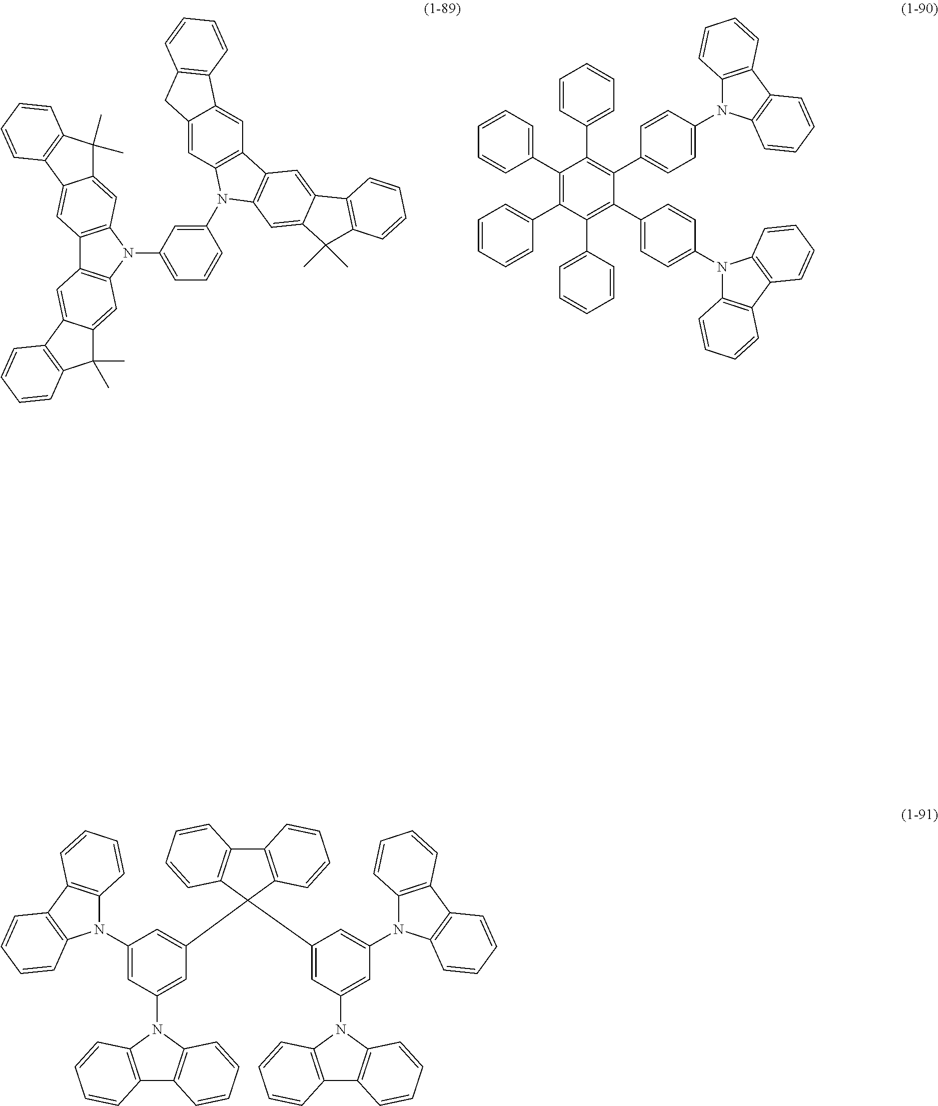 [SMILES: CC1(C)c2ccccc2-c2cc3c4cc5c(cc4n(-c4cccc(-n6c7cc8c(cc7c7cc9c(cc76)C(C)(C)c6ccccc6-9)-c6ccccc6C8(C)C)c4)c3cc21)Cc1ccccc1-5 ; c1ccc(-c2c(-c3ccccc3)c(-c3ccccc3)c(-c3ccc(-n4c5ccccc5c5ccccc54)cc3)c(-c3ccc(-n4c5ccccc5c5ccccc54)cc3)c2-c2ccccc2)cc1 ; c1ccc2c(c1)-c1ccccc1C2(c1cc(-n2c3ccccc3c3ccccc32)cc(-n2c3ccccc3c3ccccc32)c1)c1cc(-n2c3ccccc3c3ccccc32)cc(-n2c3ccccc3c3ccccc32)c1]

The carbazole compounds employed in accordance with the invention can be synthesised by standard methods of organic chemistry, as disclosed in detail, for example, in WO 2008/086851. The contents of this specification are incorporated into the present application by way of reference.

Thus, it is known that 2-nitrobiphenyl derivatives can be reacted with a trialkyl phosphite to give the corresponding carbazole derivatives (M. Tavasli et al., Synthesis 2005, 1619-1624). This reaction can be used to build up 2-aryl-substituted carbazole derivatives by firstly building up a corresponding aryl-substituted 2-nitrobiphenyl derivative, which is subsequently reacted with trialkyl phosphite. The 2-aryl-substituted carbazole derivative can be coupled to a dibromoaromatic compound in a Hartwig-Buchwald coupling under standard conditions to give the compound of the formula (1). The various methods and reaction conditions for carrying out the Hartwig-Buchwald coupling are known to the person skilled in the art of organic synthesis. Instead of a dibromoaromatic compound, it is also possible to use corresponding compounds containing other leaving groups, for example chlorine, iodine, triflate, tosylate or generally sulfonates. The use of trisubstituted aromatic compounds or compounds containing even more leaving groups correspondingly enables the synthesis of compounds of the formula (1) in which the index q stands for 2 or more.

The synthesis of compounds of the formula (1) is depicted in the following Scheme 1, where, for clarity, q has been selected to be =1 and no substituents R or R¹ are depicted:

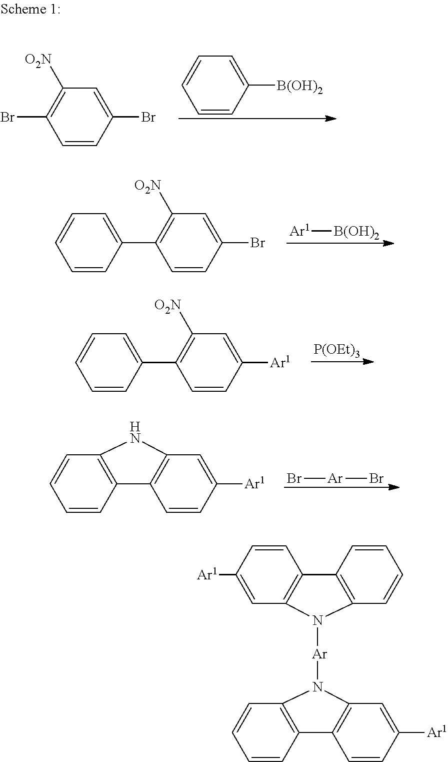

In accordance with an embodiment, the formulation according to the invention comprises a ketone compound, preferably an aromatic ketone compound. In an embodiment of the present invention, the ketone compound is preferably a compound of the following formula (2):

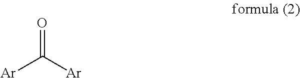

where the following applies to the symbols used:
Ar is on each occurrence, identically or differently, an aromatic or heteroaromatic ring system having 5 to 60 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C=Se, C═NR², P(═O)(R²), SO, SO₂, NR², O, S or CONR² and where one or more H atoms may be replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or a combination of these systems; two or more adjacent substituents R¹ here may also form a mono- or polycyclic, aliphatic, aromatic or heteroaromatic ring system with one another;
Ar¹ is on each occurrence, identically or differently, an aromatic or heteroaromatic ring system having 5 to 40 aromatic ring atoms, which may be substituted by one or more radicals R²;
R² is on each occurrence, identically or differently, H, D, CN or an aliphatic, aromatic and/or heteroaromatic hydrocarbon radical having 1 to 20 C atoms, in which, in addition, H atoms may be replaced by F; two or more adjacent substituents R² here may also form a mono- or polycyclic, aliphatic, aromatic or heteroaromatic ring system with one another.

Suitable compounds of the formula (2) are, in particular, the ketones disclosed in WO 04/093207 and in DE 102008033943. These are incorporated into the present application by way of reference.

It is evident from the definition of the compound of the formula (2) that this does not have to contain only one carbonyl group, but instead may also contain a plurality of these groups.

The group Ar in the ketone compounds of the formula (2) is preferably an aromatic ring system having 6 to 40 aromatic ring atoms, i.e. it contains no heteroaryl groups. As defined above, the aromatic ring system does not necessarily have to contain only aromatic groups, but instead two aryl groups may also be interrupted by a non-aromatic group, for example by a further carbonyl group.

In a further preferred embodiment of the present invention, the group Ar of the ketone compound has not more than two condensed rings. It is thus preferably built up only from phenyl and/or naphthyl groups, particularly preferably only from phenyl groups, but does not contain any larger condensed aromatic systems, such as, for example, anthracene.

Preferred groups Ar which are bonded to the carbonyl group of the ketone compound are phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2″-p-terphenyl, 2″-, 4′- or 5″-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthylnaphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridazinyl, 2-(1,3,5-triazin)yl-, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals.

The groups Ar may, as described above, be substituted by one or more radicals R¹. These radicals R¹ of the ketone compound are preferably selected, identically or differently on each occurrence, from the group consisting of H, F, C(═O)Ar¹, P(═O)(Ar¹)₂, S(═O)Ar¹, S(═O)₂Ar¹, a straight-chain alkyl group having 1 to 4 C atoms or a branched or cyclic alkyl group having 3 to 5 C atoms, each of which may be substituted by one or more radicals R², where one or more H atoms may be replaced by F, or an aromatic ring system having 6 to 24 aromatic ring atoms, which may be substituted by one or more radicals R², or a combination of these systems; two or more adjacent substituents R¹ here may also form a mono- or polycyclic, aliphatic, aromatic or heteroaromatic ring system with one another.

Since the formulation is applied as a solution, straight-chain, branched or cyclic alkyl groups having up to 10 C atoms are also preferred as substituents R¹. The radicals R¹ are particularly preferably selected, identically or differently on each occurrence, from the group consisting of H, C(═O)Ar¹ or an aromatic ring system having 6 to 24 aromatic ring atoms, which may be substituted by one or more radicals R², but is preferably unsubstituted.

In a further preferred embodiment of the present invention, the group Ar¹ of the ketone compound is, identically or differently on each occurrence, an aromatic ring system having 6 to 24 aromatic ring atoms, which may be substituted by one or more radicals R². Ar¹ is particularly preferably, identically or differently on each occurrence, an aromatic ring system having 6 to 12 aromatic ring atoms.

Particular preference is given to benzophenone derivatives which are substituted at each of the 3,5,3′,5′-positions by an aromatic or heteroaromatic ring system having 5 to 30 aromatic ring atoms, which may in turn be substituted by one or more radicals R¹ as defined above. Preference is furthermore given to ketones which are substituted by at least one spirobifluorene group.

Preferred aromatic ketones are therefore the compounds of the following formula (3) to (6),

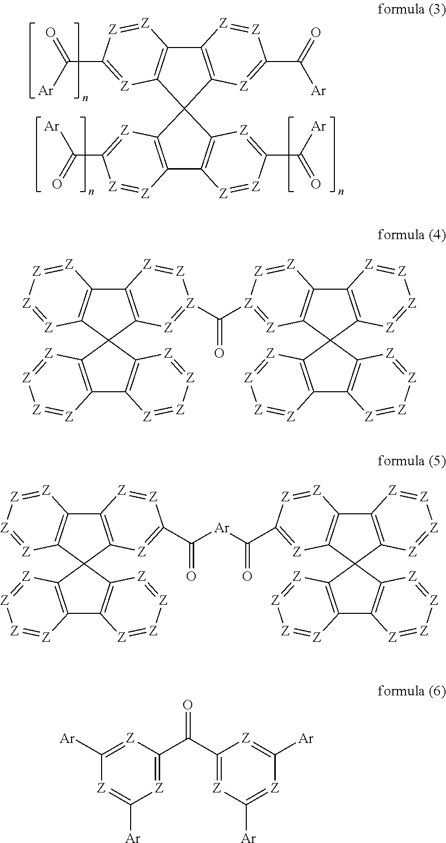

where Ar and R¹ have the same meaning as described above for the ketone compound (formula (2)), and furthermore:
Z is, identically or differently on each occurrence, CR¹ or N;
n is, identically or differently on each occurrence, 0 or 1.

Ar in the above-mentioned formulae (3), (5) and (6) preferably stands for an aromatic or heteroaromatic ring system having 1 to 30 aromatic ring atoms, which may be substituted by one or more radicals R¹. Particular preference is given to the above-mentioned groups Ar.

Examples of preferred compounds of the formula (2) are compounds (2-1) to (2-70) depicted below.

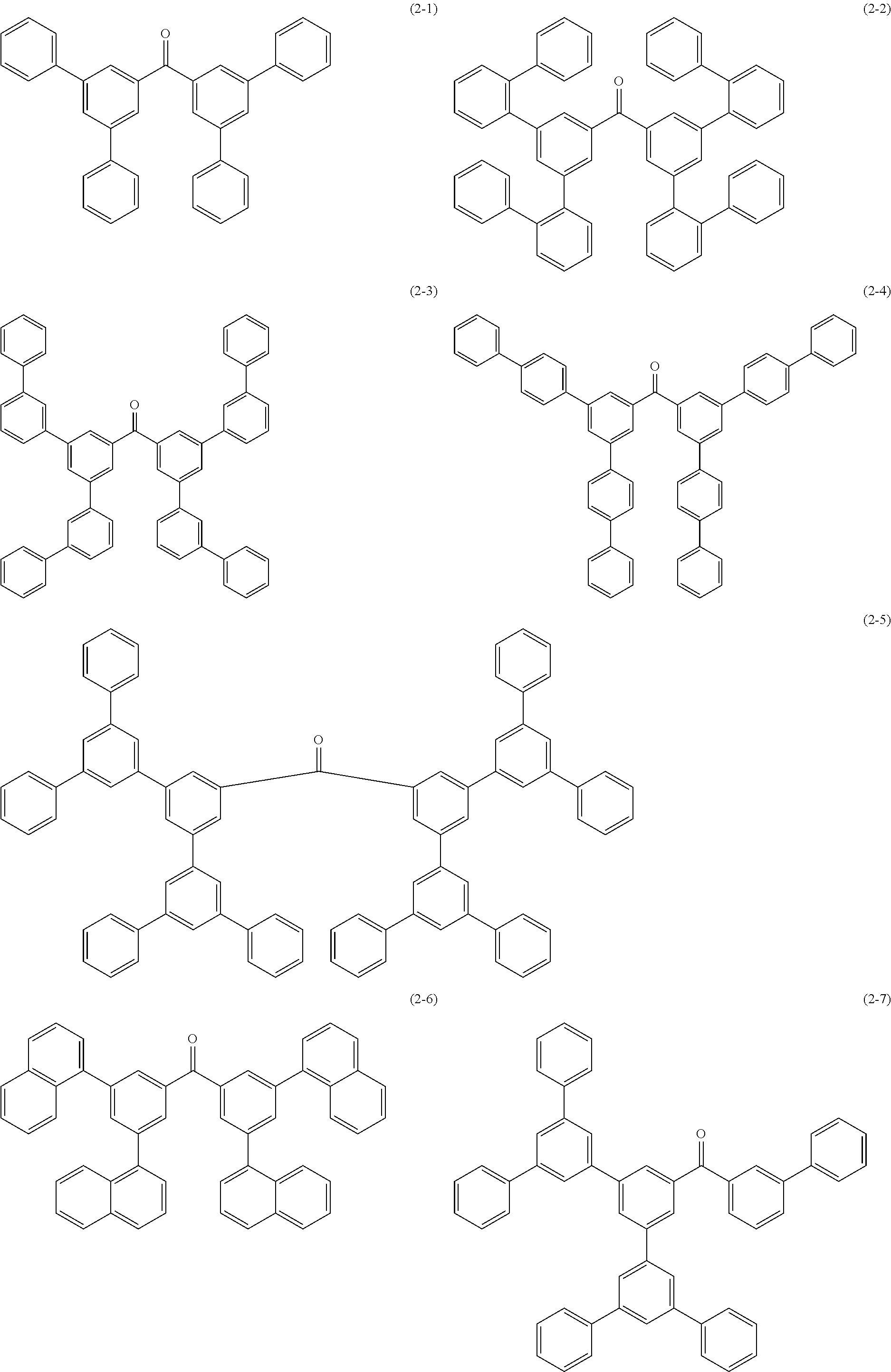

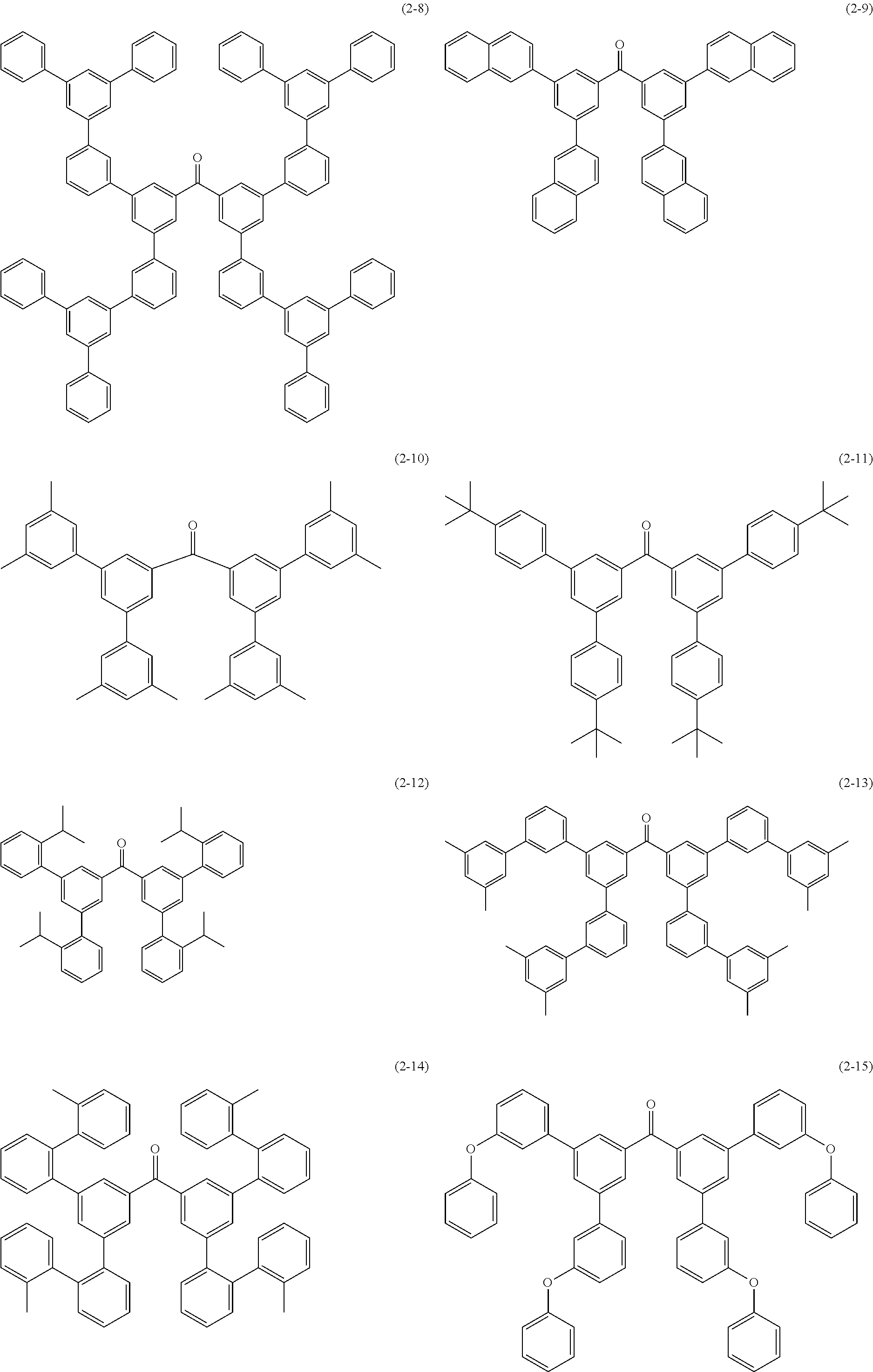

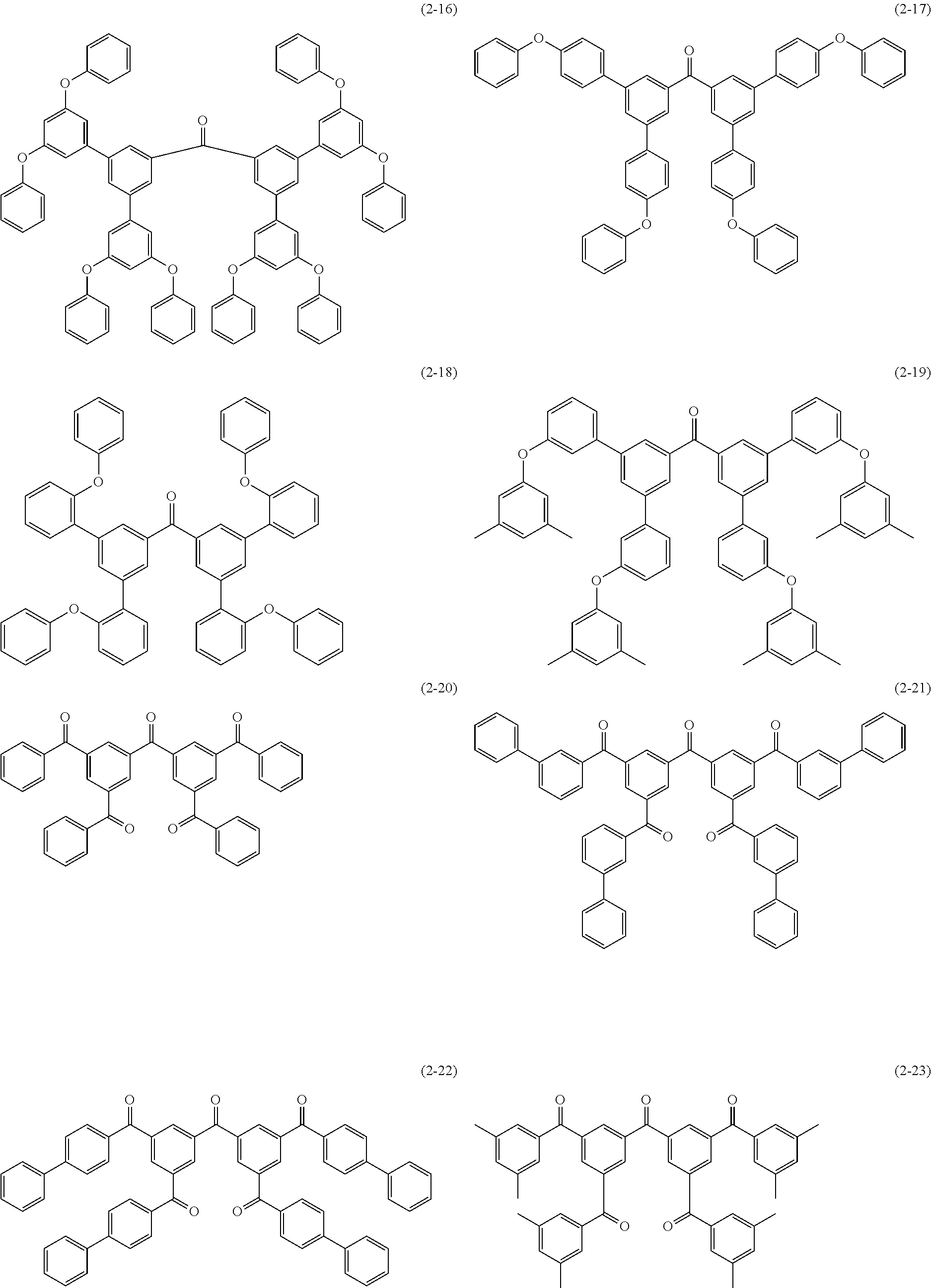

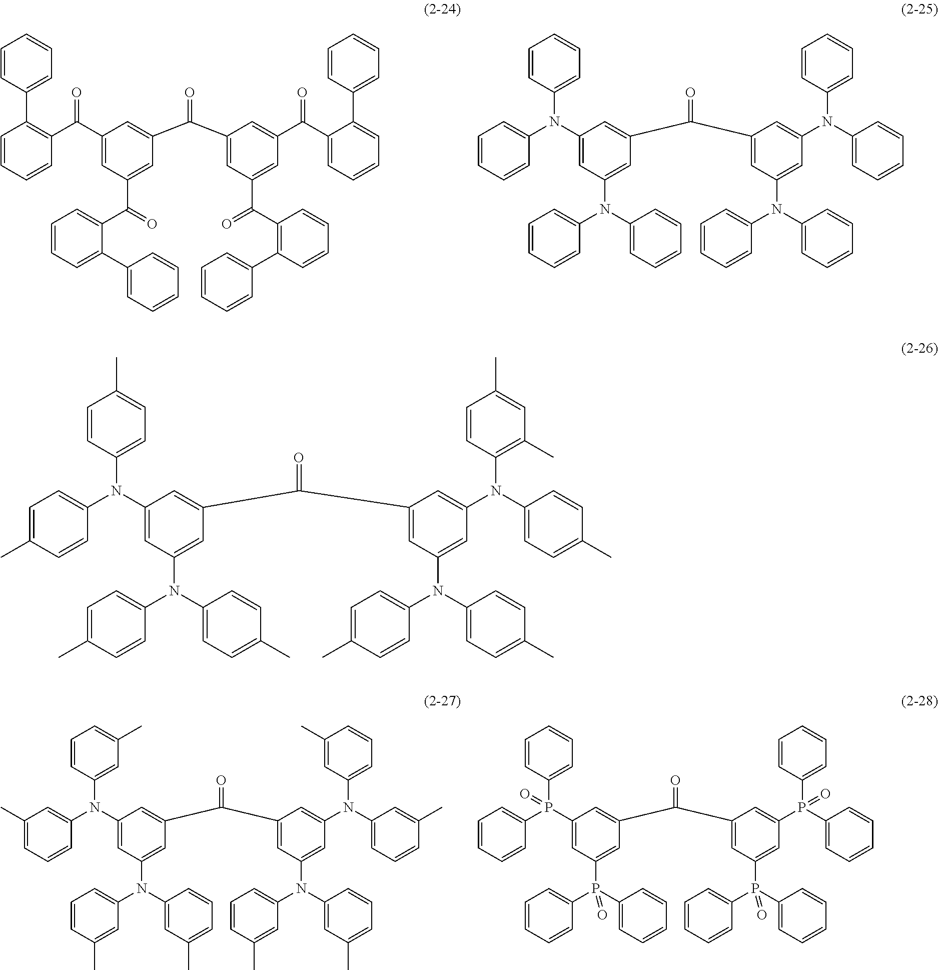

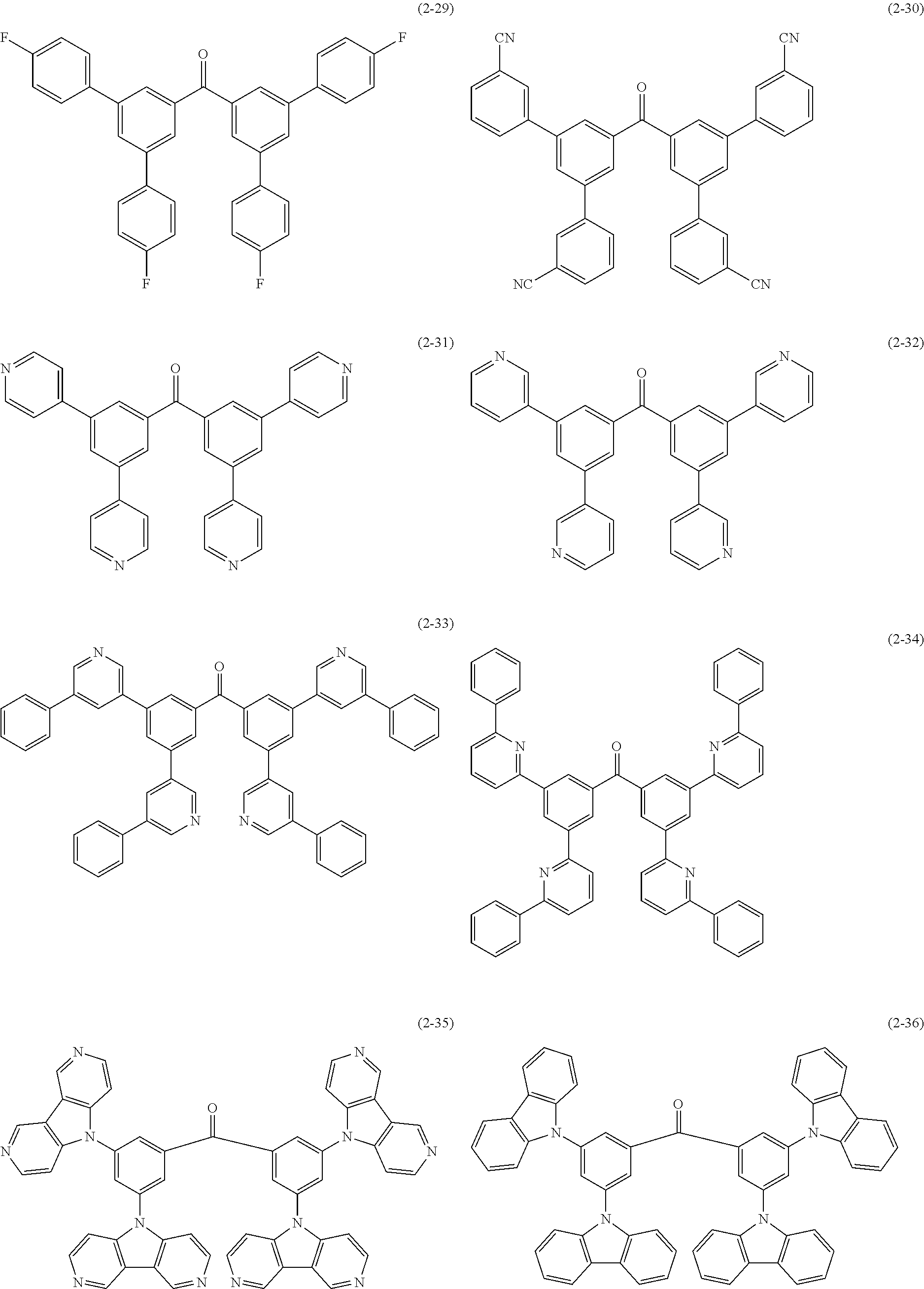

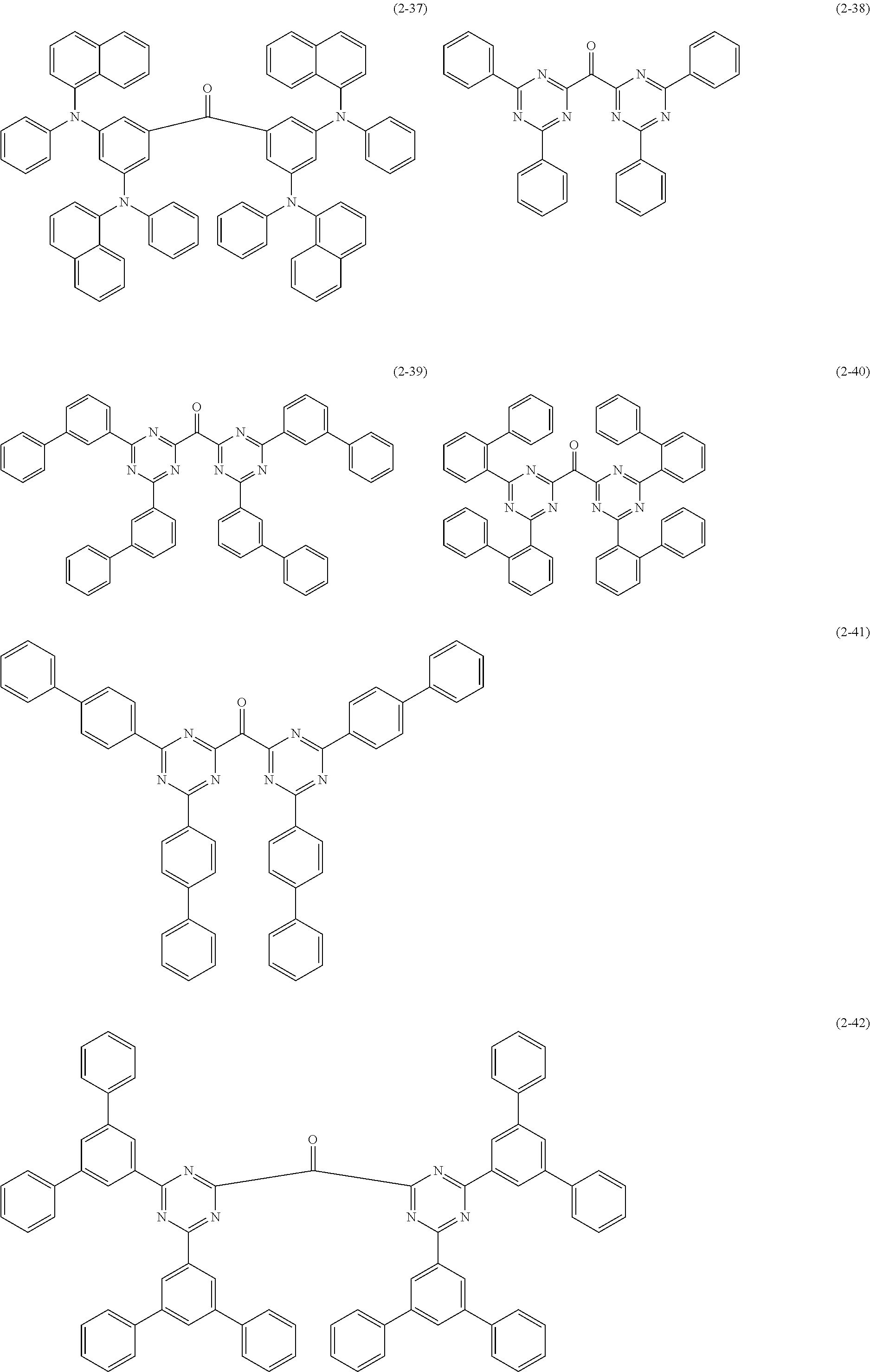

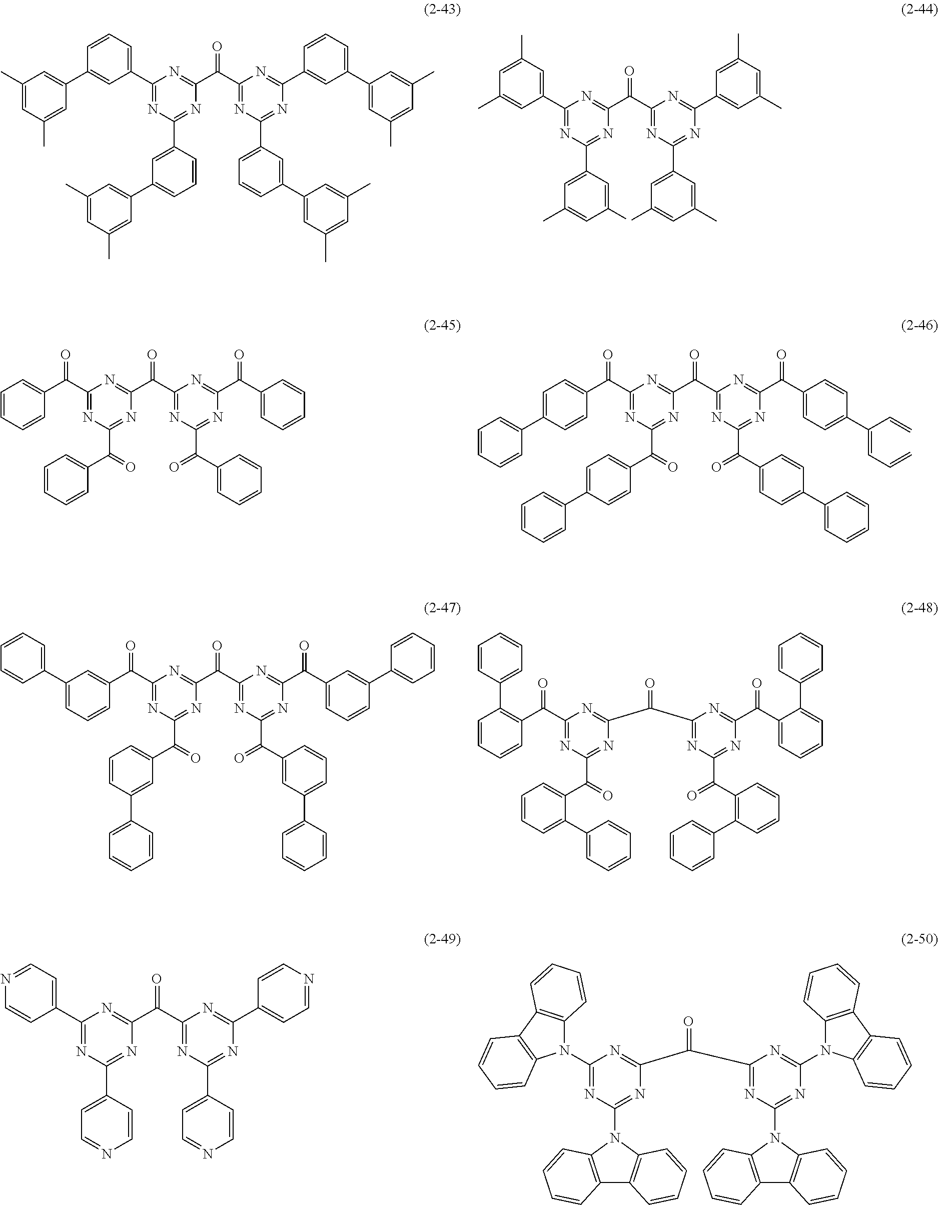

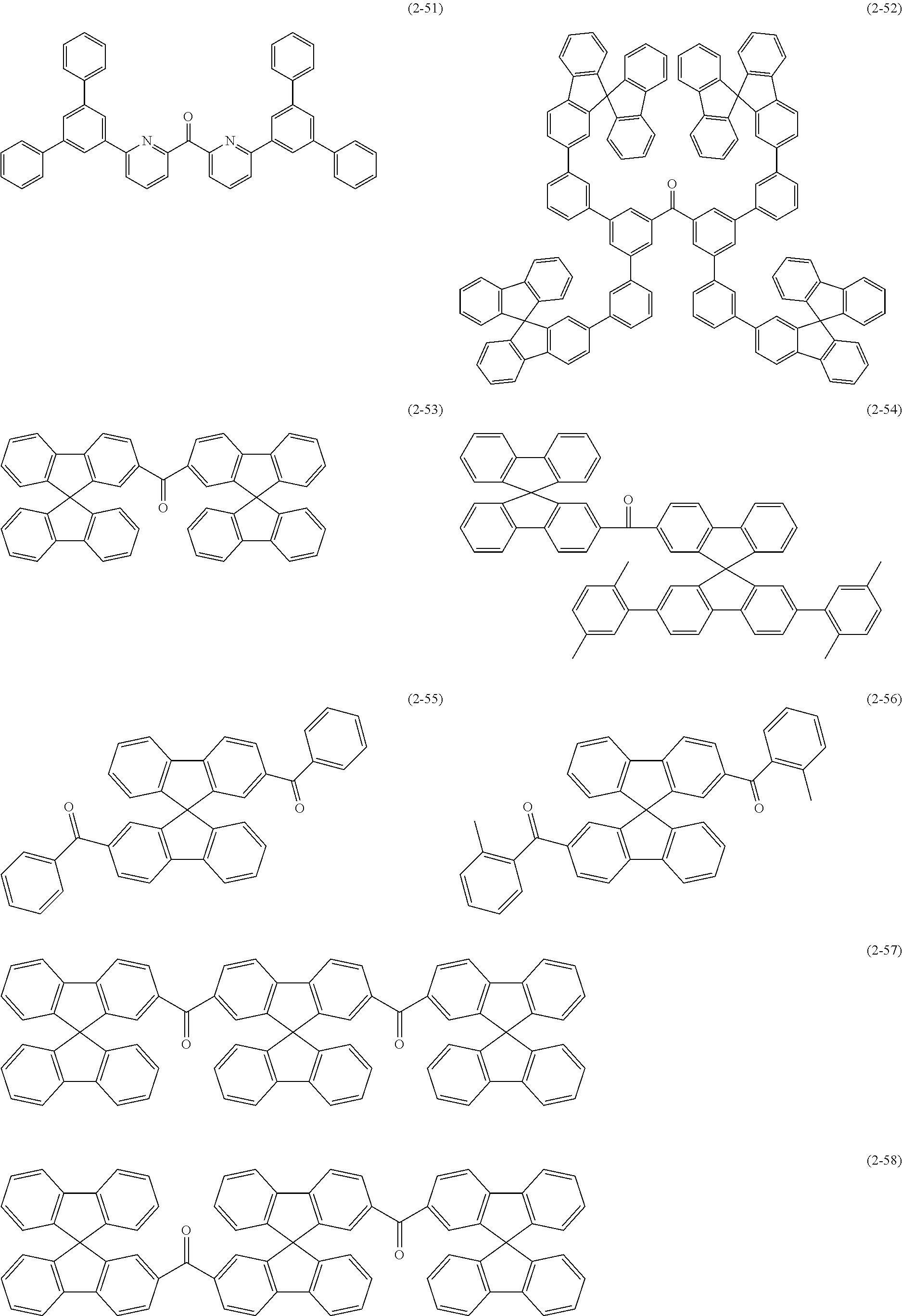

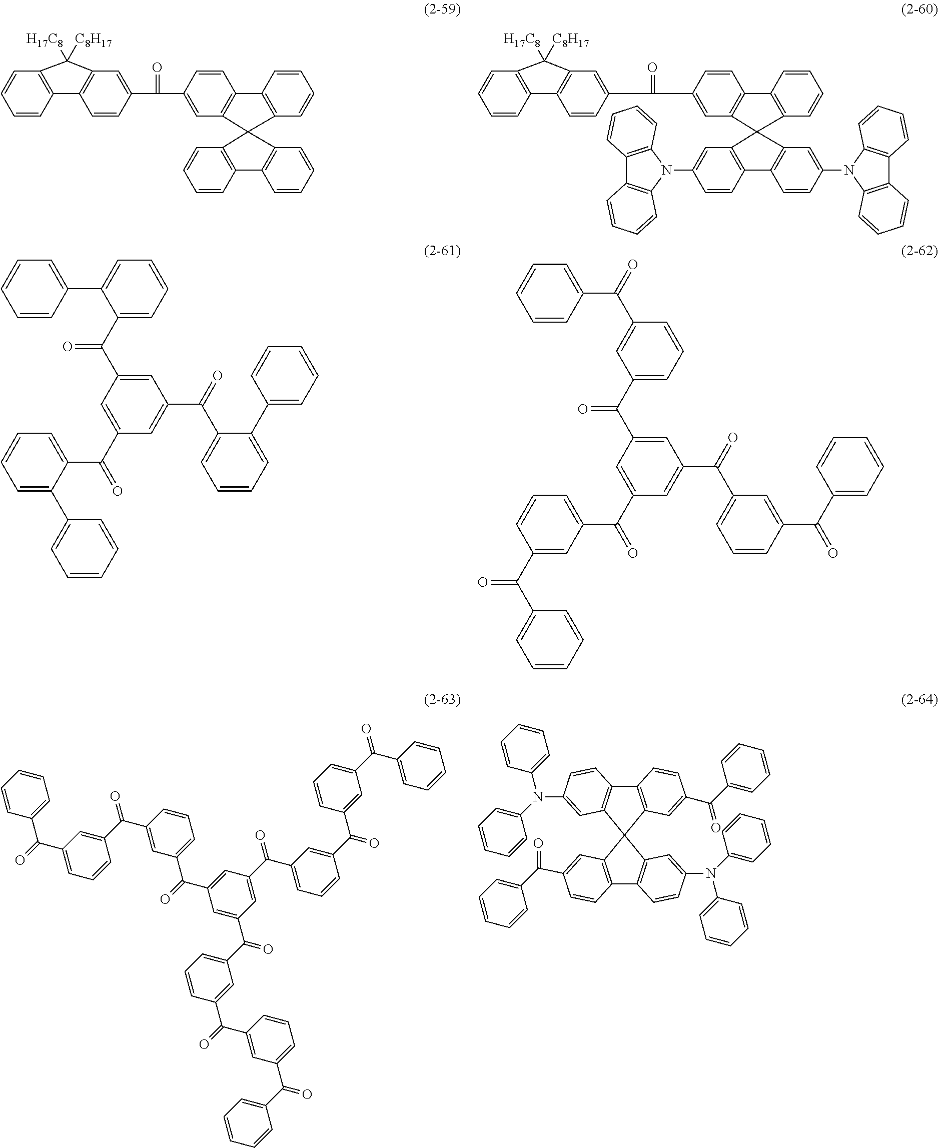

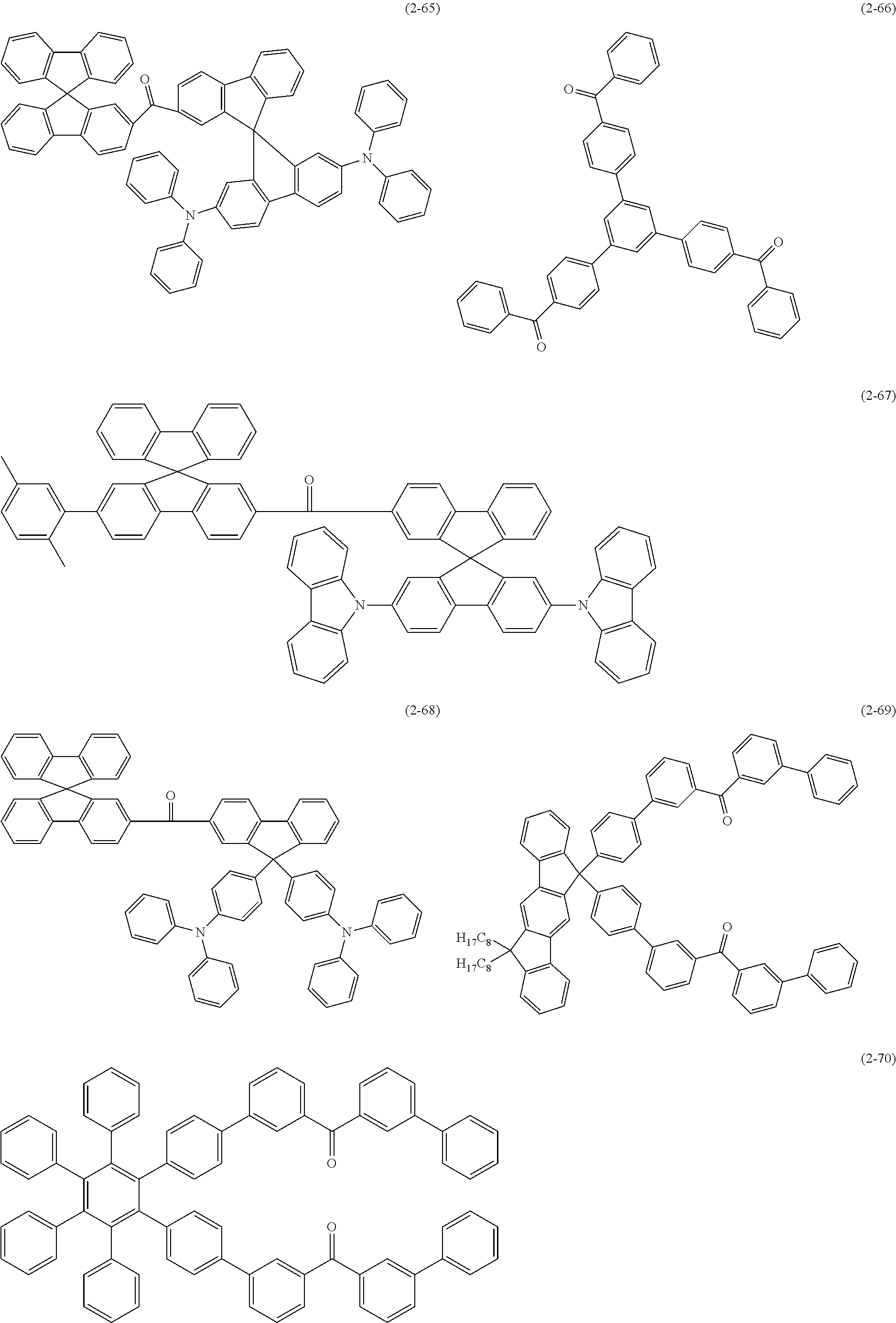

Suitable triazine derivatives which can be used in the formulation according to the invention are, in particular, 1,3,5-triazines which are substituted by at least one, preferably at least two, particularly preferably by three, aromatic or heteroaromatic ring systems. Particular preference is thus given to compounds of the following formulae (7) and (8),

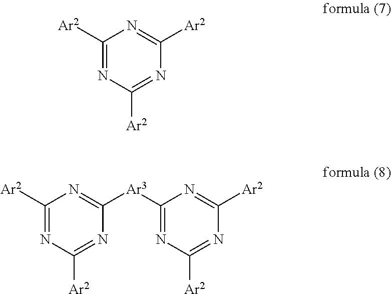

where
Ar² is, identically or differently on each occurrence, a monovalent aromatic or heteroaromatic ring system having 5 to 60 aromatic ring atoms, which may in each case be substituted by one or more radicals R¹;
Ar³ is a divalent aromatic or heteroaromatic ring system having 5 to 60 aromatic ring atoms, which may be substituted by one or more radicals R¹;
   and R¹ has the meaning indicated above in relation to the ketone compound of the formula (2).

In the compounds of the formulae (7) and (8), at least one group Ar² is preferably selected from the groups of the following formulae (9) to (15), and the other groups Ar² have the meaning indicated for formula (7) or (8),

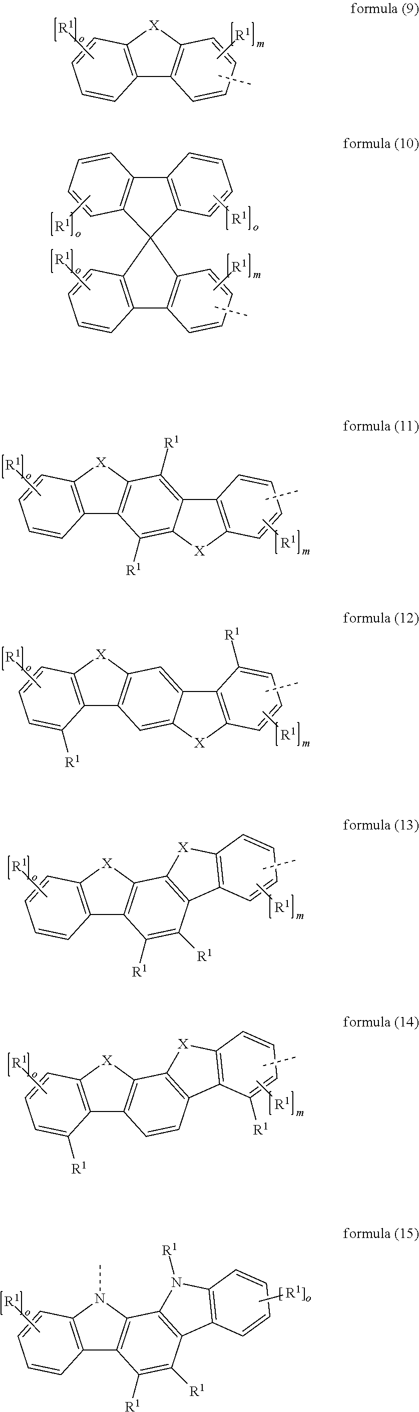

where R¹ has the same meaning as described above, the dashed bond represents the link to the triazine unit, and furthermore:
X is, identically or differently on each occurrence, a divalent bridge selected from B(R¹), C(R¹)₂, Si(R¹)₂, C═O, C═NR¹, C═C(R¹)₂, O, S, S═O, SO₂, N(R¹), P(R¹) and P(═O)R¹;
m is on each occurrence, identically or differently, 0, 1, 2 or 3;
o is on each occurrence, identically or differently, 0, 1, 2, 3 or 4.

Particularly preferred groups Ar² of the triazine compound are selected from the groups of the following formulae (9a) to (15a),

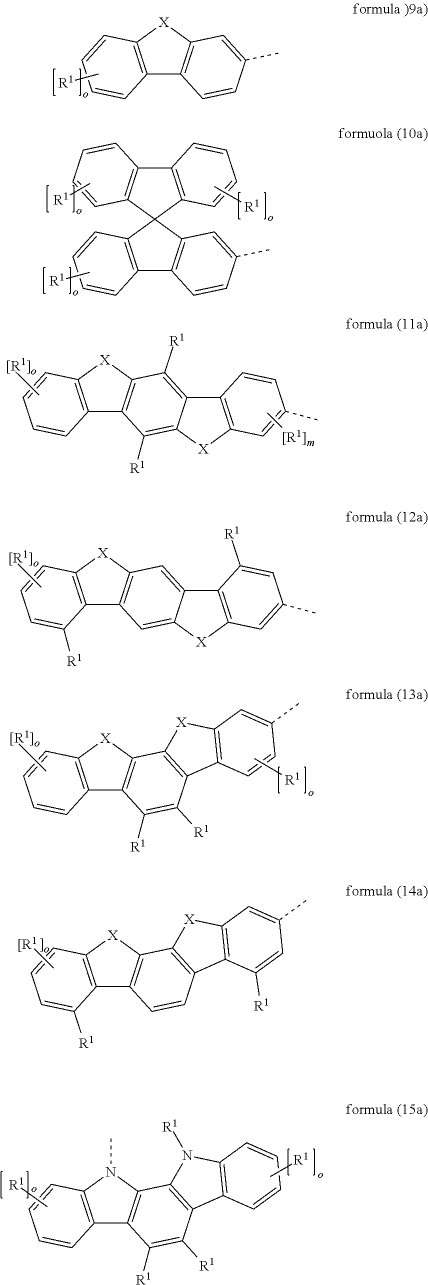

where the symbols and indices used have the same meaning as described above. X here is preferably selected, identically or differently, from C(R¹)₂, N(R¹), O or S, particularly preferably C(R¹)₂.

Preferred groups Ar³ in the compounds of the formula (8) are selected from the groups of the following formulae (16) to (22),

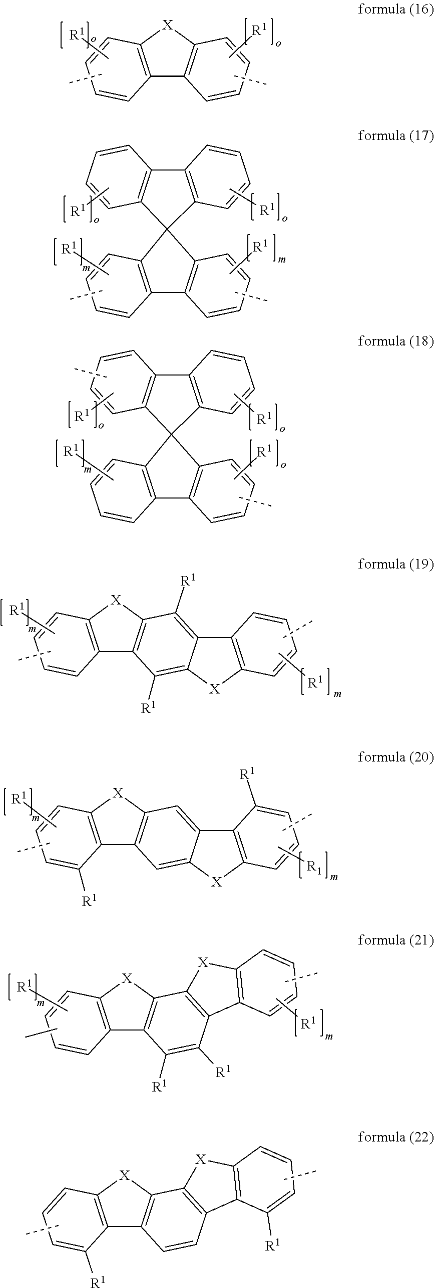

where the symbols and indices used have the same meaning as described above in relation to the triazine compound, and the dashed bonds represent the link to the two triazine units.

Particularly preferred groups Ar³ are selected from the following formulae (16a) to (22a),

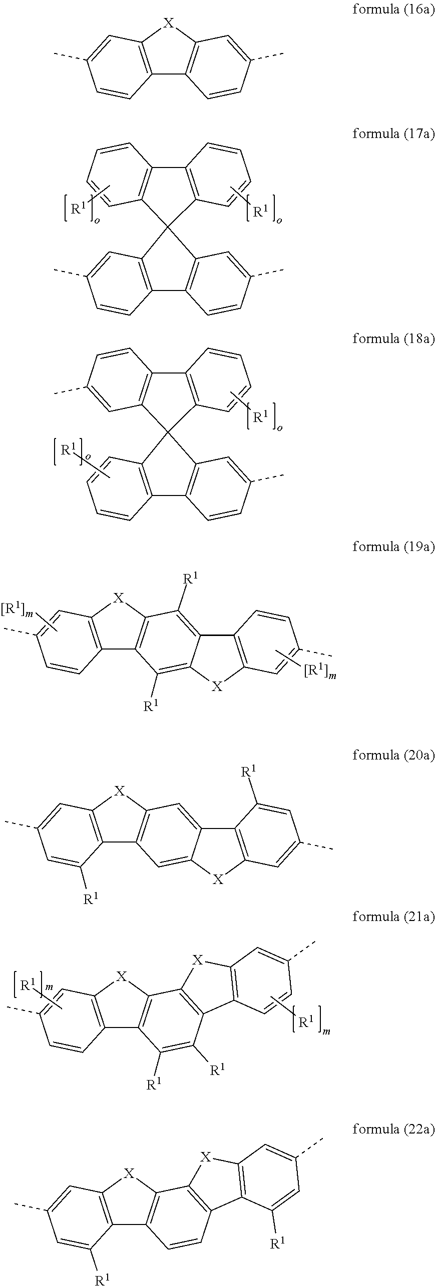

where the symbols and indices used have the same meaning as described above in relation to the triazine compound. X here is preferably selected, identically or differently, from C(R¹)₂, N(R¹), O or S, particularly preferably C(R¹)₂.

Preference is furthermore given to compounds of the above-mentioned formula (8) in which the group Ar³ is selected from the above-mentioned formulae (16) to (22) and Ar² is selected, identically or differently on each occurrence, from the above-mentioned formulae (9) to (15) or phenyl, 1- or 2-naphthyl, ortho-, meta- or para-biphenyl, each of which may be substituted by one or more radicals R¹, but are preferably unsubstituted.

Examples of further preferred compounds of the formula (7) are compounds (7-1) to (7-65) depicted below.

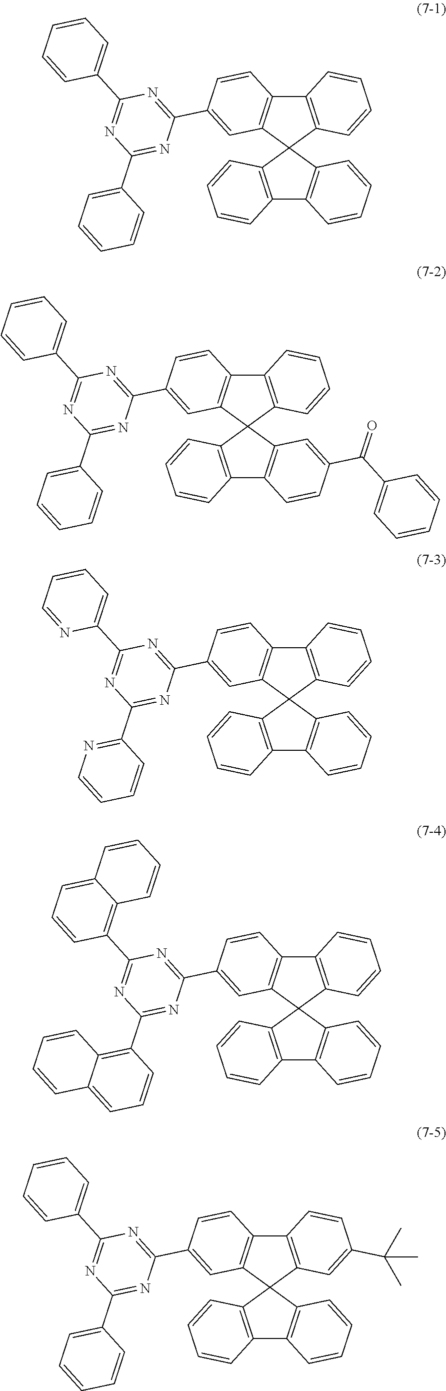

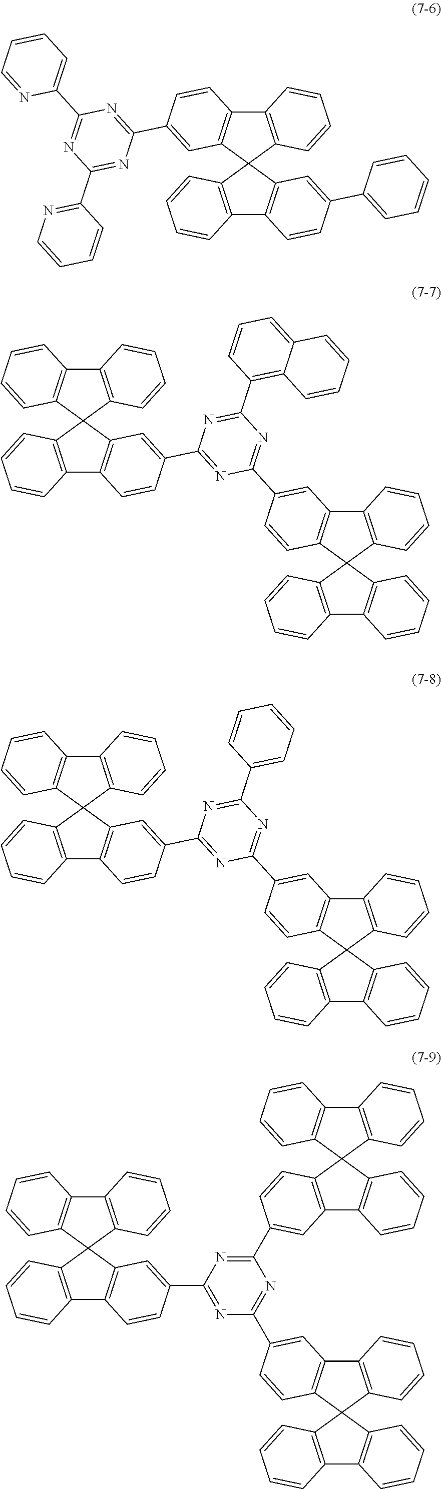 [SMILES: c1ccc(-c2ccc3c(c2)C2(c4ccccc4-3)c3ccccc3-c3ccc(-c4nc(-c5ccccn5)nc(-c5ccccn5)n4)cc32)cc1 ; c1ccc2c(c1)-c1ccccc1C21c2ccccc2-c2cc(-c3nc(-c4ccc5c(c4)C4(c6ccccc6-c6ccccc64)c4ccccc4-5)nc(-c4cccc5ccccc45)n3)ccc21 ; c1ccc(-c2nc(-c3ccc4c(c3)-c3ccccc3C43c4ccccc4-c4ccccc43)nc(-c3ccc4c(c3)C3(c5ccccc5-c5ccccc53)c3ccccc3-4)n2)cc1 ; c1ccc2c(c1)-c1ccccc1C21c2ccccc2-c2cc(-c3nc(-c4ccc5c(c4)-c4ccccc4C54c5ccccc5-c5ccccc54)nc(-c4ccc5c(c4)C4(c6ccccc6-c6ccccc64)c4ccccc4-5)n3)ccc21]

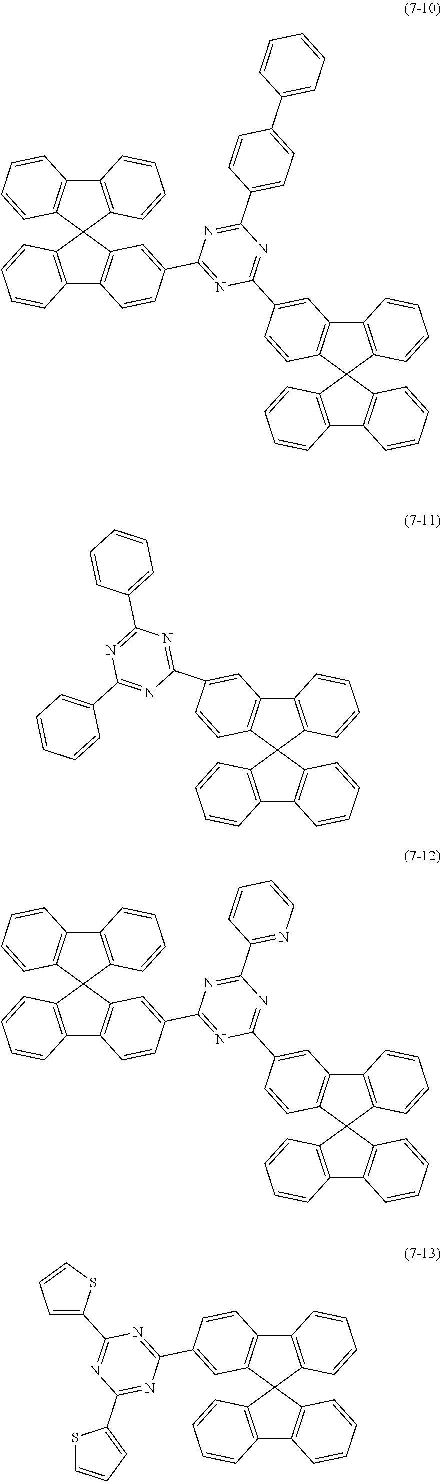 [SMILES: c1ccc(-c2ccc(-c3nc(-c4ccc5c(c4)-c4ccccc4C54c5ccccc5-c5ccccc54)nc(-c4ccc5c(c4)C4(c6ccccc6-c6ccccc64)c4ccccc4-5)n3)cc2)cc1 ; c1ccc(-c2nc(-c3ccccc3)nc(-c3ccc4c(c3)-c3ccccc3C43c4ccccc4-c4ccccc43)n2)cc1 ; c1ccc(-c2nc(-c3ccc4c(c3)-c3ccccc3C43c4ccccc4-c4ccccc43)nc(-c3ccc4c(c3)C3(c5ccccc5-c5ccccc53)c3ccccc3-4)n2)nc1 ; c1csc(-c2nc(-c3ccc4c(c3)C3(c5ccccc5-c5ccccc53)c3ccccc3-4)nc(-c3cccs3)n2)c1]

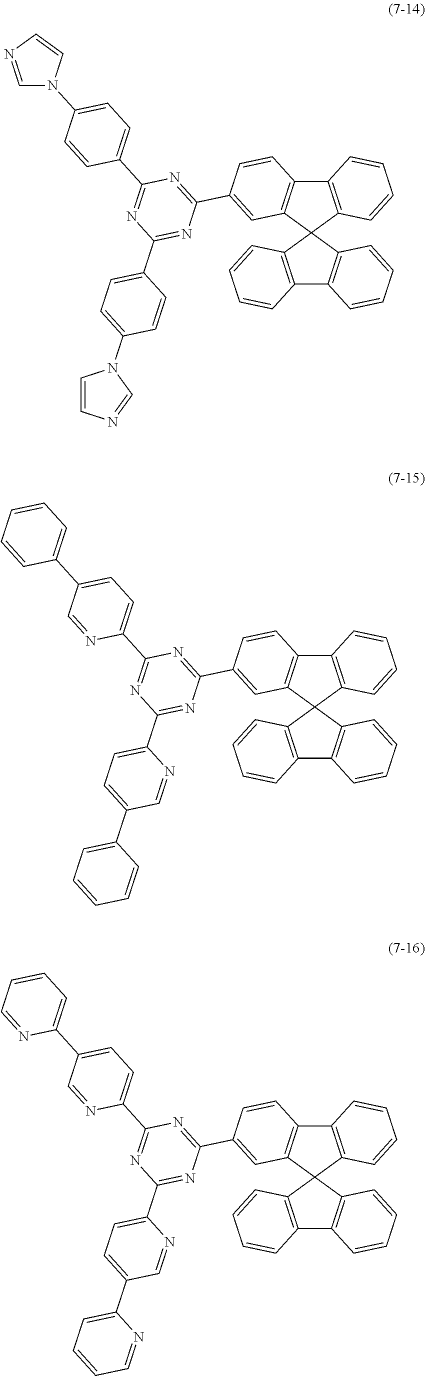 [SMILES: c1ccc2c(c1)-c1ccccc1C21c2ccccc2-c2ccc(-c3nc(-c4ccc(-n5ccnc5)cc4)nc(-c4ccc(-n5ccnc5)cc4)n3)cc21 ; c1ccc(-c2ccc(-c3nc(-c4ccc5c(c4)C4(c6ccccc6-c6ccccc64)c4ccccc4-5)nc(-c4ccc(-c5ccccc5)cn4)n3)nc2)cc1 ; c1ccc(-c2ccc(-c3nc(-c4ccc5c(c4)C4(c6ccccc6-c6ccccc64)c4ccccc4-5)nc(-c4ccc(-c5ccccn5)cn4)n3)nc2)nc1]

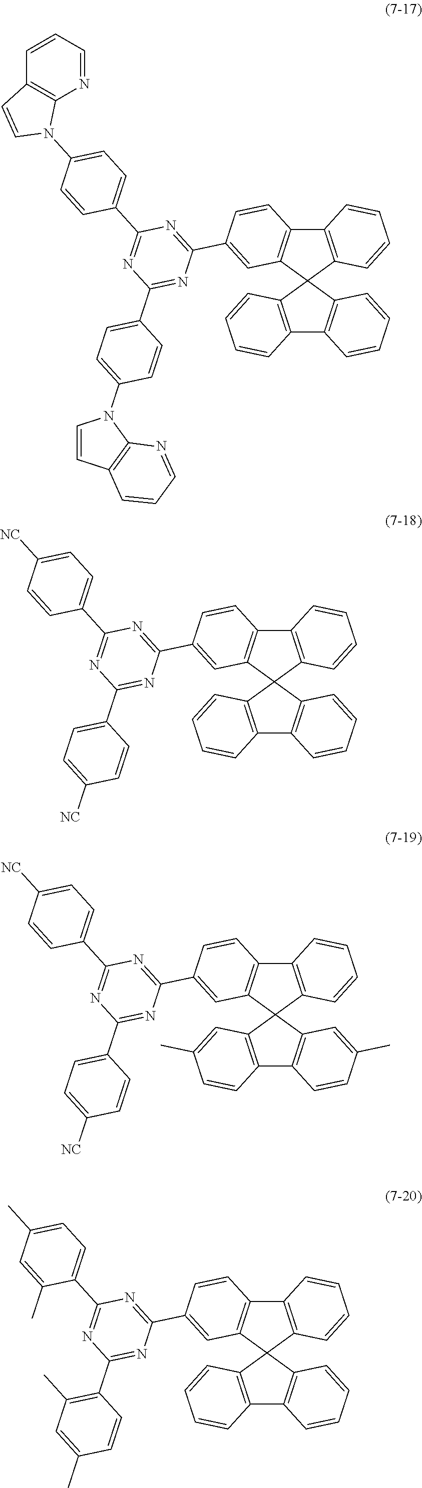

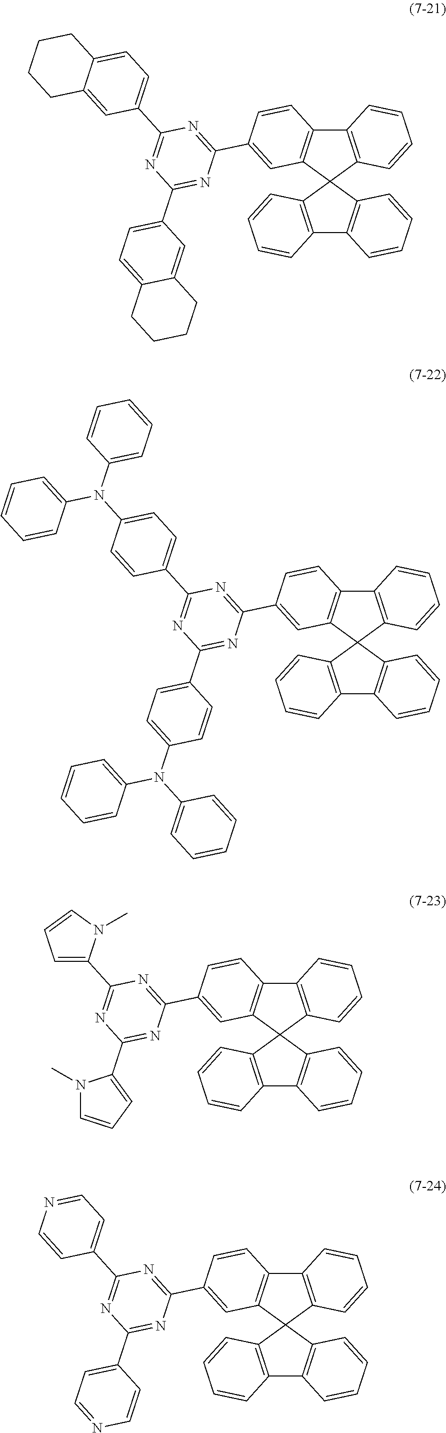 [SMILES: c1ccc2c(c1)-c1ccccc1C21c2ccccc2-c2ccc(-c3nc(-c4ccc5c(c4)CCCC5)nc(-c4ccc5c(c4)CCCC5)n3)cc21 ; c1ccc(N(c2ccccc2)c2ccc(-c3nc(-c4ccc(N(c5ccccc5)c5ccccc5)cc4)nc(-c4ccc5c(c4)C4(c6ccccc6-c6ccccc64)c4ccccc4-5)n3)cc2)cc1 ; Cn1cccc1-c1nc(-c2ccc3c(c2)C2(c4ccccc4-c4ccccc42)c2ccccc2-3)nc(-c2cccn2C)n1 ; c1ccc2c(c1)-c1ccccc1C21c2ccccc2-c2ccc(-c3nc(-c4ccncc4)nc(-c4ccncc4)n3)cc21]

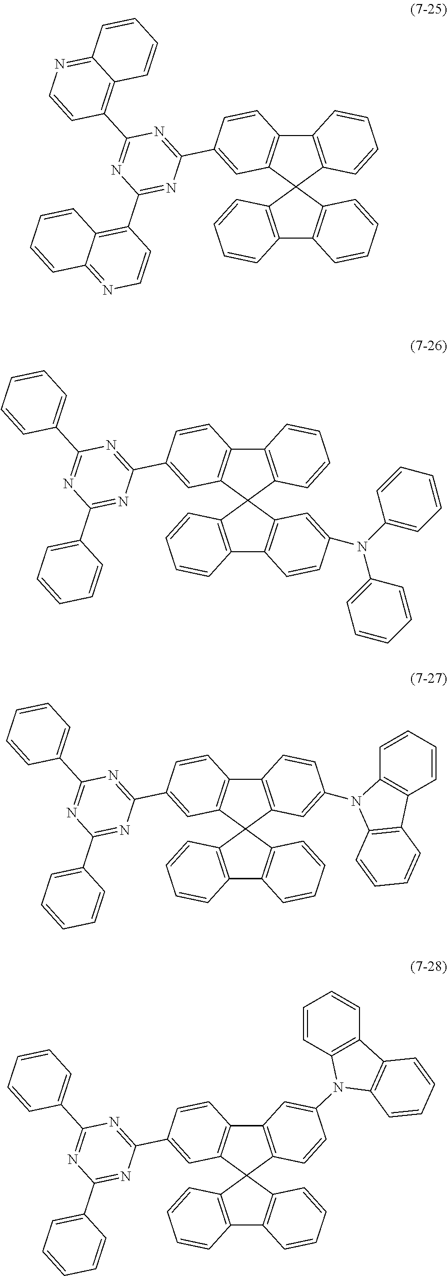 [SMILES: c1ccc2c(c1)-c1ccccc1C21c2ccccc2-c2ccc(-c3nc(-c4ccnc5ccccc45)nc(-c4ccnc5ccccc45)n3)cc21 ; c1ccc(-c2nc(-c3ccccc3)nc(-c3ccc4c(c3)C3(c5ccccc5-4)c4ccccc4-c4ccc(N(c5ccccc5)c5ccccc5)cc43)n2)cc1 ; c1ccc(-c2nc(-c3ccccc3)nc(-c3ccc4c(c3)C3(c5ccccc5-c5ccccc53)c3cc(-n5c6ccccc6c6ccccc65)ccc3-4)n2)cc1 ; c1ccc(-c2nc(-c3ccccc3)nc(-c3ccc4c(c3)C3(c5ccccc5-c5ccccc53)c3ccc(-n5c6ccccc6c6ccccc65)cc3-4)n2)cc1]

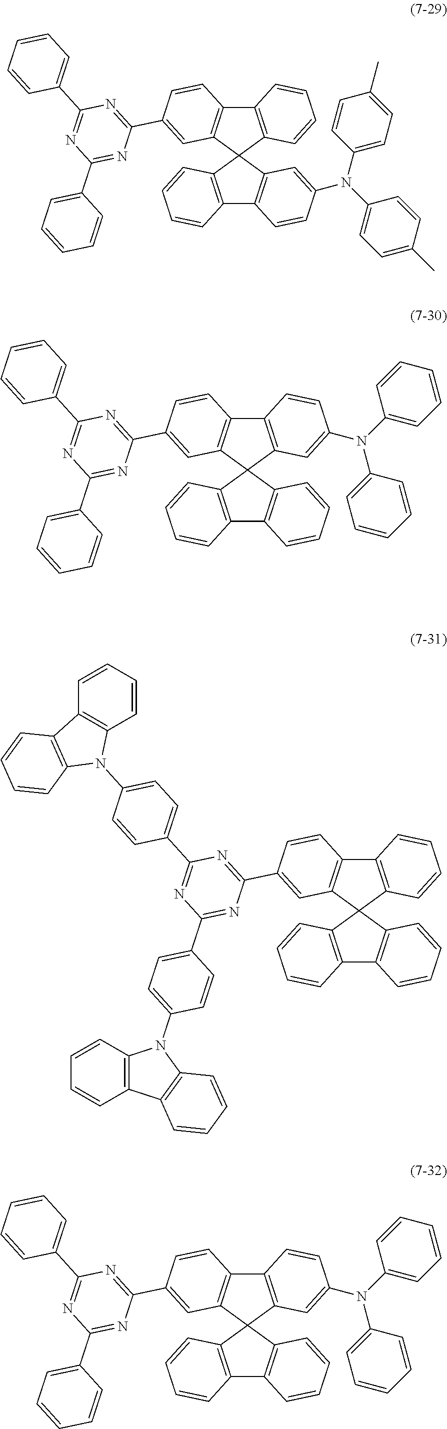 [SMILES: Cc1ccc(N(c2ccc(C)cc2)c2ccc3c(c2)C2(c4ccccc4-c4ccc(-c5nc(-c6ccccc6)nc(-c6ccccc6)n5)cc42)c2ccccc2-3)cc1 ; c1ccc(-c2nc(-c3ccccc3)nc(-c3ccc4c(c3)C3(c5ccccc5-c5ccccc53)c3cc(N(c5ccccc5)c5ccccc5)ccc3-4)n2)cc1 ; c1ccc2c(c1)-c1ccccc1C21c2ccccc2-c2ccc(-c3nc(-c4ccc(-n5c6ccccc6c6ccccc65)cc4)nc(-c4ccc(-n5c6ccccc6c6ccccc65)cc4)n3)cc21 ; c1ccc(-c2nc(-c3ccccc3)nc(-c3ccc4c(c3)C3(c5ccccc5-c5ccccc53)c3cc(N(c5ccccc5)c5ccccc5)ccc3-4)n2)cc1]

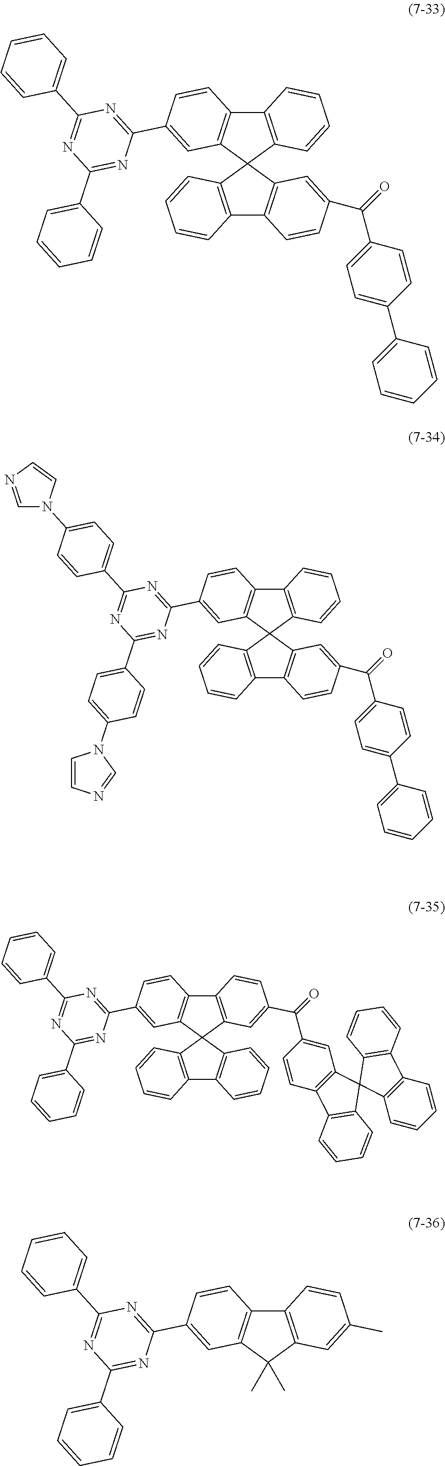 [SMILES: O=C(c1ccc(-c2ccccc2)cc1)c1ccc2c(c1)C1(c3ccccc3-2)c2ccccc2-c2ccc(-c3nc(-c4ccccc4)nc(-c4ccccc4)n3)cc21 ; O=C(c1ccc(-c2ccccc2)cc1)c1ccc2c(c1)C1(c3ccccc3-2)c2ccccc2-c2ccc(-c3nc(-c4ccc(-n5ccnc5)cc4)nc(-c4ccc(-n5ccnc5)cc4)n3)cc21 ; O=C(c1ccc2c(c1)C1(c3ccccc3-c3ccccc31)c1ccccc1-2)c1ccc2c(c1)C1(c3ccccc3-c3ccccc31)c1cc(-c3nc(-c4ccccc4)nc(-c4ccccc4)n3)ccc1-2 ; Cc1ccc2c(c1)C(C)(C)c1cc(-c3nc(-c4ccccc4)nc(-c4ccccc4)n3)ccc1-2]

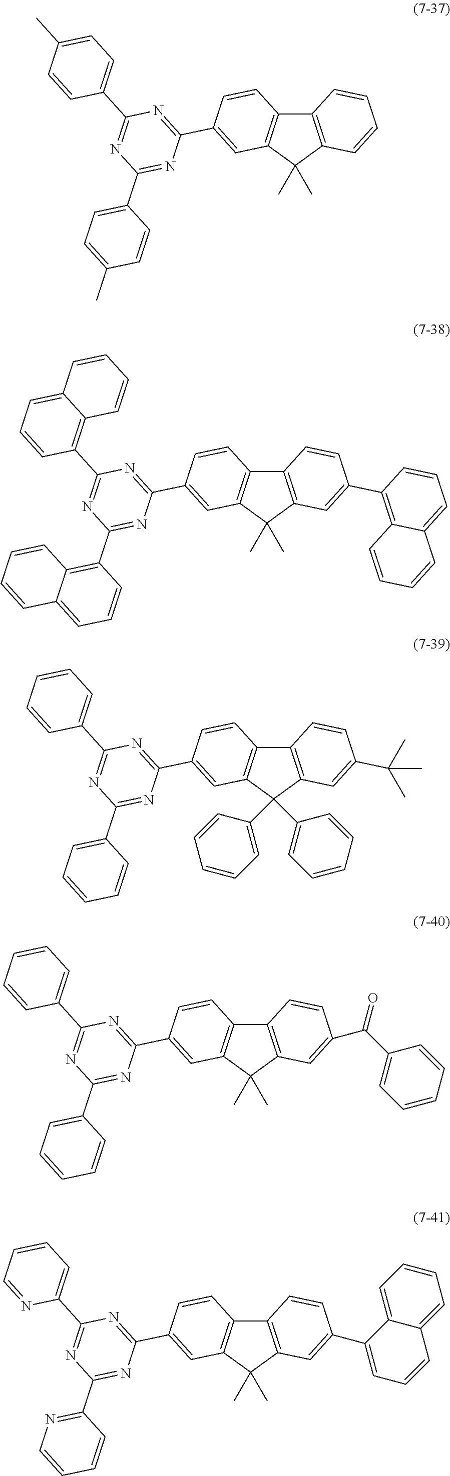

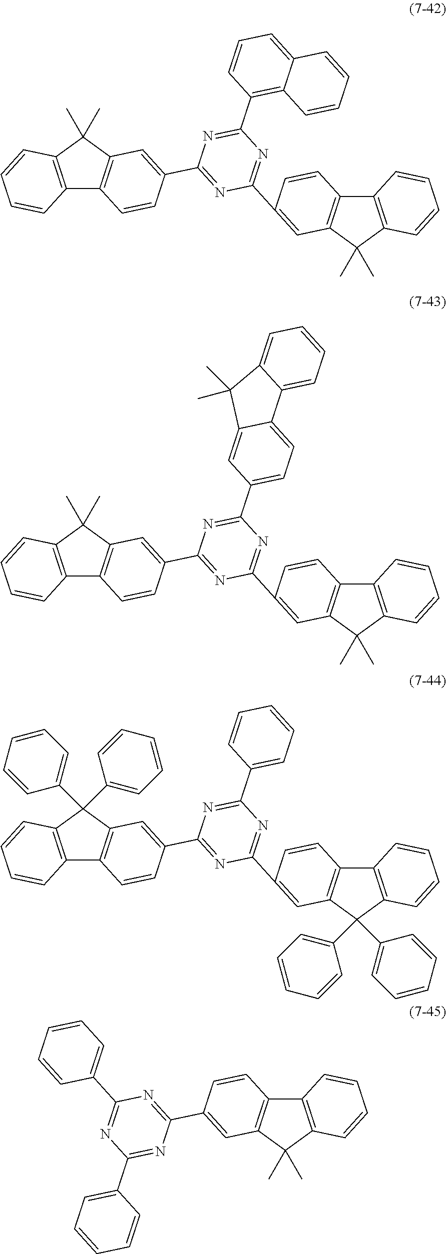 [SMILES: CC1(C)c2ccccc2-c2ccc(-c3nc(-c4ccc5c(c4)C(C)(C)c4ccccc4-5)nc(-c4cccc5ccccc45)n3)cc21 ; CC1(C)c2ccccc2-c2ccc(-c3nc(-c4ccc5c(c4)C(C)(C)c4ccccc4-5)nc(-c4ccc5c(c4)C(C)(C)c4ccccc4-5)n3)cc21 ; c1ccc(-c2nc(-c3ccc4c(c3)C(c3ccccc3)(c3ccccc3)c3ccccc3-4)nc(-c3ccc4c(c3)C(c3ccccc3)(c3ccccc3)c3ccccc3-4)n2)cc1 ; CC1(C)c2ccccc2-c2ccc(-c3nc(-c4ccccc4)nc(-c4ccccc4)n3)cc21]

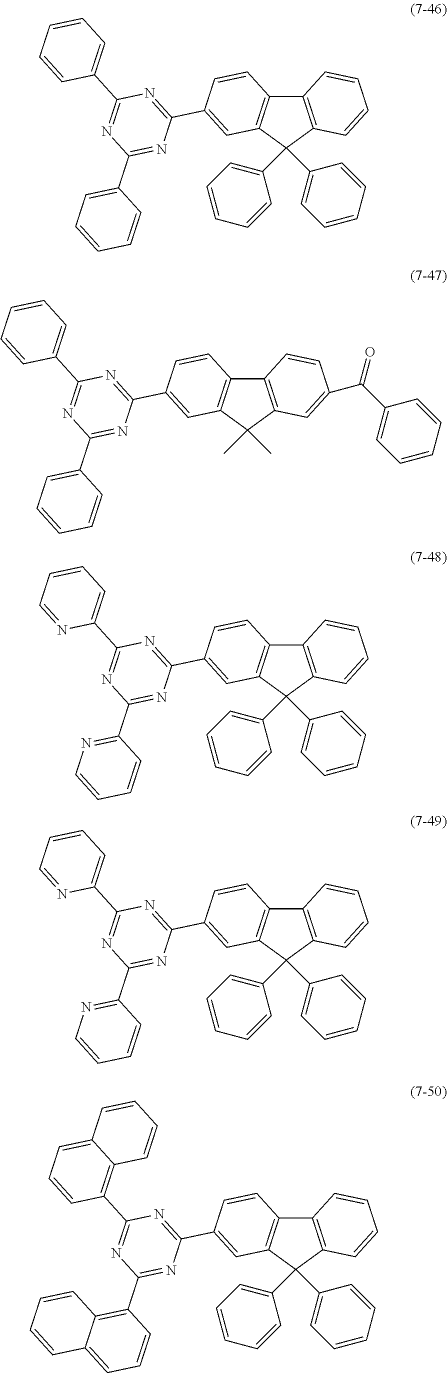

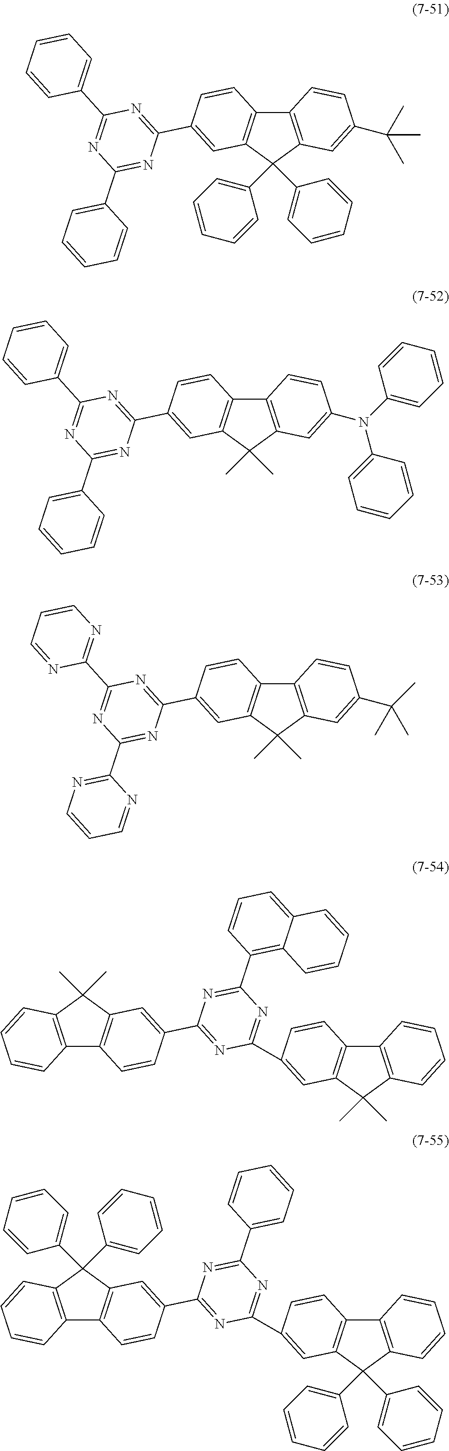 [SMILES: CC(C)(C)c1ccc2c(c1)C(c1ccccc1)(c1ccccc1)c1cc(-c3nc(-c4ccccc4)nc(-c4ccccc4)n3)ccc1-2 ; CC1(C)c2cc(-c3nc(-c4ccccc4)nc(-c4ccccc4)n3)ccc2-c2ccc(N(c3ccccc3)c3ccccc3)cc21 ; CC(C)(C)c1ccc2c(c1)C(C)(C)c1cc(-c3nc(-c4ncccn4)nc(-c4ncccn4)n3)ccc1-2 ; CC1(C)c2ccccc2-c2ccc(-c3nc(-c4ccc5c(c4)C(C)(C)c4ccccc4-5)nc(-c4cccc5ccccc45)n3)cc21 ; c1ccc(-c2nc(-c3ccc4c(c3)C(c3ccccc3)(c3ccccc3)c3ccccc3-4)nc(-c3ccc4c(c3)C(c3ccccc3)(c3ccccc3)c3ccccc3-4)n2)cc1]

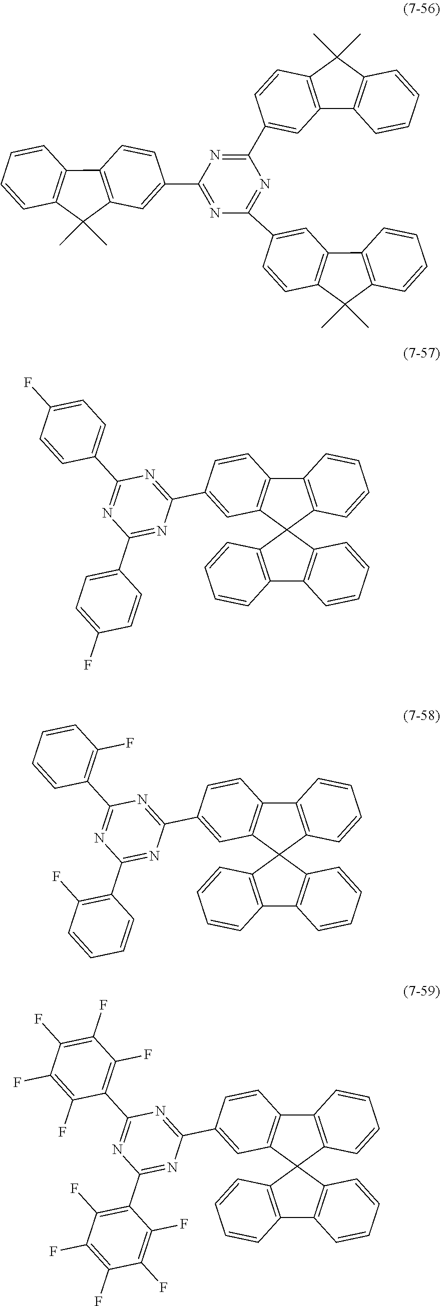 [SMILES: CC1(C)c2ccccc2-c2cc(-c3nc(-c4ccc5c(c4)-c4ccccc4C5(C)C)nc(-c4ccc5c(c4)C(C)(C)c4ccccc4-5)n3)ccc21 ; Fc1ccc(-c2nc(-c3ccc(F)cc3)nc(-c3ccc4c(c3)C3(c5ccccc5-c5ccccc53)c3ccccc3-4)n2)cc1 ; Fc1ccccc1-c1nc(-c2ccc3c(c2)C2(c4ccccc4-c4ccccc42)c2ccccc2-3)nc(-c2ccccc2F)n1 ; Fc1c(F)c(F)c(-c2nc(-c3ccc4c(c3)C3(c5ccccc5-c5ccccc53)c3ccccc3-4)nc(-c3c(F)c(F)c(F)c(F)c3F)n2)c(F)c1F]

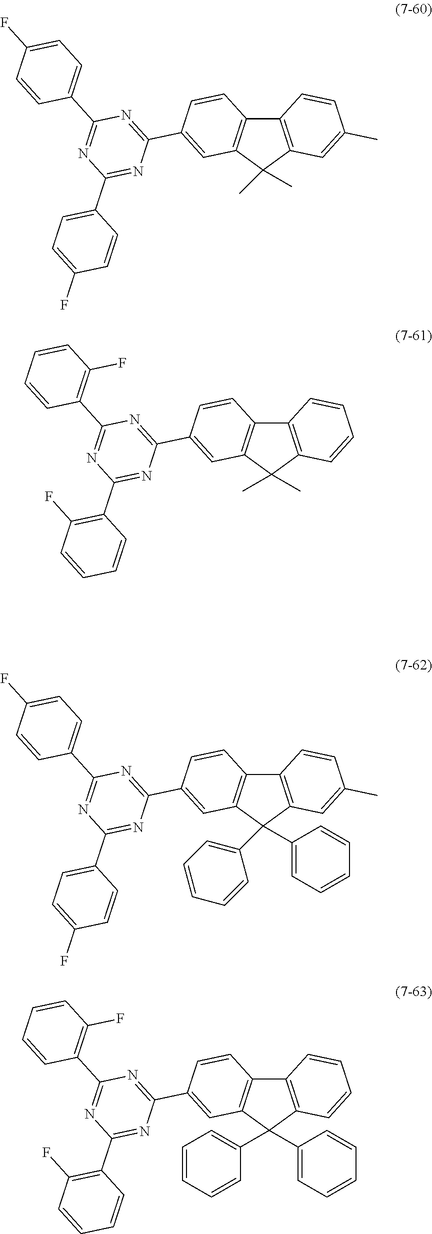

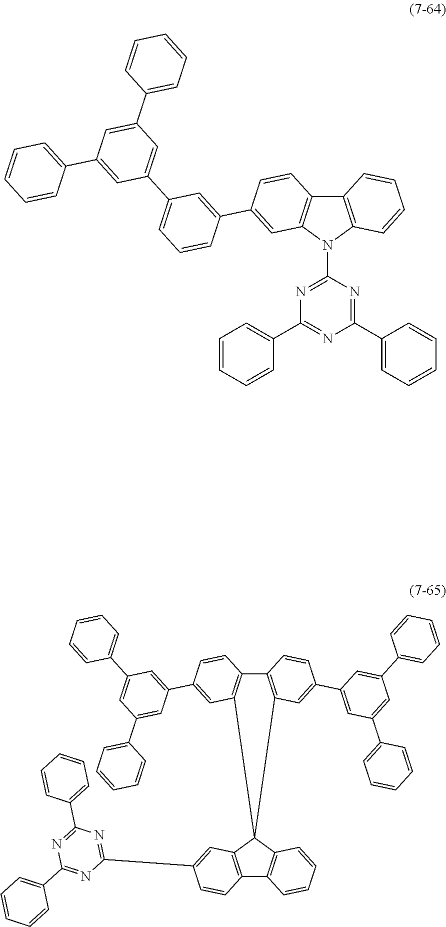 [SMILES: c1ccc(-c2cc(-c3ccccc3)cc(-c3cccc(-c4ccc5c6ccccc6n(-c6nc(-c7ccccc7)nc(-c7ccccc7)n6)c5c4)c3)c2)cc1 ; c1ccc(-c2cc(-c3ccccc3)cc(-c3ccc4c(c3)C3(c5ccccc5-c5ccc(-c6nc(-c7ccccc7)nc(-c7ccccc7)n6)cc53)c3cc(-c5cc(-c6ccccc6)cc(-c6ccccc6)c5)ccc3-4)c2)cc1]

Examples of further preferred compounds of the formula (8) are compounds (8-1) to (8-16) depicted below.

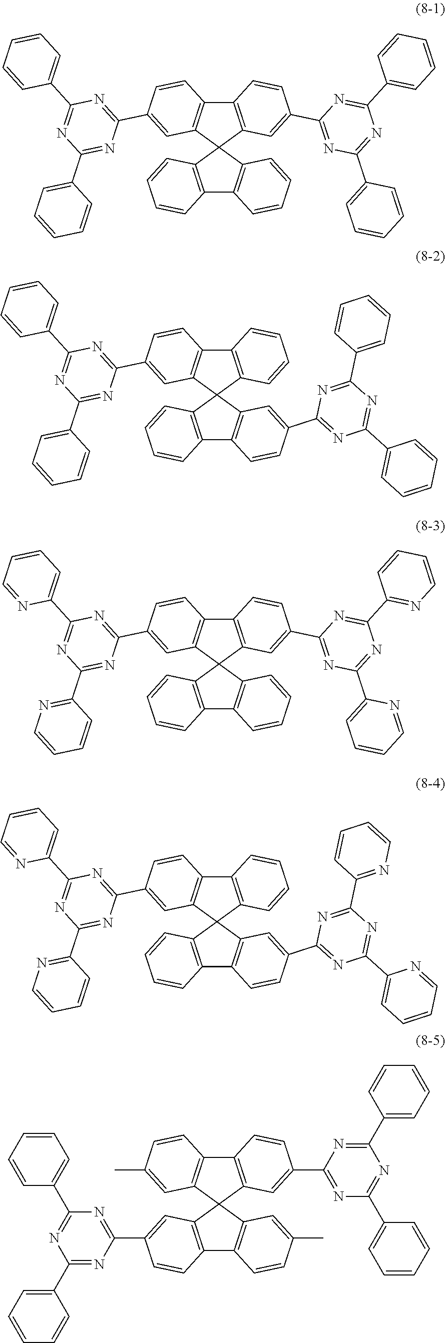

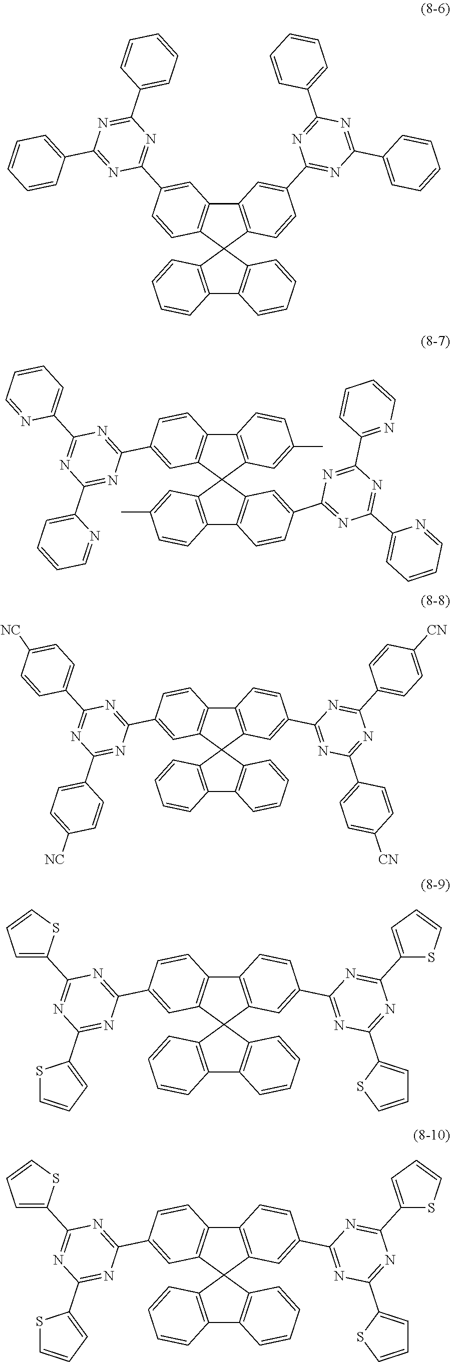

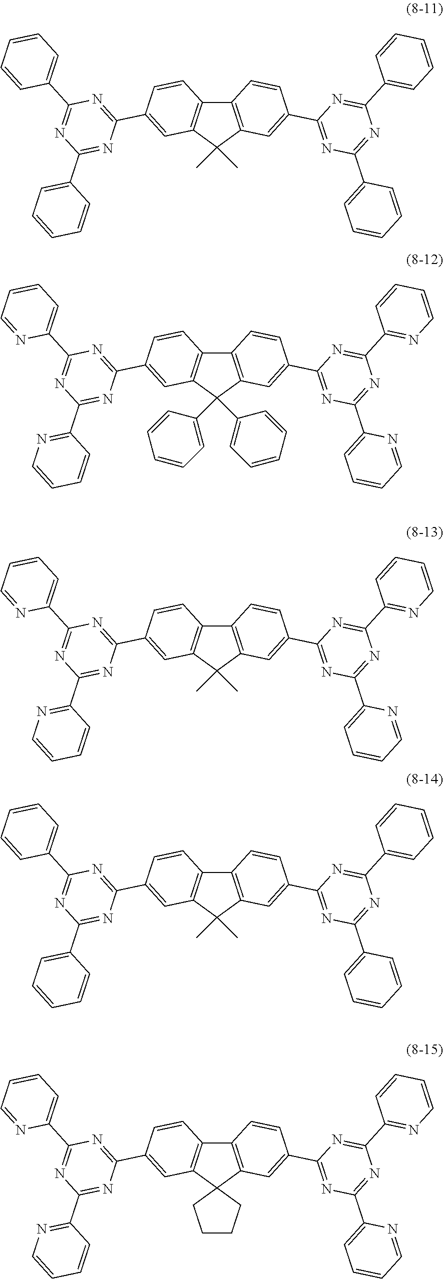 [SMILES: CC1(C)c2cc(-c3nc(-c4ccccc4)nc(-c4ccccc4)n3)ccc2-c2ccc(-c3nc(-c4ccccc4)nc(-c4ccccc4)n3)cc21 ; c1ccc(C2(c3ccccc3)c3cc(-c4nc(-c5ccccn5)nc(-c5ccccn5)n4)ccc3-c3ccc(-c4nc(-c5ccccn5)nc(-c5ccccn5)n4)cc32)cc1 ; CC1(C)c2cc(-c3nc(-c4ccccn4)nc(-c4ccccn4)n3)ccc2-c2ccc(-c3nc(-c4ccccn4)nc(-c4ccccn4)n3)cc21 ; CC1(C)c2cc(-c3nc(-c4ccccc4)nc(-c4ccccc4)n3)ccc2-c2ccc(-c3nc(-c4ccccc4)nc(-c4ccccc4)n3)cc21 ; c1ccc(-c2nc(-c3ccc4c(c3)C3(CCCC3)c3cc(-c5nc(-c6ccccn6)nc(-c6ccccn6)n5)ccc3-4)nc(-c3ccccn3)n2)nc1]

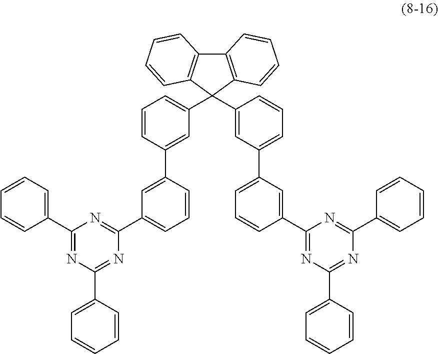 [SMILES: c1ccc(-c2nc(-c3ccccc3)nc(-c3cccc(-c4cccc(C5(c6cccc(-c7cccc(-c8nc(-c9ccccc9)nc(-c9ccccc9)n8)c7)c6)c6ccccc6-c6ccccc65)c4)c3)n2)cc1]

As already stated above, the formulation according to the invention also comprises a triplet emitter compound. A triplet emitter compound (phosphorescent compound) in accordance with the present invention is a compound which exhibits luminescence from an excited state of relatively high spin multiplicity, i.e. a spin state>1, in particular from an excited triplet state, at room temperature. In accordance with the present invention, all luminescent transition-metal complexes containing transition metals from the second and third transition-metal series, in particular all luminescent iridium and platinum compounds, are to be regarded as phosphorescent compounds.

In a preferred embodiment of the present invention, the triplet emitter compound is a red-phosphorescent compound or a green-phosphorescent compound.

Suitable triplet emitter compounds (phosphorescent compounds) are, in particular, compounds which emit light, preferably in the visible region, on suitable excitation and in addition contain at least one atom having an atomic number greater than 20, preferably greater than 38 and less than 84, particularly preferably greater than 56 and less than 80. The triplet emitter compounds used are preferably compounds which contain copper, molybdenum, tungsten, rhenium, ruthenium, osmium, rhodium, iridium, palladium, platinum, silver, gold or europium, in particular compounds which contain iridium or platinum.

Particularly preferred formulations according to the invention comprise, as triplet emitter compound, at least one compound of the formulae (23) to (26),

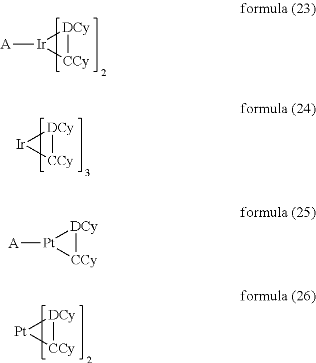

where R¹ has the same meaning as described above in relation to formula (2), and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R′;
A is, identically or differently on each occurrence, a monoanionic, bidentate chelating ligand, preferably a diketonate ligand.

Due to the formation of ring systems between a plurality of radicals R¹, a bridge may also be present between the groups DCy and CCy. Furthermore, due to formation of ring systems between a plurality of radicals R′, a bridge may also be present between two or three ligands CCy-DCy or between one or two ligands CCy-DCy and the ligand A, giving a polydentate or polypodal ligand system.

Examples of the emitters described above are revealed by WO 00/70655, WO 01/41512, WO 02/02714, WO 02/15645, EP 1191613, EP 1191612, EP 1191614, WO 04/081017, WO 05/033244, WO 05/042550, WO 05/113563, WO 06/008069, WO 06/061182, WO 06/081973, DE 102008015526, DE 102008027005 and DE 102009007038. In general, all phosphorescent complexes as used in accordance with the prior art for phosphorescent OLEDs and as are known to the person skilled in the art in the area of organic electroluminescence are suitable, and the person skilled in the art will be able to use further phosphorescent compounds without inventive step.

In particular, the person skilled in the art knows which phosphorescent complexes emit with which emission colour.

Preferred phosphorescent compounds are structures (T-1) to (T-140) shown in the following table.

| | |
|---|---|
| 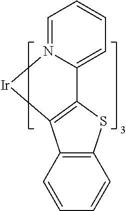 | (T-1) |
| 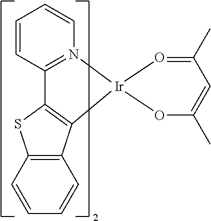 | (T-2) |
| 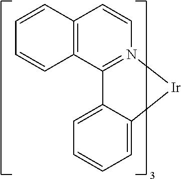 | (T-3) |
| 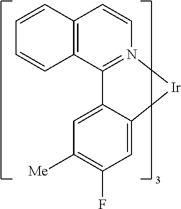 | (T-4) |
| 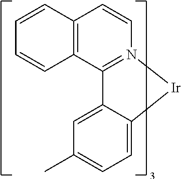 | (T-5) |
| 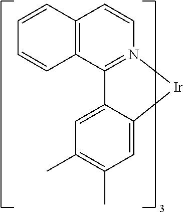 | (T-6) |
| 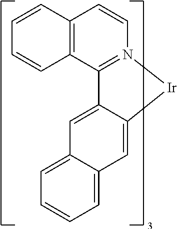 | (T-7) |
| 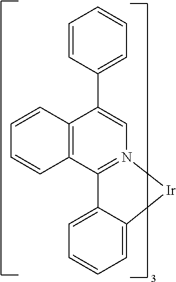 | (T-8) |
| 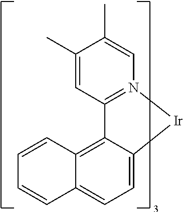 | (T-9) |
| 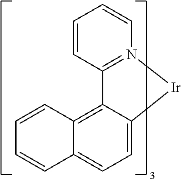 | (T-10) |
| 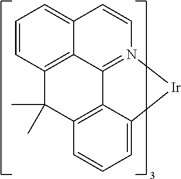 | (T-11) |
| 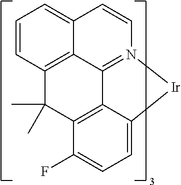 | (T-12) |
| 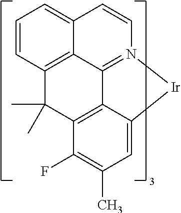 | (T-13) |
| 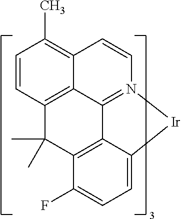 | (T-14) |
| 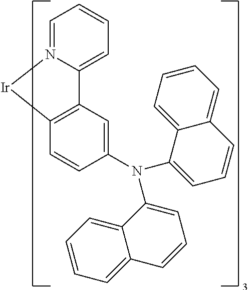 | (T-15) |
| 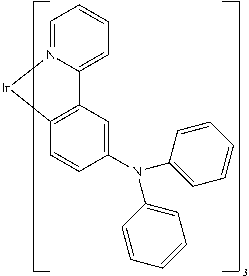 | (T-16) |
| 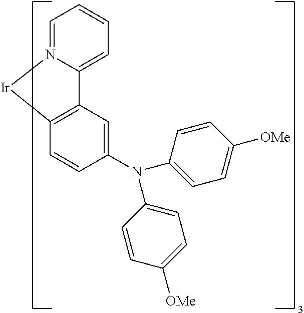 | (T-17) |
| 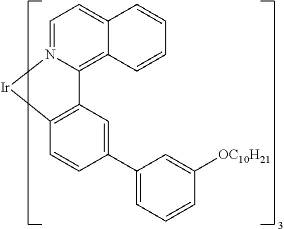 | (T-18) |
| 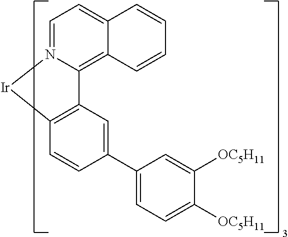 | (T-19) |
| 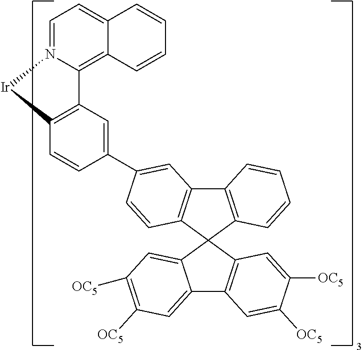 | (T-20) |
| 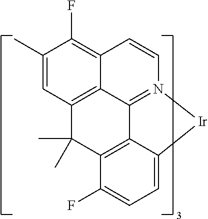 | (T-21) |
| 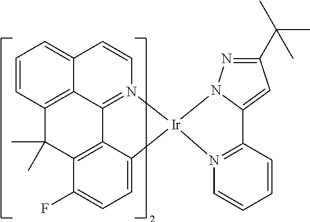 | (T-22) |
| 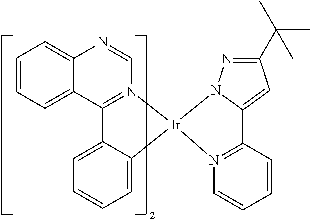 | (T-23) |
| 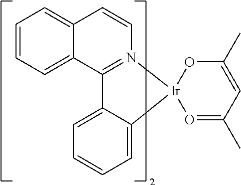 | (T-24) |
| 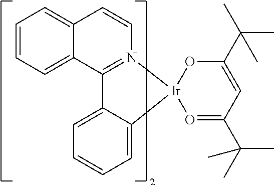 | (T-25) |
| 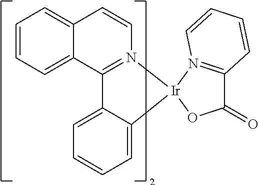 | (T-26) |
| 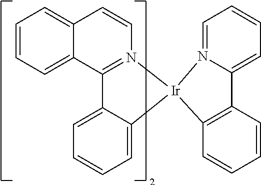 | (T-27) |
| 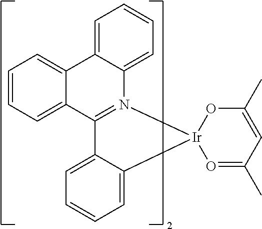 | (T-28) |
| 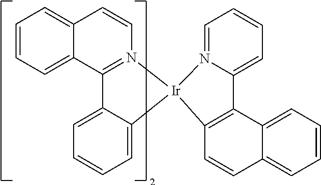 | (T-29) |
| 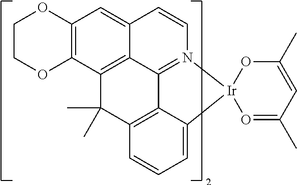 | (T-30) |
| 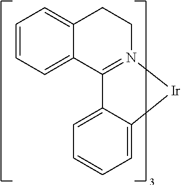 | (T-31) |
| 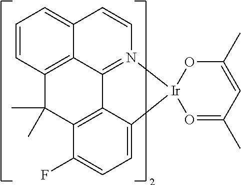 | (T-32) |
| 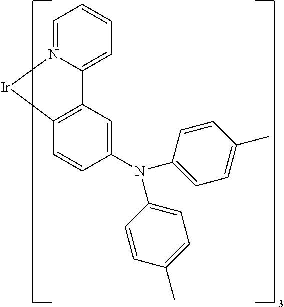 | (T-33) |
| 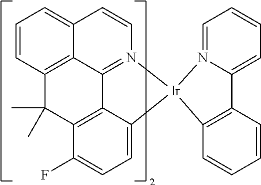 | (T-34) |
| 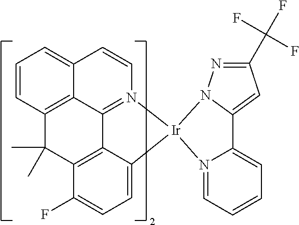 | (T-35) |
| 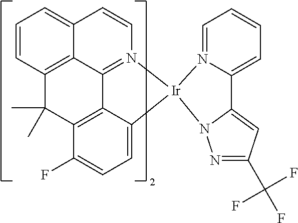 | (T-36) |
| 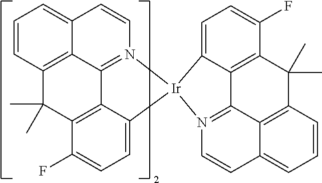 | (T-37) |
| 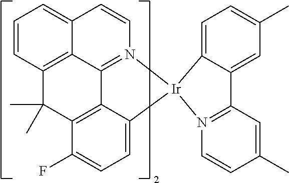 | (T-38) |
| 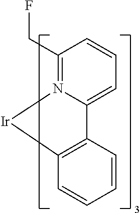 | (T-39) |
| 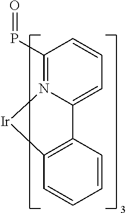 | (T-40) |
| 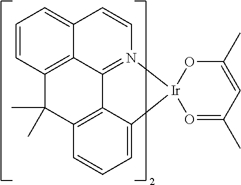 | (T-41) |
| 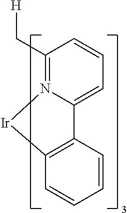 | (T-42) |
| 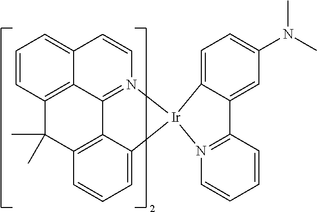 | (T-43) |
| 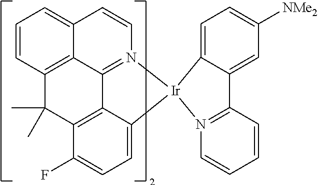 | (T-44) |
| 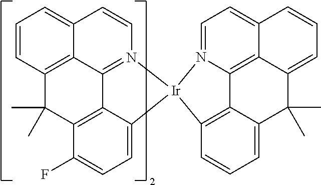 | (T-45) |
| 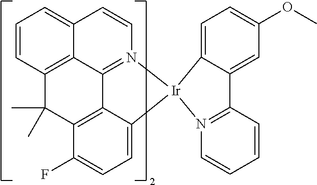 | (T-46) |
| 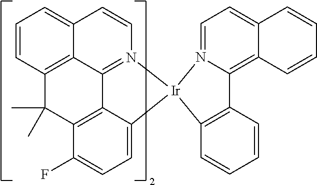 | (T-47) |
| 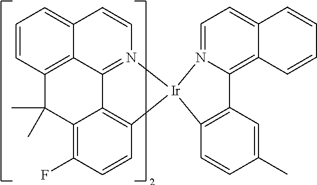 | (T-48) |
| 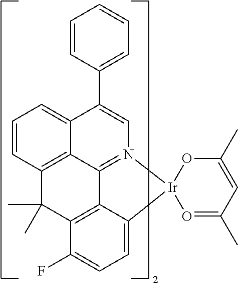 | (T-49) |
| 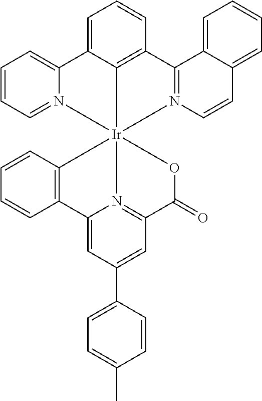 | (T-50) |
| 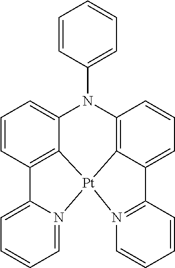 | (T-51) |
| 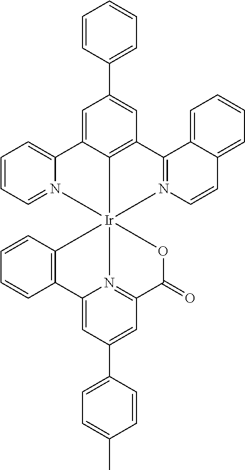 | (T-52) |
| 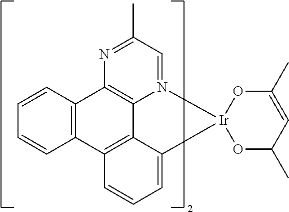 | (T-53) |
| 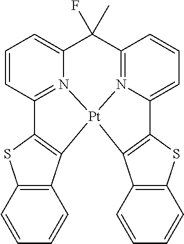 | (T-54) |
| 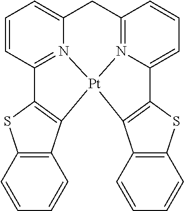 | (T-55) |
| 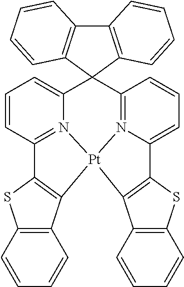 | (T-56) |
| 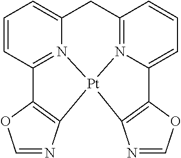 | (T-57) |
| 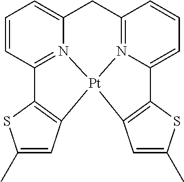 | (T-58) |
| 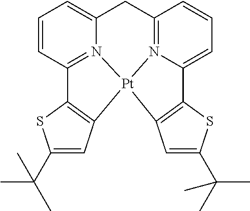 | (T-59) |
| 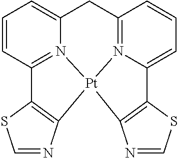 | (T-60) |
| 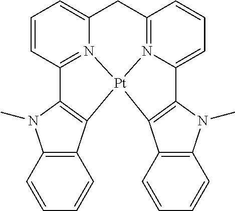 | (T-61) |
| 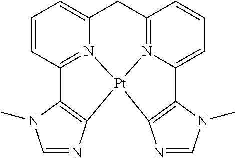 | (T-62) |
| 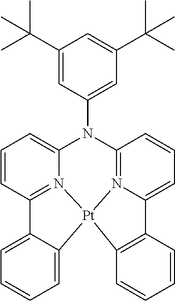 | (T-63) |
| 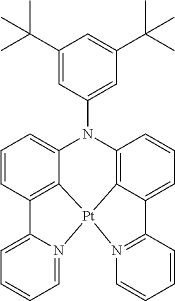 | (T-64) |
| 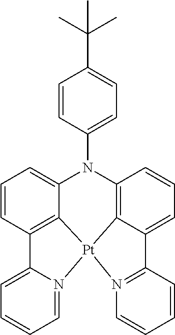 | (T-65) |
| 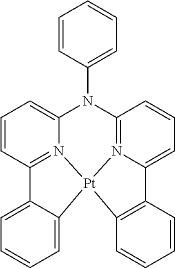 | (T-66) |
| 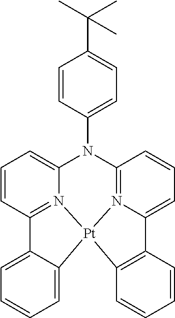 | (T-67) |
| 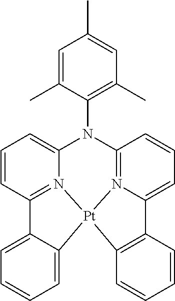 | (T-68) |
| 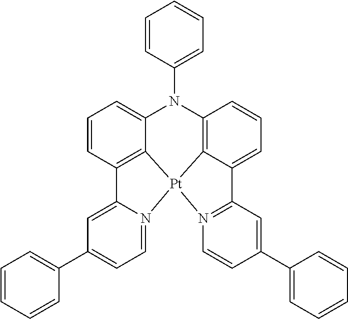 | (T-69) |
| 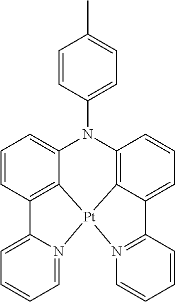 | (T-70) |
| 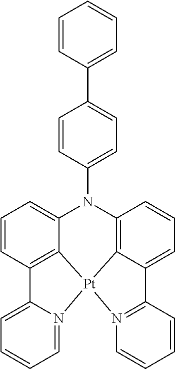 | (T-71) |
| 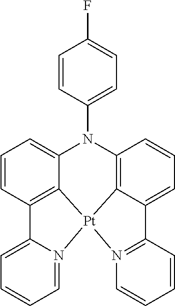 | (T-72) |
| 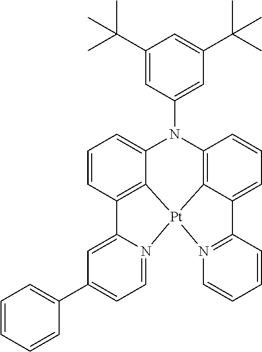 | (T-73) |
| 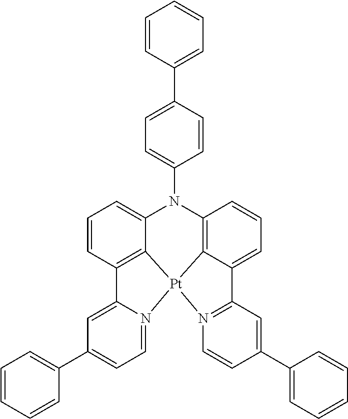 | (T-74) |
| 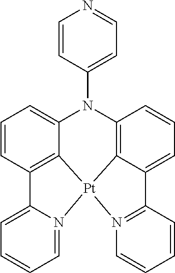 | (T-75) |
| 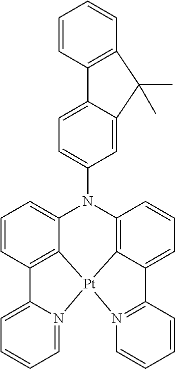 | (T-76) |
| 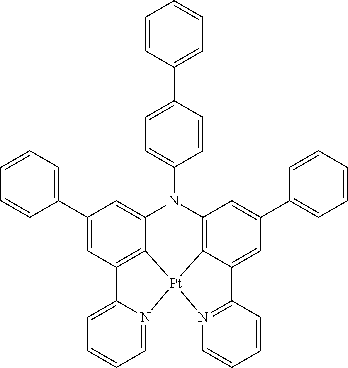 | (T-77) |
| 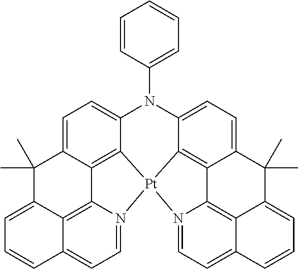 | (T-78) |
| 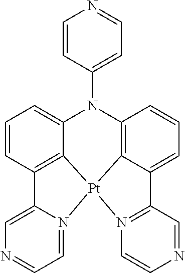 | (T-79) |
| 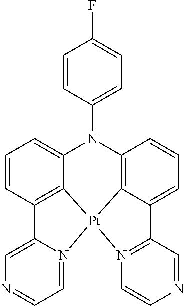 | (T-80) |
| 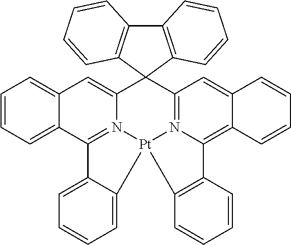 | (T-81) |
| 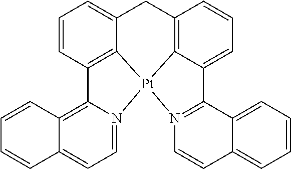 | (T-82) |
| 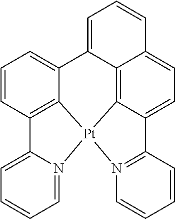 | (T-83) |
| 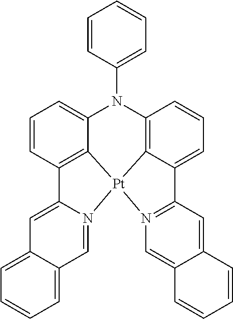 | (T-84) |
| 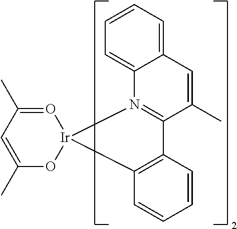 | (T-85) |
| 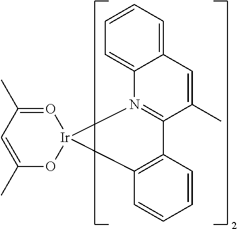 | (T-86) |
| 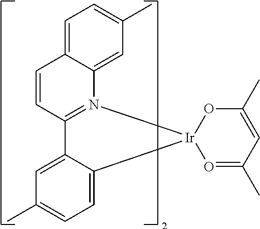 | (T-87) |
| 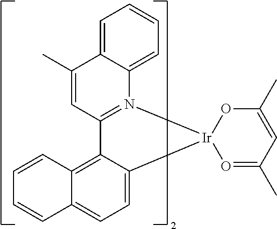 | (T-88) |
| 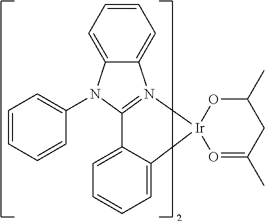 | (T-89) |
| 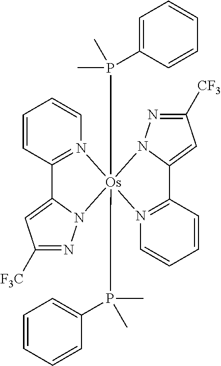 | (T-90) |
| 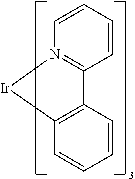 | (T-91) |
| 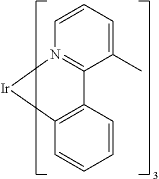 | (T-92) |
| 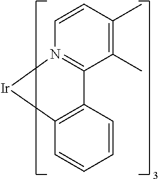 | (T-93) |
| 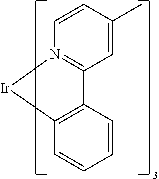 | (T-94) |
| 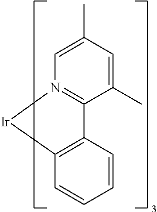 | (T-95) |
| 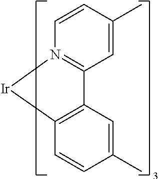 | (T-96) |
| 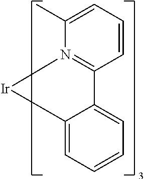 | (T-97) |
| 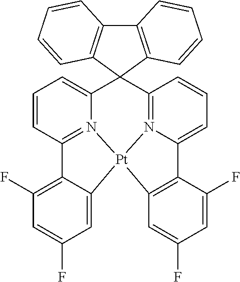 | (T-98) |
| 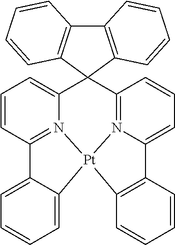 | (T-99) |
| 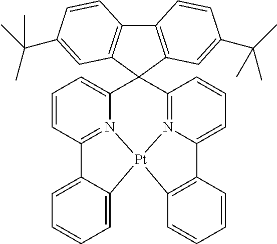 | (T-100) |
| 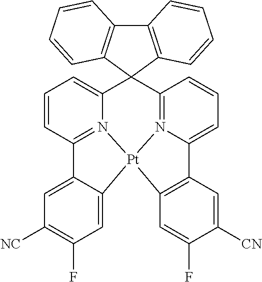 | (T-101) |
| 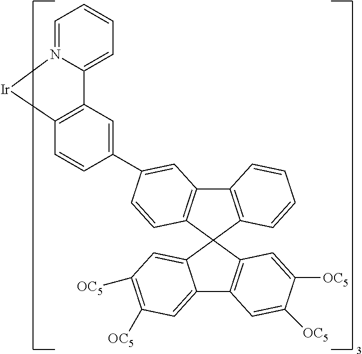 | (T-102) |
| 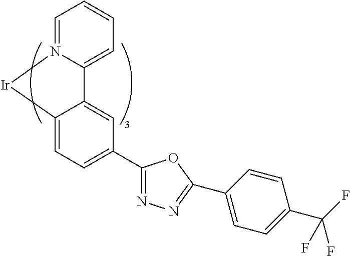 | (T-103) |
| 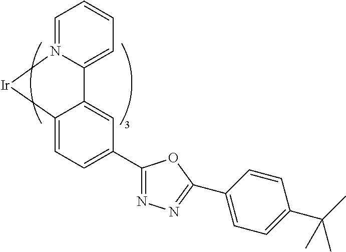 | (T-104) |
| 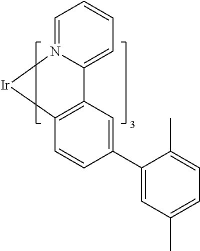 | (T-105) |
| 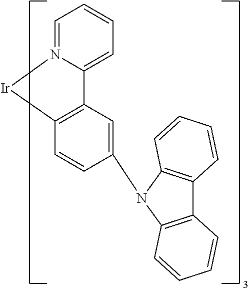 | (T-106) |
| 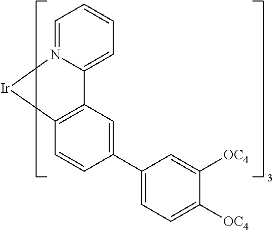 | (T-107) |
| 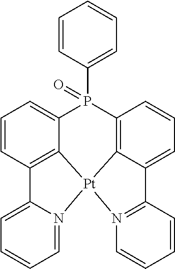 | (T-108) |
| 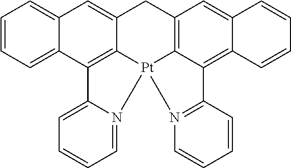 | (T-109) |
| 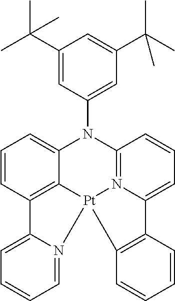 | (T-110) |
| 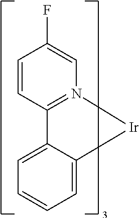 | (T-111) |
| 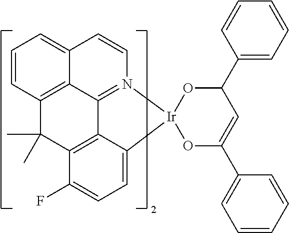 | (T-112) |
| 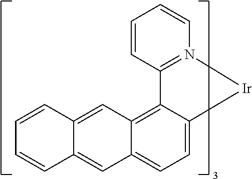 | (T-113) |
| 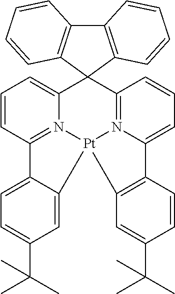 | (T-114) |
| 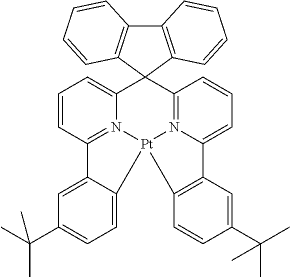 | (T-115) |
| 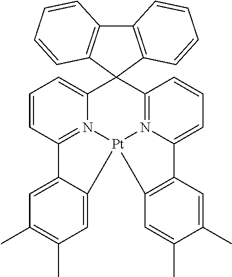 | (T-116) |
| 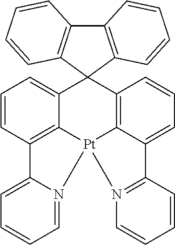 | (T-117) |
| 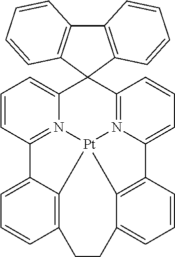 | (T-118) |
| 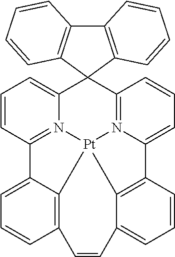 | (T-119) |
| 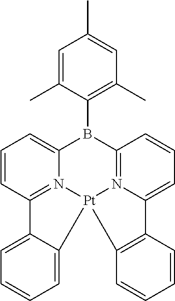 | (T-120) |
| 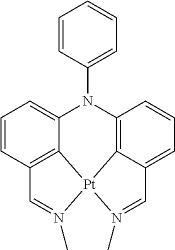 | (T-121) |
| 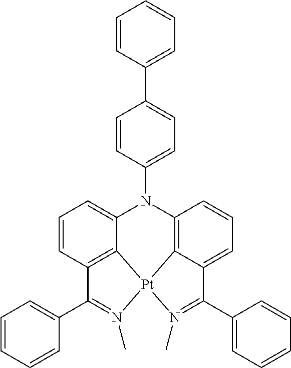 | (T-122) |
| 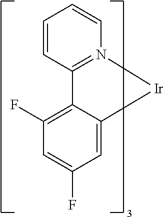 | (T-123) |
| 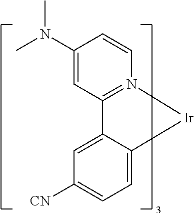 | (T-124) |
| 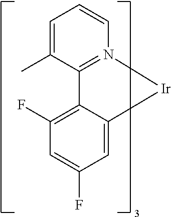 | (T-125) |
| 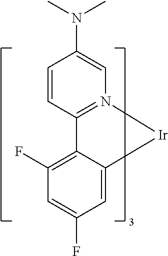 | (T-126) |
| 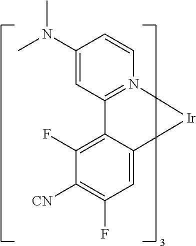 | (T-127) |
| 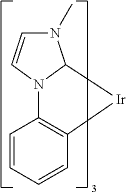 | (T-128) |
| 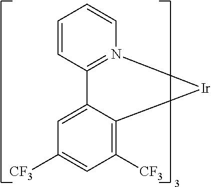 | (T-129) |
| 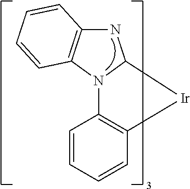 | (T-130) |
| 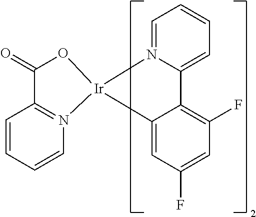 | (T-131) |
| 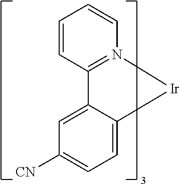 | (T-132) |
| 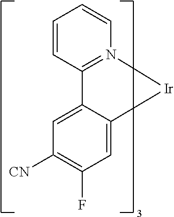 | (T-133) |
| 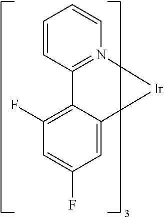 | (T-134) |
| 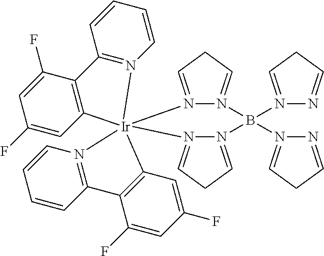 | (T-135) |
| 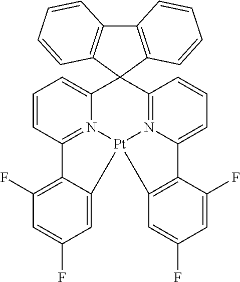 | (T-136) |
| 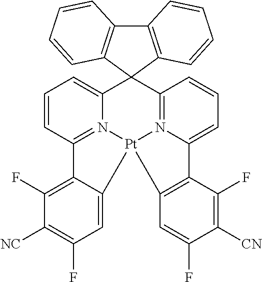 | (T-137) |
| 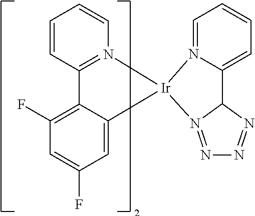 | (T-138) |
| 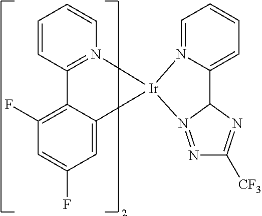 | (T-139) |
| 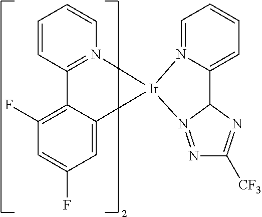 | (T-140) |

The formulation according to the invention furthermore comprises at least one solvent. The formulation is eminently suitable for the production of layers from solution.

Suitable and preferred solvents are, for example, toluene, anisole, xylenes, methyl benzoate, dimethylanisoles, trimethylbenzenes, tetralin, veratrols, tetrahydrofuran, chlorobenzene and dichlorobenzene, as well as mixtures thereof.

The formulation according to the invention is suitable for the production of organic electroluminescent devices (OLEDs, PLEDs), in particular for a luminescent layer in such devices. In particular, the individual components of the formulation are in the form of a homogeneous solution, which enables the formulation to be converted into a layer particularly well.

The present invention therefore furthermore relates to the use of the formulation according to the invention for the production of organic electronic devices, in particular organic electroluminescent devices.

The present invention again furthermore relates to organic electronic devices which are produced using the formulation according to the invention, in particular organic electroluminescent devices comprising an anode, a cathode and at least one emitting layer, characterised in that at least one emitting layer is obtained from a mixture according to the invention.

Apart from the cathode, the anode and the at least one emitting layer, the organic electroluminescent device may also comprise further layers. These are selected, for example, from in each case one or more hole-injection layers, hole-transport layers, hole-blocking layers, electron-transport layers, electron-injection layers, electron-blocking layers, exciton-blocking layers, charge-generation layers and/or organic or inorganic p/n junctions. In addition, interlayers which control, for example, the charge balance in the device may be present. In particular, such interlayers may be appropriate as interlayer between two emitting layers, in particular as interlayer between a fluorescent layer and a phosphorescent layer. Furthermore, the layers, in particular the charge-transport layers, may also be doped. Doping of the layers may be advantageous for improved charge transport. However, it should be pointed out that each of the layers mentioned above does not necessarily have to be present, and the choice of layers is always dependent on the compounds used. The use of layers of this type is known to the person skilled in the art, and he will be able to use all materials in accordance with the prior art that are known for such layers for this purpose without inventive step.

It is furthermore possible to use more than one emitting layer, for example two or three emitting layers, which preferably have different emission colours. A particularly preferred embodiment of the present invention relates to a white-emitting organic electroluminescent device. This is characterised in that it emits light having CIE colour coordinates in the range from 0.28/0.29 to 0.45/0.41. The general structure of a white-emitting electro-luminescent device of this type is disclosed, for example, in WO 05/011013.

The cathode of the electroluminescent device according to the invention preferably comprises metals having a low work function, metal alloys or multilayered structures comprising different metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Ca/Ag or Ba/Ag, are generally used. Preference is likewise given to metal alloys, in particular alloys comprising an alkali metal or alkaline-earth metal and silver, particularly preferably an alloy of Mg and Ag. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, CsF, Cs₂CO₃, BaF₂, MgO, NaF, etc.). The layer thickness of this layer is preferably between 0.5 and 5 nm.

The anode of the electroluminescent device according to the invention preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. At least one of the electrodes here must be transparent in order to facilitate the coupling-out of light. A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers, such as, for example, PEDOT or PAN I.

The device is correspondingly (depending on the application) structured, provided with contacts and finally hermetically sealed, since the lifetime of devices of this type is drastically shortened in the presence of water and/or air.

In general, all further materials as employed in accordance with the prior art in organic electroluminescent devices can be employed in combination with the emitting layer which comprises the mixture according to the invention.

Preference is furthermore given to an organic electroluminescent device which is characterised in that one or more layers are coated by means of a sublimation process, in which the materials are vapour-deposited in vacuum sublimation units at an initial pressure of less than 10⁻⁵ mbar, preferably less than 10⁻⁶ mbar. However, it should be noted that the initial pressure may also be even lower, for example less than 10⁻⁷ mbar.

Preference is likewise given to an organic electroluminescent device which is characterised in that one or more layers are coated by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Particular preference is given to an organic electroluminescent device which is characterised in that one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds are necessary for this purpose, as are present in the mixture according to the invention.

The organic electroluminescent device can also be produced as a hybrid system by applying one or more layers from solution and applying one or more further layers by vapour deposition.

These processes are generally known to the person skilled in the art and can be applied by him without inventive step to the organic electroluminescent devices according to the invention.

The organic electroluminescent devices according to the invention have the following surprising advantages over the prior art:
1. The organic electroluminescent device according to the invention has very high efficiency. The efficiency here is better than on use of an electron-transporting matrix material in combination with a hole-trans-porting matrix material in accordance with the prior art.
2. The organic electroluminescent device according to the invention at the same time has an improved lifetime. The lifetime here is longer than on use of an electron-transporting matrix material in combination with a hole-transporting matrix material in accordance with the prior art.

The invention is described in greater detail by the following examples, without wishing to restrict it thereby. The person skilled in the art will be able, without inventive step, to produce further organic electroluminescent devices according to the invention.

### General Methods:

Determination of the HOMO, LUMO and energy gap from cyclic voltammetry and absorption spectrum

In accordance with the present application, the HOMO and LUMO values and the energy gap are determined by the general methods described below:

The HOMO value arises from the oxidation potential, which is measured by cyclic voltammetry (CV) at room temperature. The measuring instrument used for this purpose is an ECO Autolab system with Metrohm 663 VA stand. The working electrode is a gold electrode, the reference electrode is Ag/AgCl, the bridge electrolyte is KCl (3 mol/l) and the auxiliary electrode is platinum.

For the measurement, firstly a 0.11 M conductive-salt solution of tetrabutylammonium hexafluorophosphate (NH₄PF₆) in dichloromethane is prepared, introduced into the measurement cell and degassed for 5 minutes. Two measurement cycles are subsequently carried out with the following parameters:

Measurement technique: CV
Initial purge time: 300 s
Cleaning potential: −1V
Cleaning time: 10 s
Deposition potential: −0.2 V
Deposition time: 10 s
Start potential: −0.2 V
End potential: 1.6 V
Voltage step: 6 mV
Sweep rate: 50 mV/s

1 ml of the sample solution (10 mg of the substance to be measured in 1 ml of dichloromethane) is subsequently added to the conductive-salt solution, and the mixture is degassed again for 5 minutes. Five further measurement cycles are subsequently carried out, the last three of which are recorded for evaluation. The same parameters are set as described above.

0.1 ml of ferrocene solution (100 mg of ferrocene in 1 ml of dichloromethane) is subsequently added to the solution, the mixture is degassed for 1 minute, and a measurement cycle is carried out with the following parameters:

Measurement technique: CV
Initial purge time: 60 s
Cleaning potential: −1V
Cleaning time: 10 s
Deposition potential: −0.2 V
Deposition time: 10 s
Start potential: −0.2 V
End potential: 1.6 V
Voltage step: 6 mV
Sweep rate: 50 mV/s

For evaluation, the mean of the voltages of the first oxidation maximum is taken from the forward curves and the mean of the voltages of the associated reduction maximum is taken from the return curves (V_{P} and V_{F}) for the sample solution and the solution to which ferrocene solution has been added, where the voltage used is in each case the voltage against ferrocene. The HOMO value of the substance to be investigated E_{HOMO} is given by E_{HOMO}=−[e·(V_{P}−V_{F})+4.8 eV], where e represents the elementary charge.

It should be noted that appropriate modifications of the measurement method may have to be carried out in individual cases, for example if the substance to be investigated is not soluble in dichloromethane or if decomposition of the substance occurs during the measurement. If a meaningful measurement should not be possible by means of CV using the above-mentioned method, the HOMO energy will be determined by photoelectron spectroscopy by means of a model AC-2 photoelectron spectrometer from Riken Keiki Co. Ltd. (http://www.rikenkeiki.com/pages/AC2.htm), in which case it should be noted that the values obtained are typically around 0.3 eV lower than those measured by CV. The HOMO value in accordance with the present application is then taken to mean the value from Riken AC2+0.3 eV.

Furthermore, HOMO values lower than −6 eV cannot be measured reliably either using the CV method described or using the photoelectron spectroscopy described. In this case, the HOMO values are determined from quantum-chemical calculation by means of density functional theory (DFT). This is carried out via the commercially available Gaussian 03W (Gaussian Inc.) software using method B3PW91/6-31G(d). Standardisation of the calculated values to CV values is achieved by comparison with materials which can be measured by CV. To this end, the HOMO values of a series of materials are measured using the CV method and also calculated. The calculated values are then calibrated by means of the measured values, and this calibration factor is used for all further calculations. In this way, it is possible to calculate HOMO values which correspond very well to those which would be measured by CV. If the HOMO value for a particular substance cannot be measured by CV or Riken AC2 as described above, the HOMO value in accordance with the present application is therefore taken to mean the value which is obtained in accordance with the description by a DFT calculation calibrated to CV, as described above. Examples of values calculated in this way for some common organic materials are: NPB (HOMO −5.16 eV, LUMO −2.28 eV); TCTA (HOMO −5.33 eV, LUMO −2.20 eV); TPBI (HOMO −6.26 eV, LUMO −2.48 eV). These values can be used for calibration of the calculation method.

The energy gap is determined from the absorption edge of the absorption spectrum measured on a film having a layer thickness of 50 nm. The absorption edge here is defined as the wavelength obtained when a straight line is fitted to the longest-wavelength falling flank in the absorption spectrum at its steepest point, and the value is determined at which this straight line intersects the wavelength axis, i.e. the absorption value=0.

The LUMO value is obtained by addition of the energy gap to the HOMO value described above.

### WORKING EXAMPLES

### Examples 1 to 45

### Production of PLEDs

The structures of emitter E1, ketones K-1 to K-12 according to the invention, triazines T-1 to T-4 according to the invention and carbazoles C-1 to C-6 according to the invention are depicted below.

### Structure of Emitter E1

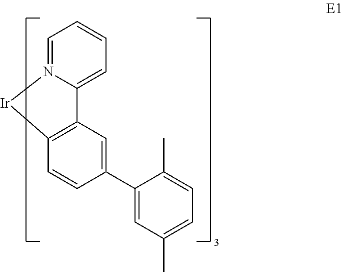

### Structures of the Ketone Compounds

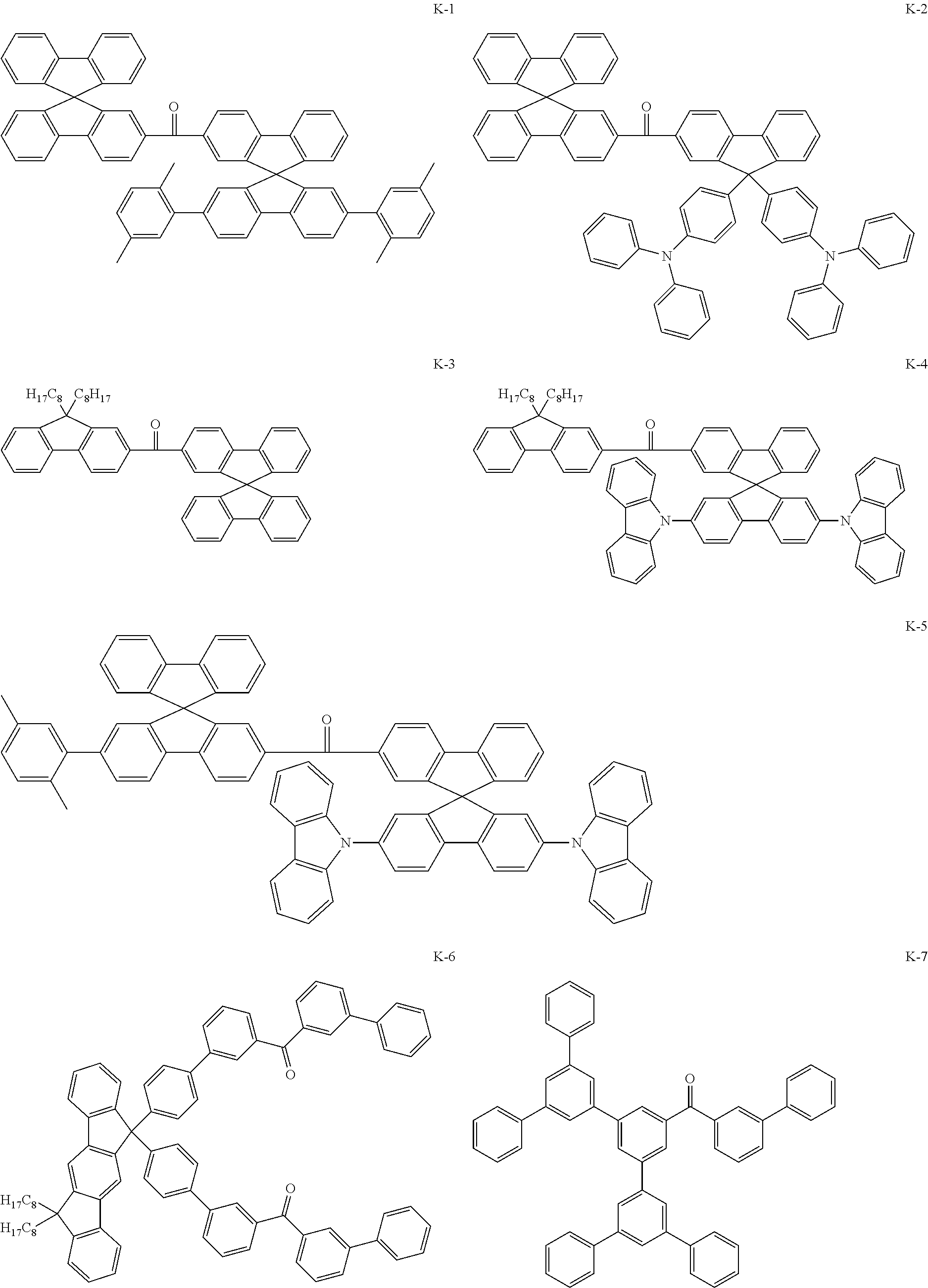

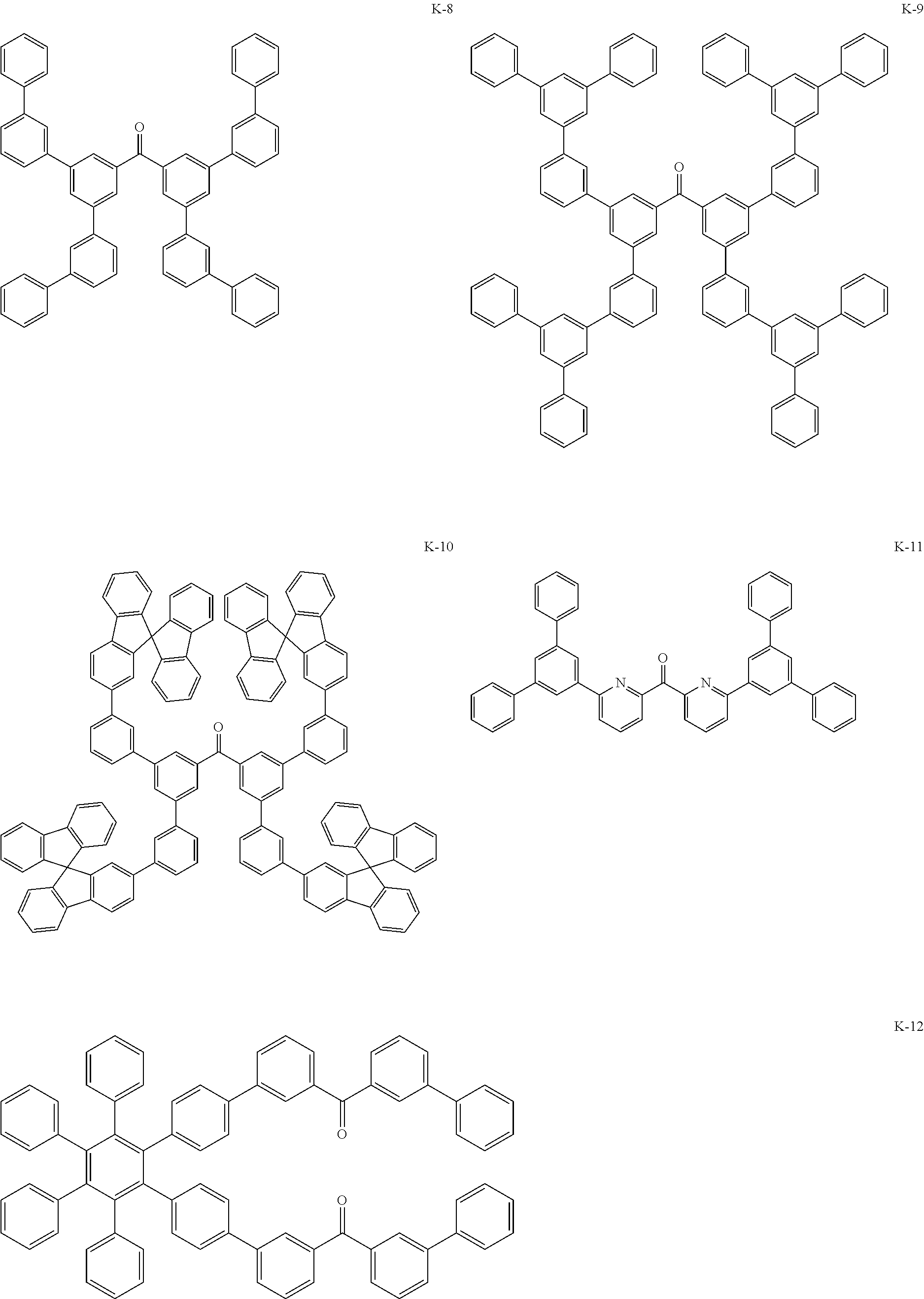

### Structures of the Triazine Compounds

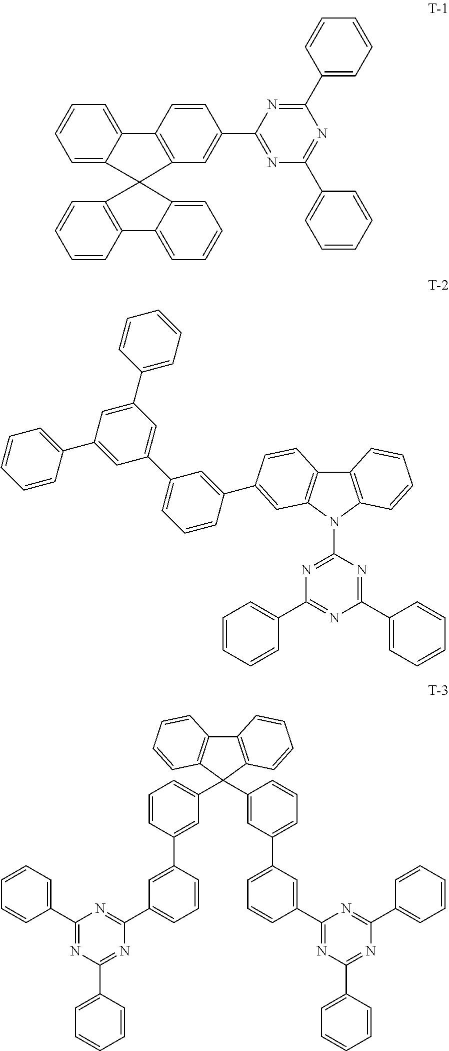 [SMILES: c1ccc(-c2nc(-c3ccccc3)nc(-c3ccc4c(c3)C3(c5ccccc5-c5ccccc53)c3ccccc3-4)n2)cc1 ; c1ccc(-c2cc(-c3ccccc3)cc(-c3cccc(-c4ccc5c6ccccc6n(-c6nc(-c7ccccc7)nc(-c7ccccc7)n6)c5c4)c3)c2)cc1 ; c1ccc(-c2nc(-c3ccccc3)nc(-c3cccc(-c4cccc(C5(c6cccc(-c7cccc(-c8nc(-c9ccccc9)nc(-c9ccccc9)n8)c7)c6)c6ccccc6-c6ccccc65)c4)c3)n2)cc1]

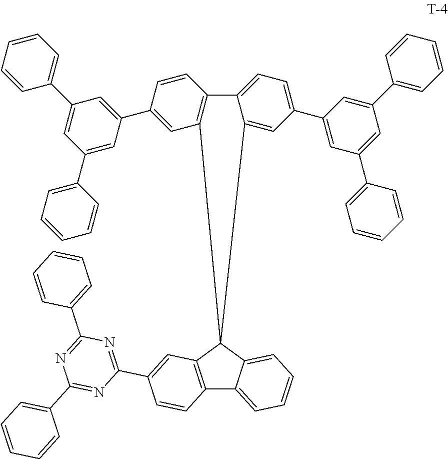 [SMILES: c1ccc(-c2cc(-c3ccccc3)cc(-c3ccc4c(c3)C3(c5ccccc5-c5ccc(-c6nc(-c7ccccc7)nc(-c7ccccc7)n6)cc53)c3cc(-c5cc(-c6ccccc6)cc(-c6ccccc6)c5)ccc3-4)c2)cc1]

### Structures of the Carbazole Compounds

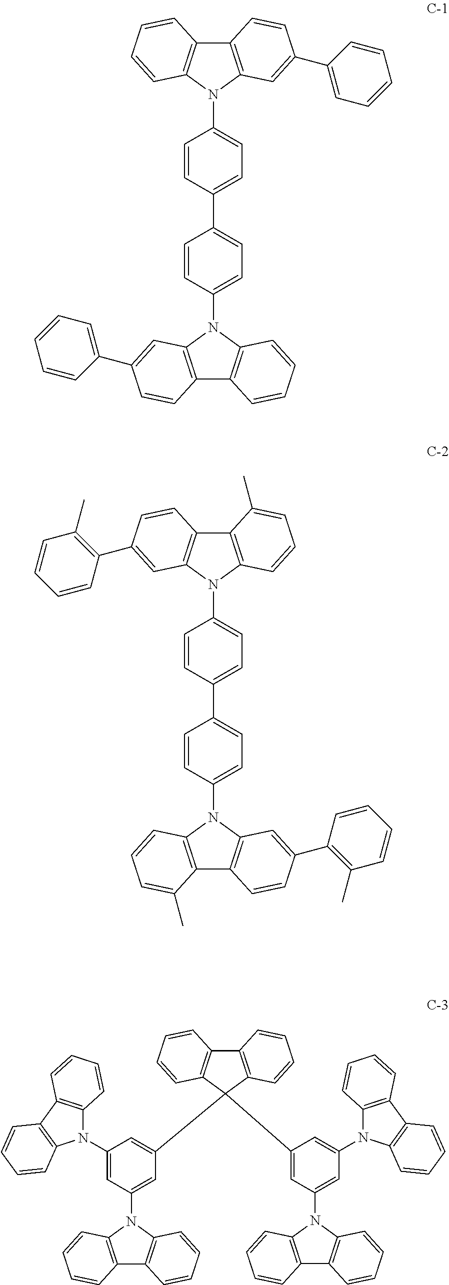 [SMILES: c1ccc(-c2ccc3c4ccccc4n(-c4ccc(-c5ccc(-n6c7ccccc7c7ccc(-c8ccccc8)cc76)cc5)cc4)c3c2)cc1 ; Cc1ccccc1-c1ccc2c3c(C)cccc3n(-c3ccc(-c4ccc(-n5c6cc(-c7ccccc7C)ccc6c6c(C)cccc65)cc4)cc3)c2c1 ; c1ccc2c(c1)-c1ccccc1C2(c1cc(-n2c3ccccc3c3ccccc32)cc(-n2c3ccccc3c3ccccc32)c1)c1cc(-n2c3ccccc3c3ccccc32)cc(-n2c3ccccc3c3ccccc32)c1]

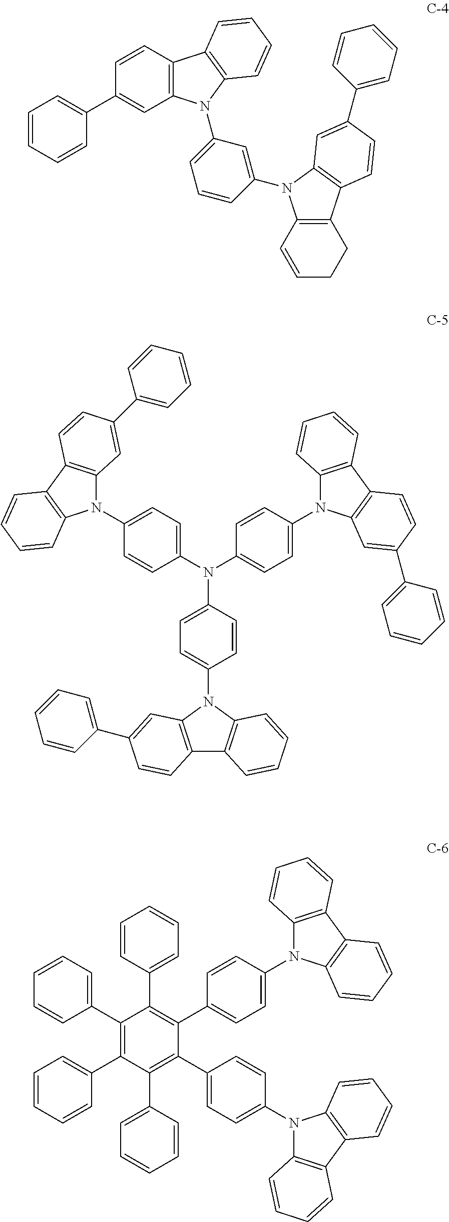 [SMILES: C1=Cc2c(c3ccc(-c4ccccc4)cc3n2-c2cccc(-n3c4ccccc4c4ccc(-c5ccccc5)cc43)c2)CC1 ; c1ccc(-c2ccc3c4ccccc4n(-c4ccc(N(c5ccc(-n6c7ccccc7c7ccc(-c8ccccc8)cc76)cc5)c5ccc(-n6c7ccccc7c7ccc(-c8ccccc8)cc76)cc5)cc4)c3c2)cc1 ; c1ccc(-c2c(-c3ccccc3)c(-c3ccccc3)c(-c3ccc(-n4c5ccccc5c5ccccc54)cc3)c(-c3ccc(-n4c5ccccc5c5ccccc54)cc3)c2-c2ccccc2)cc1]

The materials which are used in the formulations according to the invention result there in significantly simpler devices having good properties. The production of such components is based on the production of polymeric light-emitting diodes (PLEDs), which has already been described a number of times in the literature (for example in WO 2004/037887 A2). In the present case, the compounds according to the invention are dissolved in toluene or chlorobenzene. The concentration employed in the examples mentioned here is 20% by weight of the emitter, 40% by weight of compounds K-1 to K-12 or of compounds T-1 to T-4 and 40% by weight of compounds C-1 to C-6. The typical solids content of such solutions is between 16 and 25 g/l if, as here, the layer thickness of 80 nm which is typical for a device is to be achieved by means of spin coating.

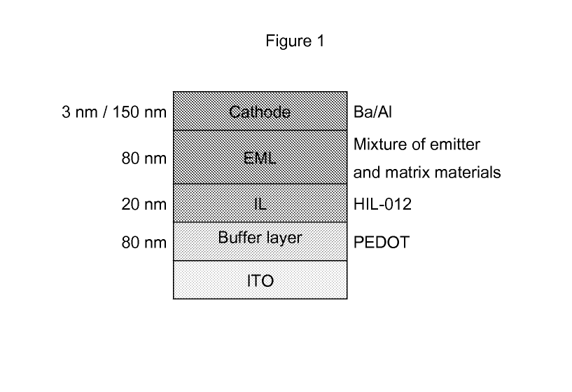

FIG. 1 shows the typical structure of a device of this type. In the EML, the matrix materials and the emitter are in the form of an amorphous layer. Structured ITO substrates and the material for the so-called buffer layer (PEDOT, actually PEDOT:PSS) are commercially available (ITO from, inter alia, Technoprint, PEDOT:PPS as Clevios P aqueous dispersion from H.C. Starck). The interlayer used serves for hole injection. HIL-012 from Merck is used. The emission layer is applied by spin coating in an inert-gas atmosphere, in the present case argon, and dried by heating at 160° C. or 180° C. for 10 minutes. Finally, a cathode comprising barium and aluminium is applied by vacuum vapour deposition. Further layers (for example HBL and ETL) can also be applied between the EML and the cathode by means of vapour deposition. The interlayer may also be replaced by one or more layers, which merely have to satisfy the condition that they are not redetached by the subsequent processing step of EML deposition from solution. The solution-processed devices are characterised by standard methods; the said OLED examples were not optimised.

Table 1 compares the device results without compounds C-1 to C-6 according to the invention with those obtained by means of a mixed layer comprising materials K-1 to K-12 or T-1 to T-4 according to the invention.

TABLE 1
Results in the device configuration from FIG. 1

| | | | | | Lifetime [h], |
|---|---|---|---|---|---|
| | | Max. | Voltage | | initial |
| | EML | eff. | [V] at | CIE | luminance |
| Ex. | 80 nm | [cd/A] | 100 cd/m² | (x, y) | 1000 cd/m² |
| Comp. | K-1:E-1 | 22 | 4.2 | 0.35/0.61 | 2700 |
| | K-1:C-1:E-1 | 30 | 4.3 | 0.36/0.61 | 8500 |
| | K-1:C-2:E-1 | 27 | 4.1 | 0.35/0.61 | 4100 |
| | K-1:C-3:E-1 | 29 | 4.1 | 0.35/0.61 | 4000 |
| | K-1:C-4:E-1 | 28 | 4.1 | 0.35/0.61 | 5700 |
| | K-1:C-5:E-1 | 32 | 4.1 | 0.34/0.62 | 4500 |
| | K-1:C-6:E-1 | 27 | 4.5 | 0.34/0.62 | 3950 |
| Comp. | K-2:E-1 | 26 | 4.5 | 0.35/0.61 | 1100 |
| | K-2:C-1:E-1 | 29 | 4.2 | 0.36/0.61 | 8500 |
| | K-2:C-2:E-1 | 31 | 4.2 | 0.35/0.61 | 5200 |
| | K-2:C-3:E-1 | 28 | 4.3 | 0.35/0.61 | 3200 |
| | K-2:C-4:E-1 | 29 | 4.2 | 0.35/0.61 | 8600 |
| | K-2:C-5:E-1 | 30 | 4.1 | 0.34/0.62 | 4500 |
| | K-2:C-6:E-1 | 30 | 4.1 | 0.34/0.62 | 6800 |
| Comp. | K-3:E-1 | 9 | 4.9 | 0.32/0.63 | 600 |
| | K-3:C-1:E-1 | 20 | 4.6 | 0.32/0.63 | 2180 |
| | K-3:C-2:E-1 | 18 | 4.5 | 0.35/0.61 | 3000 |
| | K-3:C-3:E-1 | 15 | 4.6 | 0.35/0.61 | 2200 |
| | K-3:C-4:E-1 | 23 | 4.4 | 0.35/0.61 | 3600 |
| | K-3:C-5:E-1 | 19 | 4.4 | 0.34/0.62 | 4500 |
| | K-3:C-6:E-1 | 21 | 4.5 | 0.34/0.62 | 5900 |
| Comp. | K-4:E-1 | 20 | 4.0 | 0.34/0.62 | 1425 |
| | K-4:C-1:E-1 | 28 | 4.0 | 0.34/0.62 | 4500 |
| | K-4:C-2:E-1 | 25 | 4.1 | 0.35/0.61 | 5100 |
| | K-4:C-3:E-1 | 30 | 4.1 | 0.35/0.61 | 6300 |
| | K-4:C-4:E-1 | 27 | 4.1 | 0.35/0.61 | 4300 |
| | K-4:C-5:E-1 | 26 | 4.1 | 0.34/0.62 | 4600 |
| | K-4:C-6:E-1 | 24 | 4.0 | 0.34/0.62 | 3900 |
| Comp. | K-5:E-1 | 24 | 4.0 | 0.36/0.60 | 1800 |
| | K-5:C-1:E-1 | 29 | 4.0 | 0.34/0.62 | 3300 |
| | K-5:C-2:E-1 | 28 | 4.0 | 0.35/0.61 | 4500 |
| | K-5:C-3:E-1 | 29 | 3.9 | 0.35/0.61 | 4200 |
| | K-5:C-4:E-1 | 29 | 3.9 | 0.35/0.61 | 3600 |
| | K-5:C-5:E-1 | 30 | 4.0 | 0.34/0.62 | 4800 |
| | K-5:C-6:E-1 | 28 | 4.1 | 0.34/0.62 | 4900 |
| Comp. | K-6:E-1 | 20 | 7.5 | 0.33/0.62 | 1500 |
| | K-6:C-1:E-1 | 27 | 6.0 | 0.33/0.62 | 8000 |
| | K-6:C-2:E-1 | 27 | 4.7 | 0.34/0.62 | 7200 |
| | K-6:C-3:E-1 | 27 | 4.5 | 0.35/0.61 | 8100 |
| | K-6:C-4:E-1 | 29 | 4.6 | 0.35/0.61 | 5600 |
| | K-6:C-5:E-1 | 28 | 4.3 | 0.35/0.61 | 3700 |
| | K-6:C-6:E-1 | 32 | 4.5 | 0.34/0.62 | 6300 |
| Comp. | K-7:E-1 | 21 | 5.7 | 0.33/0.63 | 1200 |
| | K-7:C-1:E-1 | 29 | 4.4 | 0.33/0.63 | 1600 |
| | K-7:C-2:E-1 | 25 | 4.5 | 0.35/0.61 | 3100 |
| | K-7:C-3:E-1 | 28 | 4.3 | 0.35/0.61 | 5200 |
| | K-7:C-4:E-1 | 27 | 4.4 | 0.35/0.61 | 5300 |
| | K-7:C-5:E-1 | 28 | 4.5 | 0.34/0.62 | 3900 |
| | K-7:C-6:E-1 | 30 | 4.4 | 0.34/0.62 | 5100 |
| Comp. | K-8:E-1 | 27 | 5.0 | 0.35/0.61 | 3200 |
| | K-8:C-1:E-1 | 33 | 4.7 | 0.34/0.62 | 10000 |
| | K-8:C-2:E-1 | 31 | 4.7 | 0.34/0.61 | 7000 |
| | K-8:C-3:E-1 | 31 | 4.7 | 0.34/0.61 | 7000 |
| | K-8:C-4:E-1 | 33 | 4.5 | 0.33/0.63 | 9000 |
| | K-8:C-5:E-1 | 32 | 4.9 | 0.33/0.62 | 5900 |
| | K-7:C-6:E-1 | 32 | 4.6 | 0.34/0.62 | 6200 |
| Comp. | K-9:E-1 | 26 | 6.3 | 0.34/0.62 | 1010 |
| | K-9:C-1:E-1 | 35 | 5.2 | 0.34/0.62 | 3000 |
| | K-9:C-2:E-1 | 33 | 5.3 | 0.34/0.62 | 3100 |
| | K-9:C-3:E-1 | 31 | 5.2 | 0.34/0.62 | 4000 |
| | K-9:C-4:E-1 | 32 | 5.1 | 0.34/0.62 | 4100 |
| | K-9:C-5:E-1 | 30 | 5.2 | 0.34/0.62 | 3200 |
| | K-9:C-6:E-1 | 31 | 5.3 | 0.34/0.62 | 3400 |
| Comp. | K-10:E-1 | 26 | 6.0 | 0.32/0.63 | 1400 |
| | K-10:C-1:E-1 | 30 | 5.5 | 0.32/0.63 | 5600 |
| | K-10:C-2:E-1 | 31 | 5.3 | 0.34/0.62 | 2100 |
| | K-10:C-3:E-1 | 33 | 5.4 | 0.34/0.62 | 4500 |
| | K-10:C-4:E-1 | 32 | 5.5 | 0.34/0.62 | 6500 |
| | K-10:C-5:E-1 | 30 | 5.3 | 0.34/0.62 | 4300 |
| | K-10:C-6:E-1 | 29 | 5.5 | 0.34/0.62 | 3400 |
| Comp. | K-11:E-1 | 30 | 5.5 | 0.34/0.62 | 7000 |
| | K-11:C-1:E-1 | 35 | 5.1 | 0.35/0.62 | 9000 |
| | K-11:C-2:E-1 | 34 | 4.9 | 0.35/0.62 | 8500 |
| | K-11:C-6:E-1 | 35 | 5.0 | 0.35/0.62 | 9500 |
| Comp. | K-12:E-1 | 25 | 8.3 | 0.34/0.62 | 2200 |
| | K-12:C-1:E-1 | 32 | 6.9 | 0.35/0.62 | 7000 |
| Comp. | T-1:E-1 | 14 | 4.2 | 0.36/0.61 | 9200 |
| | T-1:C-1:E-1 | 24 | 3.5 | 0.34/0.62 | 10500 |
| | T-1:C-2:E-1 | 23 | 3.3 | 0.34/0.62 | 10400 |
| | T-1:C-3:E-1 | 19 | 3.3 | 0.33/0.62 | 10200 |
| | T-1:C-4:E-1 | 20 | 3.3 | 0.33/0.62 | 10100 |
| | T-1:C-5:E-1 | 23 | 3.3 | 0.33/0.62 | 10600 |
| | T-1:C-6:E-1 | 21 | 3.3 | 0.33/0.62 | 10400 |
| Comp. | T-2:E-1 | 25 | 5.3 | 0.33/0.62 | 5700 |
| | T-2:C-1:E-1 | 28 | 5.2 | 0.33/0.63 | 8200 |
| | T-2:C-2:E-1 | 27 | 5.1 | 0.34/0.62 | 3993 |
| | T-2:C-3:E-1 | 29 | 5.3 | 0.33/0.62 | 8400 |
| | T-2:C-4:E-1 | 28 | 5.2 | 0.33/0.62 | 7500 |
| | T-2:C-5:E-1 | 27 | 5.3 | 0.33/0.62 | 9000 |
| | T-2:C-6:E-1 | 29 | 3.3 | 0.33/0.62 | 10100 |
| Comp. | T-3:E-1 | 28 | 5.4 | 0.34/0.62 | 7200 |
| | T-3:C-1:E-1 | 33 | 3.5 | 0.34/0.62 | 17800 |
| | T-3:C-2:E-1 | 30 | 3.4 | 0.34/0.62 | 3993 |
| | T-3:C-3:E-1 | 31 | 3.5 | 0.33/0.62 | 6200 |
| | T-3:C-4:E-1 | 32 | 3.5 | 0.33/0.62 | 5300 |
| | T-3:C-5:E-1 | 30 | 3.5 | 0.33/0.62 | 8000 |
| | T-3:C-6:E-1 | 30 | 3.5 | 0.33/0.62 | 8300 |
| Comp. | T-4:E-1 | 25 | 3.9 | 0.33/0.62 | 5900 |
| | T-4:C-1:E-1 | 29 | 3.5 | 0.34/0.62 | 6250 |
| | T-4:C-2:E-1 | 30 | 3.4 | 0.34/0.62 | 8300 |
| | T-4:C-3:E-1 | 28 | 3.6 | 0.33/0.62 | 7500 |
| | T-4:C-4:E-1 | 31 | 3.5 | 0.33/0.62 | 5650 |
| | T-4:C-5:E-1 | 30 | 3.5 | 0.33/0.62 | 7300 |
| | T-4:C-6:E-1 | 28 | 3.6 | 0.33/0.62 | 9600 |

1.-11. (canceled)

12. A formulation comprising a carbazole compound, an electron-transport compound, a triplet emitter compound and at least one solvent, where the electron-transport compound encompasses a ketone compound or a triazine compound and where the carbazole compound contains at least two carbazole groups which are connected to one another via their N atoms.

13. The formulation according to claim 12, wherein the carbazole compound is a compound of the formula (1) 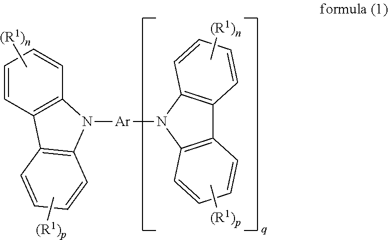
where the following applies to the symbols and indices used:
Ar is on each occurrence an aromatic or heteroaromatic ring system having 5 to 60 aromatic ring atoms, which is optionally substituted by one or more radicals R;
R and R¹ is on each occurrence, identically or differently, H, D, F, Cl, Br, I, N(Ar¹)₂, CN, NO₂, Si(R²)₃, B(OR²)₂, C(═O)Ar¹, P(═O)(Ar¹)₂, S(═O)Ar¹, S(═O)₂Ar¹, —CR²═CR²(Ar¹), OSO₂R², a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems; two or more substituents R, R¹ or R and R¹ here may also form a mono- or polycyclic, aliphatic, aromatic or heteroaromatic ring system with one another;
Ar¹ is on each occurrence, identically or differently, an aromatic or heteroaromatic ring system having 5 to 60 aromatic ring atoms, which is optionally substituted by one or more radicals R²;
R² is on each occurrence, identically or differently, H or an aliphatic, aromatic and/or heteroaromatic hydrocarbon radical having 1 to 20 C atoms; or an aromatic or heteroaromatic ring system having 5 to 60 aromatic ring atoms, which is optionally substituted by one or more radicals R; two or more substituents R² here may also form a mono or polycyclic, aliphatic, aromatic or heteroaromatic ring system with one another;
n is on each occurrence, identically or differently, 0, 1, 2, 3 or 4;
p is on each occurrence, identically or differently, 0, 1, 2, 3 or 4; and
q is 1, 2, 3, 4 or 5.

14. The formulation according to claim 12, wherein the ketone compound is a compound of the formula (2) 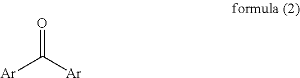
where the following applies to the symbols used:
Ar is on each occurrence, identically or differently, an aromatic or heteroaromatic ring system having 5 to 60 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which is optionally substituted by one or more radicals R², where one or more non-adjacent CH₂ groups is optionally replaced by R²C═CR², C═C, Si(R²)₂, Ge(R²)₂, Sn(R²)₂, C═O, C═S, C=Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems; two or more adjacent substituents R¹ here may also form a mono- or polycyclic, aliphatic, aromatic or heteroaromatic ring system with one another;
Ar¹ is on each occurrence, identically or differently, an aromatic or heteroaromatic ring system having 5 to 40 aromatic ring atoms, which is optionally substituted by one or more radicals R²; and
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another.

15. The formulation according to claim 13, wherein the ketone compound is a compound of the formula (2) 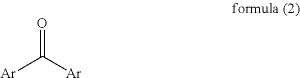
where the following applies to the symbols used:
Ar is on each occurrence, identically or differently, an aromatic or heteroaromatic ring system having 5 to 60 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which is optionally substituted by one or more radicals R², where one or more non-adjacent CH₂ groups is optionally replaced by R²C═CR², Si(R²)₂, Ge(R²)₂, Sn(R²)₂, C═O, C═S, C=Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems; two or more adjacent substituents R¹ here may also form a mono- or polycyclic, aliphatic, aromatic or heteroaromatic ring system with one another;
Ar¹ is on each occurrence, identically or differently, an aromatic or heteroaromatic ring system having 5 to 40 aromatic ring atoms, which is optionally substituted by one or more radicals R²; and
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another.

16. The formulation according to claim 14, wherein the group Ar of the ketone compound stands for phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthylnaphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridazinyl, 2-(1,3,5-triazin)yl-, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals.

17. The formulation according to claim 12, wherein the triazine compound is a compound of the formula (7) or (8), 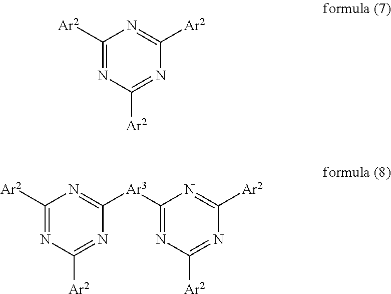
where the following applies to the other symbols used:
Ar² is, identically or differently on each occurrence, a monovalent aromatic or heteroaromatic ring system having 5 to 60 aromatic ring atoms, which optionally in each case is substituted by one or more radicals R¹;
Ar³ is a divalent aromatic or heteroaromatic ring system having 5 to 60 aromatic ring atoms, which is optionally substituted by one or more radicals R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which is optionally substituted by one or more radicals R², where one or more non-adjacent CH₂ groups is optionally replaced by R²C═CR², C═C, Si(R²)₂, Ge(R²)₂, Sn(R²)₂, C═O, C═S, C=Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems; two or more adjacent substituents R¹ here may also form a mono- or polycyclic, aliphatic, aromatic or heteroaromatic ring system with one another, and
Ar¹ is on each occurrence, identically or differently, an aromatic or heteroaromatic ring system having 5 to 40 aromatic ring atoms, which is optionally substituted by one or more radicals R²; and
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another.

18. The formulation according to claim 15, wherein the triazine compound is a compound of the formula (7) or (8), 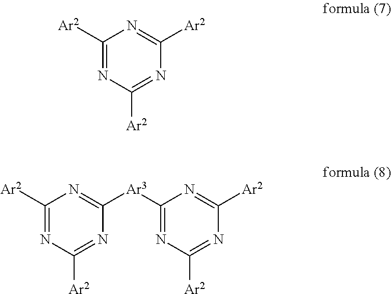
where the following applies to the other symbols used:
Ar² is, identically or differently on each occurrence, a monovalent aromatic or heteroaromatic ring system having 5 to 60 aromatic ring atoms, which optionally in each case is substituted by one or more radicals R¹;
Ar³ is a divalent aromatic or heteroaromatic ring system having 5 to 60 aromatic ring atoms, which is optionally substituted by one or more radicals R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems; two or more adjacent substituents R¹ here may also form a mono- or polycyclic, aliphatic, aromatic or heteroaromatic ring system with one another, and
Ar¹ is on each occurrence, identically or differently, an aromatic or heteroaromatic ring system having 5 to 40 aromatic ring atoms, which is optionally substituted by one or more radicals R²; and
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another.

19. The formulation according to claim 12, wherein the triplet emitter compound is a compound of the formulae (23) to (26), 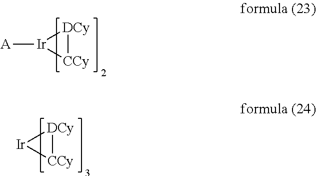 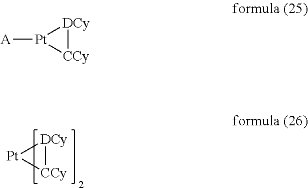
where R¹ has the same meaning as described in claim 13, and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
R¹ is on each occurrence, identically or differently, H, D, F, Cl, Br, I, N(Ar¹)₂, CN, NO₂, Si(R²)₃, B(OR²)₂, C(═O)Ar¹, P(═O)(Ar¹)₂, S(═O)Ar¹, S(═O)₂Ar¹, —CR²═CR²(Ar¹), OSO₂R², a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C═C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems;
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another and
A is, identically or differently on each occurrence, a monoanionic or bidentate chelating ligand.

20. The formulation according to claim 18, wherein the triplet emitter compound is a compound of the formulae (23) to (26), 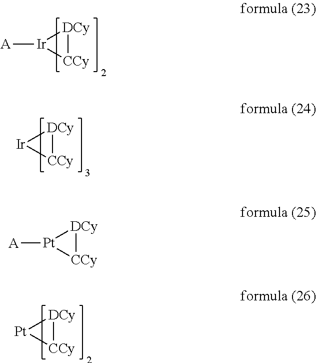
where R¹ has the same meaning as described in claim 13, and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
R¹ is on each occurrence, identically or differently, H, D, F, Cl, Br, I, N(Ar¹)₂, CN, NO₂, Si(R²)₃, B(OR²)₂, C(═O)Ar¹, P(═O)(Ar¹)₂, S(═O)Ar¹, S(═O)₂Ar¹, —CR²═CR²(Ar¹), OSO₂R², a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems;
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another and
A is, identically or differently on each occurrence, a monoanionic or bidentate chelating ligand.

21. The formulation according to claim 12, wherein the triplet emitter compound is a compound of the formulae (23) to (26), 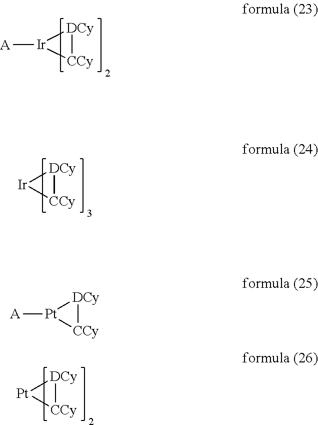
where R¹ has the same meaning as described in claim 13, and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
R¹ is on each occurrence, identically or differently, H, D, F, Cl, Br, I, N(Ar¹)₂, CN, NO₂, Si(R²)₃, B(OR²)₂, C(═O)Ar¹, P(═O)(Ar¹)₂, S(═O)Ar¹, S(═O)₂Ar¹, —CR²═CR²(Ar¹), OSO₂R², a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems;
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another and
A is, identically or differently on each occurrence, a diketonate ligand.

22. The formulation according to claim 18, wherein the triplet emitter compound is a compound of the formulae (23) to (26), 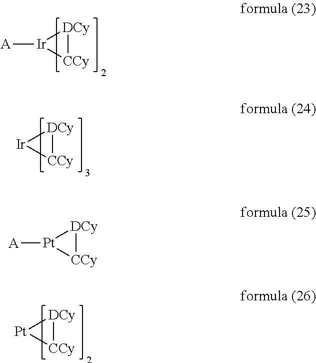
where R¹ has the same meaning as described in claim 13, and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
R¹ is on each occurrence, identically or differently, H, D, F, Cl, Br, I, N(Ar¹)₂, CN, NO₂, Si(R²)₃, B(OR²)₂, C(═O)Ar¹, P(═O)(Ar¹)₂, S(═O)Ar¹, S(═O)₂Ar¹, —CR²═CR²(Ar¹), OSO₂R², a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C=Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which is optionally substituted by one or more radicals R², or a combination of these systems;
R² is on each occurrence, identically or differently, H, D, CN or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic, aromatic or heteroaromatic ring system with one another and
A is, identically or differently on each occurrence, a diketonate ligand.

23. A process for producing an organic electroluminescent device which comprises utilizing the formulation according to claim 12.

24. An organic electroluminescent device comprising a cathode, an anode and at least one electroluminescent layer, wherein the electroluminescent layer comprises a mixture comprising a carbazole compound, an electron-transport compound and a triplet emitter compound, where the electron-transport unit encompasses a ketone compound or a triazine compound and where the carbazole compound contains at least two carbazole groups which are connected to one another via their N atoms.

25. An organic electroluminescent device comprising the electroluminescent layer has been obtained from the formulation according to claim 12.

26. The organic electroluminescent device according to claim 24, wherein there is no electron-injection layer present in the device.

27. The organic electroluminescent device according to claim 24, wherein the electroluminescent layer has been applied from solution.
